(19) United States
(12) Patent Application Publication
(10) Pub. No.: US 2018/0179241 A1
(43) Pub. Date: Jun. 28, 2018

(54) BISTABLE COMPLEXES AND DEVICES AND METHODS OF MAKING AND USING THE SAME

(71) Applicants: Natia L. Frank, Victoria (CA); Daniel Plaul, Kiel (DE); Michelle M. Paquette, Kansas City, MO (US); Aiko Kurimoto, Victoria (CA)

(72) Inventors: Natia L. Frank, Victoria (CA); Daniel Plaul, Kiel (DE); Michelle M. Paquette, Kansas City, MO (US); Aiko Kurimoto, Victoria (CA)

(73) Assignee: UVic Industry Partnerships Inc.

(21) Appl. No.: 15/881,371

(22) Filed: Jan. 26, 2018

Related U.S. Application Data
(63) Continuation-in-part of application No. PCT/CA2016/050892, filed on Jul. 28, 2016.
(60) Provisional application No. 62/198,482, filed on Jul. 29, 2015.
(60) Provisional application No. 62/293,251, filed on Feb. 9, 2016.

(51) Int. Cl. C07F 15/06; C09K 9/02; H01L 43/12; G11C 11/16; H01L 45/00; G11C 13/04

(52) U.S. Cl. CPC C07F 15/065; C09K 9/02; H01L 43/12; G11C 11/161; C09K 2211/1007; G11C 13/047; C09K 2211/187; C09K 2211/1033; C09K 2211/1044; H01L 45/1253

(57) ABSTRACT

Disclosed herein are embodiments of complexes exhibiting reversible light-induced magnetization, and/or heat, and/or electrically-induced switching with unprecedented lifetimes. In particular embodiments, the complexes are provided as organic thin films that can exhibit long lifetimes at ambient temperatures. In some representative embodiments, the complex comprises an electronically bistable cobalt complex functionalized with an optically bistable ligand. A photoisomerization-induced spin-charge excited state (PISCES) process can occur, resulting in the direct observation of light-induced spin state switching at room temperature in the solid state.

### CROSS REFERENCE TO RELATED APPLICATIONS

This application is a continuation-in-part under 35 U.S.C. § 120 of International Application No. PCT/CA2016/050892, filed on Jul. 28, 2016, which claims the benefit of and priority to earlier filed U.S. Provisional Application No. 62/293,251, filed on Feb. 9, 2016, and U.S. Provisional Patent Application No. 62/198,482, filed on Jul. 29, 2015; each of these prior applications is incorporated by reference herein in its entirety.

### FIELD

The present disclosure concerns embodiments of magnetically and electronically bistable complexes, devices comprising such complexes, and methods of making and using the same.

### BACKGROUND

The requirement for improved methods of storing and processing data has led to intense research into quantum information processing technologies. Whereas conventional electronics utilize binary digits, quantum information processing relies on a two-state quantum system, such as photon polarization or electron spin, to form a “qubit.” Entanglement and superposition of qubits leads to the generation of an infinite number of states, leading to an exponential increase in information storage and processing capabilities. To be useful, however, a qubit must be externally controllable and environmentally isolated from the bath. Optical methods for injection, detection, and manipulation of spin eigenstates on ultrafast timescales in nitrogen vacancies of carbon materials, doped spinels, garnets, and colloidal quantum dots highlight the advantages of an all-optical protocol for quantum information processing and spintronics applications.

Controllable quantum systems are under active investigation for quantum computing, secure information processing, quantum modeling, and nonvolatile memory. The optical and electrical manipulation of spin quantum states provides an important strategy for quantum control with both temporal and spatial resolution. Challenges in increasing the lifetime of directly observed photoinduced or electric-field induced magnetic states at T>200 K in the solid state have hindered progress towards utilizing photomagnetic and electronically bistable materials in quantum device architectures. In addition, no magnetically bistable system exists which can be triggered by light or electric field in the solid state at room temperature at the single molecule level exists to date. Single molecular complexes are in the 1-5 nm size regime, and allow for high density nonvolatile memory applications. Thus, there exists a need in the art for systems that have extended lifetimes of magnetic states and that allow optical or electrical gating of spin states in controllable media, such as the solid state at room temperature.

### SUMMARY

Disclosed herein are embodiments of complexes that exhibit electronic and magnetic bistability and can be switched between two electrical or magnetic states by external stimuli, such as light, via a ligand-mediated process. In some embodiments, the disclosed complexes are solid state magnetically bistable complexes that exhibit a photoisomerization-induced spin-charge excited state (“PISCES”) process at room temperature when in organic thin films. Further disclosed are devices comprising the disclosed complexes, such as magnetic tunnel junctions, transistors, arrays, light-induced memory-based devices, and the like. In particular disclosed embodiments, magnetic tunnel junctions comprising a photomagnetic layer comprising a magnetically bistable complex or cluster thereof, wherein the magnetically bistable complex comprises an optically bistable photoisomerizable component and an electronically bistable metal-containing component; wherein the optically bistable photoisomerizable component is coupled to a metal of the electronically bistable metal-containing component. The magnetic tunnel junctions can further comprise a tunnel barrier layer positioned adjacent or substantially adjacent to the photomagnetic layer and a ferromagnetic layer positioned adjacent or substantially adjacent to the tunnel barrier layer. The photomagnetic layer can comprise any of the disclosed complexes and/or clusters of such complexes. In some embodiments, the magnetic tunnel junctions can further comprise one or more electrode layers positioned adjacent to or substantially adjacent to the photomagnetic layer and/or the ferromagnetic layer. In yet additional embodiments, the magnetic tunnel junctions can further comprise a pinning layer, a reference layer, and/or a multilayer structure layer. In some embodiments, the photomagnetic layer can be embedded in a transistor architecture positioned adjacent to an electrode or back gate.

The foregoing and other objects, features, and advantages of the present disclosure will become more apparent from the following detailed description, which proceeds with reference to the accompanying figures.

### BRIEF DESCRIPTION OF THE DRAWINGS

FIG. 1 is a schematic diagram illustrating optical switching of spin states as observed in a representative photochromic cobalt-dioxolene complex by a photoisomerization-induced spin-charge excited state (PISCES) process.

FIG. 2 is an X-ray crystal structure of a representative complex at 90 K.

FIG. 3 is a graph of absorbance (a.u.) as a function of wavelength (nm) illustrating the conversion from the hs-Co(II) state (104/106, as depicted in FIG. 1) at 350 K to the ls-Co(III) state (100/102, as depicted in FIG. 1) for the complex illustrated in FIG. 2 with decreasing temperature in a drop-cast thin film as indicated by an increase in the ls-Co(III)-based LMCT band in the NIR region (* denotes signal due to background correction).

FIG. 4 is a graph of magnetic moment (χ_{M}T) as a function of temperature (K) illustrating the temperature dependence of the magnetic moment in the polycrystalline state at 10,000 Oe (red) and in toluene solution as measured by Evan's method (blue) in which ls-Co(III) to hs-Co(II) conversion occurs with increasing temperature.

FIG. 5 is a graph of absorbance (a.u.) as a function of wavelength (nm) illustrating the effects of steady-state irradiation of a toluene solution of the representative complex embodiment illustrated in FIG. 2 with visible light (450-550 nm), which leads to conversion from the ring-opened (referred to herein as “RO”) form (100/106, as depicted in FIG. 1) to the ring-closed (referred to herein as “RC”) form (102/104, as depicted in FIG. 1), with a decrease in RO π-π* transition at 555 nm and increase in the hs-Co(II) MLCT transition at 800 nm (inset).

FIG. 6 is a graph of absorbance (a.u.) as a function of time (minutes) illustrating the high fatigue resistance of the representative complex embodiment illustrated in FIG. 2, as shown by minimal decrease in the absorbance intensity of the RO π-π* band at 555 nm over 15 cycles.

FIG. 7 is a graph of peak area RO (a.u.) as a function of time (seconds) illustrating the change in peak area as a function of time for the RO π-π* band [“b”] and the hs-Co(II) MLCT band [“a”] upon visible irradiation; the inset shows the Lorentzian deconvolution [▬] and experimental [□] data for a trace from the UV-vis spectrum.

FIG. 8 is a graph of absorbance (a.u.) as a function of wavelength (nm) illustrating the photoisomerization of a thin film of the representative complex embodiment illustrated in FIG. 2 upon visible irradiation, which induces a decrease in the ls-Co(III)-based CT band at ˜2500 nm in the NIR region.

FIG. 9 is a schematic diagram illustrating how the changes in charge/spin state caused by photoisomerization give rise to changes in magnetization.

FIG. 10 is a graph of magnetic moment (χ_{M}T) as a function of cycle index illustrating the changes in the magnetic moment at 290, 300, and 310 K over several cycles of visible irradiation followed by thermal relaxation.

FIG. 11 is a graph of magnetic moment as a function of time (seconds) illustrating the formation of the photostationary state by irradiation at 310 K; a PISCES conversion results in an increase in magnetization, and a photostationary state is reached within 200 s; in this embodiment, magnetization relaxation occurs via thermal ligand relaxation to the original χ_{M}T value with a rate constant of k_{obs}=0.1 s⁻¹.

FIG. 12 provides a theoretical model for the photoisomerization-induced spin-charge excited state (PISCES) mechanism by illustrating model curves representing the mole fraction of hs-Co(II) as a function of T for the RC and RO forms of the representative complex illustrated in FIG. 2; theoretical T_{1/2} values can be derived from effective reduction potentials of the two states of the photoisomerizable ligand; PISCES is achieved at ˜300 K through visible-light induced photoisomerization from the RO to the RC form with an increase in magnetization due to population of the hs-Co(II) state; thermal relaxation or UV irradiation leads to repopulation of the RO form, and a decrease in magnetization.

FIG. 13 illustrates relative ground-state energies modeled at the UB3LYP/6-311G(d,p) level (not to scale); the relative energies support a thermodynamically driven PISCES process.

FIG. 14 is an ¹H NMR spectrum of the representative complex illustrated in FIG. 2 in toluene-d₈ at 300 MHz at 300 K (wherein S denotes the resonances from the solvent (toluene-d₈)).

FIG. 15 is an ¹H NMR spectrum providing tentative assignment of the key ¹H NMR resonances that allow determination of relative concentrations of RO and RC forms of the representative complex at 300 K in solution as illustrated in FIG. 2.

FIG. 16 is a graph of absorbance (a.u.) as a function of concentration (mol L⁻¹) illustrating the determination of the extinction coefficient of the representative complex of FIG. 2 at 555 nm in toluene; the black line corresponds to the best linear fit; this results in an ε˜47200 M⁻¹·cm⁻¹ for the RO form based on the thermal equilibrium constant of RO/SO form of K_{T}=4.0 derived from NMR data in toluene solution.

FIG. 17 is an electronic absorption spectrum of the representative complex illustrated in FIG. 2 in the thin-film state with decreasing temperature (300 to 200 K) in which the RO π-π* transition increases with increasing population of the RO state; an isosbestic point is observed at 575 nm.

FIG. 18 is an electronic absorption spectrum of the representative complex illustrated in FIG. 2 in toluene solution (10 M) with decreasing temperature (300 to 196 K) in which the MLCT transition decreases reversibly with decreasing population of the hs-Co(II) state.

FIG. 19 is a plot of the thermal hysteresis associated with the thermal dependence of χ_{M}T for the representative complex of FIG. 2 as a polycrystalline sample at 10,000 Oe upon warming from 200 to 350 K (▪) and cooling from 350 K to 200 K (□).

FIG. 20 is a first-order monoexponential fit (▬) of the experimental absorbance (▪) at 555 nm for a toluene solution of the representative complex of FIG. 2 at ˜300 K upon thermal relaxation is obtained after generating a photostationary state with steady-state visible irradiation (k_{obs}=0.01 s⁻¹).

FIG. 21 is a graph of peak area RO (a.u.) illustrating the peak areas of the combined RO π-π* ν(1) and ν(2) bands [“b”] and of the hs-Co(II) MLCT band [“a”] as a function of irradiation with visible light.

FIG. 22 is a graph of peak area RO (a.u.) illustrating the peak areas of the combined RO π-π* ν(1) and ν(2) bands [“b”] of thermal relaxation in the dark as a function of time.

FIG. 23 is a graph of first-order monoexponential fits (▬) of the change in peak areas (▪) as a function of time obtained from deconvolution of the spectra of the representative complex of FIG. 2 in toluene solution at ˜300 K upon thermal relaxation after generating a photostationary state with steady-state visible irradiation; the total peak area of the two dominant vibronic bands, ν(1) and ν(2), of the RO π-π* transition (k_{obs}=0.01 s⁻¹) is illustrated.

FIG. 24 is a graph of first-order monoexponential fit (▬) of the change in peak areas (▪) as a function of time obtained from deconvolution of the spectra of the representative complex of FIG. 2 in toluene solution at ˜300 K upon thermal relaxation after generating a photostationary state with steady-state visible irradiation. This fit illustrates the peak area of the hs-Co(II) MLCT band (k_{obs}=0.01 s⁻¹).

FIG. 25 illustrates first-order monoexponential fit (▬) of the experimental absorbance (▪) at 4250 cm⁻¹ (2500 nm) with k_{obs}=0.0150 in toluene solution.

FIG. 26 illustrates first-order biexponential fit (▬) of the experimental absorbance (▪) at 2500 nm for a thin film of the representative complex of FIG. 2 upon thermal relaxation after generating a photostationary state with steady-state visible irradiation (k_{obs}=0.03 s⁻¹ (32%); 0.1 s⁻¹ (68%)).

FIG. 27 illustrates the temperature dependence of the magnetic moment of a thin-film sample of the representative complex of FIG. 2 between 305 and 330 K determined in 0.1 K steps.

FIG. 28 illustrates the kinetics of thermal relaxation of the magnetic moment (χₘT) in a thin-film sample of the representative complex of FIG. 2 at 310 K after generating a photostationary state via steady-state irradiation with visible light (5 mW·mm⁻²) for 180 seconds; the first-order monoexponential fit (▬) of the experimental χ_{M}T data (▬) with k_{obs}=0.1 s⁻¹ (left) is illustrated.

FIG. 29 illustrates the first-order biexponential fit (▬) of the experimental χ_{M}T data (▬) with k_{obs}=0.04 s⁻¹ (28%); 0.15 s⁻¹ (72%) related to the embodiment described in FIG. 32.

FIG. 30 illustrates the dependence of the magnetic response to laser power change in the χ_{M}T product of a thin-film sample of the representative complex of FIG. 2 at 310 K upon steady-state irradiation with multiline visible light and thermal relaxation in the dark; the irradiation in the first three cycles was performed with a power of 5 mW·mm⁻² and the following seven cycles with a power of 2.5 mW·mm⁻².

FIG. 31 is a NIR spectrum of the representative complex of FIG. 2 in toluene solution at ˜300 K before and after steady-state visible irradiation for 2 minutes (bold black traces, lines 22 and 24, respectively), and over the course of thermal relaxation during the next 11 min (lines 26-36); the asterisks denote signals caused by an imperfect toluene background correction.

FIG. 32 is a graph of absorbance (a.u.) as a function of time (seconds) illustrating the kinetics of thermal relaxation of the representative complex of FIG. 2 at 4250 cm⁻¹ in toluene solution after generating a photostationary state upon irradiation with visible light for 180 seconds.

FIG. 33 illustrates the correlation between critical temperature, T_{1/2}, for the ls-Co(III)→hs-Co(II) process in representative Co(3,5-DTBQ)₂(NN) complexes (experimentally determined in toluene) with the reduction potential of their respective diimine ligand (experimentally determined in CH₃CN); a linear least-squares fit of the data for the four ligands from the original study is shown, with extrapolated data points for the RC and RO forms of APSO.

FIG. 34 provides a basic schematic diagram for the interaction of σ-donor (a) and π-acceptor (b) ligands with metal d orbitals in an octahedral coordination environment; wherein in each case, the Oₕ ligand field splitting, Δ, is shown.

FIG. 35 is an x-ray structure representation of a representative complex cluster in which two photochromes are bound to a tetranuclear cobalt cluster.

FIG. 36 is an x-ray structure representation of another representative complex cluster in which two different photochromes are bound to a tetranuclear cobalt cluster.

FIG. 37 is a synthetic scheme showing a representative method for making a tetranuclear cobalt cluster with two bound photochromes.

FIG. 38 is an absorbance spectrum showing the ability of a representative complex cluster to exhibit optical gating, the change in absorbance spectra in toluene solution at 298 K was detected with visible irradiation in a tetranuclear cobalt photochrome complex and thermal relaxation; the absorbance at 555 nm was fit to a biexponential decay (inset).

FIG. 39 is a spectrum exhibiting the thermal relaxation of the a representative APSO-containing cluster in the solid state following visible irradiation (550 nm), in which the thermal relaxation was fit to a first order biexponential fit with two rate constants (inset), consistent with two photochromes bound to the cluster.

FIGS. 40A and 40B are absorbance spectra of another representative complex cluster that exhibits optical gating (FIG. 40A) and showing the absorbance peaks for different transitions within the complex cluster (FIG. 40B).

FIG. 41 is a graph of magnetic moment as a function of temperature illustrating the temperature dependence of the magnetic moments of a parent cluster (a), a representative APSO-containing complex cluster (b), and a representative IPSO-containing complex cluster (c), each of which is in the solid state; the decrease in magnetic moment may be attributed to a gradual transition between high spin Co(II) and low spin Co(III).

FIG. 42 is a graph of magnetic moment as a function of temperature in solution (CD₂Cl₂, 200-300 K) as determined by Evan's method illustrating the temperature dependence of the magnetic moments of a parent cluster (a), a representative APSO-containing complex cluster (b), and a representative IPSO-containing complex cluster (c), each of which is in a solution state.

FIGS. 43A-43C are absorbance spectra obtained from analysis of a parent cluster (FIG. 43A), a representative APSO-containing complex cluster (FIG. 43B), and a representative IPSO-containing complex cluster (FIG. 43C).

FIGS. 44A and 44B are electronic absorption spectra showing results from a charge-transfer induced spin transition process for a representative APSO-containing complex cluster (FIG. 44A), and a representative IPSO-containing complex cluster (FIG. 44B) in which the deconvolution of the representative spectra into distinct transitions are shown.

FIGS. 45A and 45B are spectra showing the temperature dependence of the pi-pi* band of a representative APSO-containing cluster in toluene solution from 300K to 200K in 10K increments with decreasing temperature, in which the highest intensity band corresponds to 300K, and lowest intensity band corresponds to 200K (FIG. 45A) and the temperature dependence of the MLCT band of the cluster in toluene solution from 300K to 200K in 10K increments with decreasing temperature in which the lowest intensity band corresponds to 300K, and highest intensity band corresponds to 200K.

FIG. 46 is an illustration of a representative magnetic tunnel junction embodiment disclosed herein.

FIG. 47 is an illustration of another representative magnetic tunnel junction embodiment disclosed herein.

FIG. 48 is an illustration of a representative memory storage cell comprising a magnetic tunnel junction as described herein.

FIGS. 49A and 49B show the magneto-optical response (in V) of a CoAPSO thin film on graphene/SiO₂ substrate as a function of external magnetic field (+3000 to −3000 to +3000 Oe) without irradiation (FIG. 49A) and after irradiation (FIG. 49B), wherein irradiation is carried out at 550 nm.

FIGS. 50A and 50B show the changes in electrical resistivity of an organic thin film of CoAPSO measured by a two-point probe measurement, −3 to 3 V with 0.2 V increments with conversion to the SO-hs-Co(II) state by annealing (Chip A) and by irradiation at 550 nm light (FIG. 50B), wherein a decrease in resistivity is observed with conversion to the SO-hs-Co(II) state upon irradiation.

FIG. 51 is a schematic illustration of a cross-section of a PCM cell embodiment disclosed herein.

### DETAILED DESCRIPTION

### I. Explanation of Terms

As used in this application and in the claims, the singular forms “a,” “an,” and “the” include the plural forms unless the context clearly dictates otherwise. Additionally, the term “includes” means “comprises.” Further, the term “coupled” does not exclude the presence of intermediate elements between the coupled items.

The present disclosure is directed toward all novel and non-obvious features and aspects of the various disclosed embodiments, alone and in various combinations and sub-combinations with one another. The disclosed systems, compounds, complexes, and methods are not limited to any specific aspect or feature or combinations thereof, nor do the disclosed systems, compounds, complexes, and methods require that any one or more specific advantages be present or problems be solved. Any theories of operation are to facilitate explanation, but the disclosed systems, compounds, complexes, and methods are not limited to such theories of operation.

Although the operations of some of the disclosed methods are described in a particular, sequential order for convenient presentation, it should be understood that this manner of description encompasses rearrangement, unless a particular ordering is required by specific language set forth below. For example, operations described sequentially may in some cases be rearranged or performed concurrently. Moreover, for the sake of simplicity, the attached figures may not show the various ways in which the disclosed systems, compounds, complexes, and methods can be used in conjunction with other systems, compounds, complexes, and methods. Additionally, the description sometimes uses terms like “produce” and “provide” to describe the disclosed methods. These terms are high-level abstractions of the actual operations that are performed. The actual operations that correspond to these terms will vary depending on the particular implementation and are readily discernible by one of ordinary skill in the art.

In some examples, values, procedures, or devices are referred to as “lowest,” “best,” “minimum,” or the like. It will be appreciated that such descriptions are intended to indicate that a selection among many used functional alternatives can be made, and such selections need not be better, smaller, or otherwise preferable to other selections.

Examples are described with reference to directions indicated as “above,” “below,” “upper,” “lower,” and the like. These terms are used for convenient description, but do not imply any particular spatial orientation.

Unless otherwise indicated, all numbers expressing quantities of components, molecular weights, percentages, temperatures, times, and so forth, as used in the specification or claims are to be understood as being modified by the term “about.” Accordingly, unless otherwise indicated, implicitly or explicitly, the numerical parameters set forth are approximations that can depend on the desired properties sought and/or limits of detection under standard test conditions/methods. When directly and explicitly distinguishing embodiments from discussed prior art, the embodiment numbers are not approximates unless the word “about” is recited. Furthermore, not all alternatives recited herein are equivalents.

A wavy line (“ [symbol] ”) indicates a bond disconnection. A dashed line (“ - - - ”) illustrates that a bond may be formed at a particular position.

To facilitate review of the various embodiments of the disclosure, the following explanations of specific terms are provided:

Adjacent/Substantially Adjacent: Components of the devices disclosed herein, particularly layers of the magnetic tunnel junctions disclosed herein, can be positioned adjacent to one another and thus are in direct contact; in embodiments wherein the components are substantially adjacent, they can have one or more layers of a third, fourth, fifth (and so on) component positioned between the two layers that are substantially adjacent. Solely by way of example, a magnetic fixed layer can be adjacent to the tunnel barrier layer so that they are in direct contact, or it can be substantially adjacent such that there are 1 to 3 additional layers in between the magnetic fixed layer and the tunnel barrier layer that are different from these two layers.

Aliphatic: A hydrocarbon, or a radical thereof, having at least one carbon atom to 50 carbon atoms, such as one to 25 carbon atoms, or one to ten carbon atoms, and which includes alkanes (or alkyl), alkenes (or alkenyl), alkynes (or alkynyl), including cyclic versions thereof, and further including straight- and branched-chain arrangements, and all stereo and position isomers as well.

Alkyl: A saturated monovalent hydrocarbon having at least one carbon atom to 50 carbon atoms, such as one to 25 carbon atoms, or one to ten carbon atoms, wherein the saturated monovalent hydrocarbon can be derived from removing one hydrogen atom from one carbon atom of a parent compound (e.g., alkane). An alkyl group can be branched, straight-chain, or cyclic (e.g., cycloalkyl).

Alkenyl: An unsaturated monovalent hydrocarbon having at least two carbon atoms to 50 carbon atoms, such as two to 25 carbon atoms, or two to ten carbon atoms, and at least one carbon-carbon double bond, wherein the unsaturated monovalent hydrocarbon can be derived from removing one hydrogen atom from one carbon atom of a parent alkene. An alkenyl group can be branched, straight-chain, cyclic (e.g., cycloalkenyl), cis, or trans (e.g., E or Z).

Alkynyl: An unsaturated monovalent hydrocarbon having at least two carbon atoms to 50 carbon atoms, such as two to 25 carbon atoms, or two to ten carbon atoms and at least one carbon-carbon triple bond, wherein the unsaturated monovalent hydrocarbon can be derived from removing one hydrogen atom from one carbon atom of a parent alkyne. An alkynyl group can be branched, straight-chain, or cyclic (e.g., cycloalkynyl).

Aryl: An aromatic carbocyclic group comprising at least five carbon atoms to 15 carbon atoms, such as five to ten carbon atoms, having a single ring or multiple condensed rings, which condensed rings can or may not be aromatic provided that the point of attachment is through an atom of the aromatic carbocyclic group.

Charge Transfer Induced Spin Transition (CTIST): A phenomenon that occurs in electronically bistable metal complexes in which two distinct oxidation states of a bound transition metal are close in energy, and can be interconverted through either metal-to-metal or metal-to-ligand charge transfer processes. Application of an external stimuli (e.g., pressure, temperature, light, etc.) may lead to inducement of the charge transfer process, which induces a change in oxidation state at one or more of the bound metal centers. If this change in oxidation state leads to a change in spin state at the said metal center, the process is considered a CTIST process.

Coupled: Two or more components can be coupled electrostatically, covalently, through pi-backbonding, ionically, or the like. In particular disclosed embodiments, metals disclosed herein can be covalently bound to one or more ligands or can be coupled such that lone pair electrons from a ligand functional group populate an empty orbital of the metal

Heteroaliphatic: An aliphatic group comprising at least one heteroatom to 20 heteroatoms, such as one to 15 heteroatoms, or one to 5 heteroatoms, which can be selected from, but not limited to oxygen, nitrogen, sulfur, selenium, phosphorous, and oxidized forms thereof within the group.

Heteroalkyl/Heteroalkenyl/Heteroalkynyl: An alkyl, alkenyl, or alkynyl group (which can be branched, straight-chain, or cyclic) comprising at least one heteroatom to 20 heteroatoms, such as one to 15 heteroatoms, or one to 5 heteroatoms, which can be selected from, but not limited to oxygen, nitrogen, sulfur, selenium, phosphorous, and oxidized forms thereof within the group.

Heteroaryl: An aryl group comprising at least one heteroatom to six heteroatoms, such as one to four heteroatoms, which can be selected from, but not limited to oxygen, nitrogen, sulfur, selenium, phosphorous, and oxidized forms thereof within the ring. Such heteroaryl groups can have a single ring or multiple condensed rings, wherein the condensed rings may or may not be aromatic and/or contain a heteroatom, provided that the point of attachment is through an atom of the aromatic heteroaryl group.

Heteroatom-Containing Functional Group: Functional groups selected from, but not limited to, hydroxyl (—OH), thiol (—SH), isothiocyanate (—NCS), isocyanate (—NCO), amine (—NH₂), halogen (I, Br, Cl, F), phosphate (—OP(O)OH₂), phosphoryl (—P(O)(OH)₂), carbonothioyl (—C(S)H, sulfino (—S(O)OH), sulfo (—SO₃H), azide (—N₃), nitrile (—CN), isonitrile (—N+C), and nitro (—NO₂).

Organic-Metal Complex: An organic-metal or coordination complex consists of a central atom or ion, which is usually a transition metal, lanthanide, or rare earth and is called the coordination center, and a surrounding array of covalently or ionically bound molecules or ions that are known as ligands.

PISCES Process: A Photoisomerization-Induced Spin-Charge Excited State process whereby reversible changes in charge and spin state at a centrally bound metal center are induced optically in complexes that are electronically bistable described herein. Optical inducement occurs indirectly through structural changes in a bound photochromic ligand, and can be carried out using optical excitation methods, such as UV light irradiation, visible light irradiation, or both. Changes in charge and spin state of the complexes described herein, however, are not limited to being activated only by optical inducement. Other methods of inducement are contemplated, such as inducement caused by changes in electric field, dielectric changes, solvation changes, dielectric changes of a host polymer matrix, heat, or combinations thereof.

### II. Overview

Disclosed herein are embodiments of complexes that are capable of being optically or electrically excited to manipulate the spin quantum states or charge states of the complexes. The ability to manipulate the spin quantum states provides quantum control with temporal and spatial resolution. The disclosed complexes can be used as optically-gated or electrically-gated magnetic materials in quantum devices. The change in magnetic state can lead to changes in resistivity through the material. The disclosed complexes exhibit increased lifetimes of photoinduced magnetic states, as compared to, for example, a parent complex (that is, a complex that does not comprise the photoisomerizable ligands), in which the photoinduced magnetic state has a lifetime of 2 ns in solution at 300 K, compared to the disclosed complexes, which exhibit a lifetime of 10 seconds at 300 K—an increase of 6 orders of magnitude). Other known metal complexes (classical electronically bistable complexes) for which direct magnetization as a function of thermal relaxation after light excitation have been measured exhibit lifetimes that are rapid (ps, ns, μs), but only at cryogenic temperatures. The complexes described herein are unique in that an indirect ligand-mediated process is used to switch the state of and electronically bistable metal centers, a nonclassical electronically bistable complex. These complexes are capable of reversible light-induced magnetization in both (1) solution or dilute media, such as polymer compositions; and (2) in the solid state, such as in thin films (e.g., thin films processed by drop casting, spin coating, sputtering, or the like). In addition, the activity of the complexes occurs in the single molecule state, and does not rely on cooperativity in the solid state for observation of photoinduced changes in magnetization. The activity of the complexes therefore can be scaled to the single molecule level on surfaces. As indicated above, the disclosed complexes can be incorporated into solution/media-based compositions and in solid-state thin films. The disclosed complexes also can be manipulated at room temperature in the solid state. Such complexes therefore are useful in a variety of applications, such as, but not limited to, optical coatings, glazings, holographic recording media, rewritable paper, optical logic gates, switchable dielectrics, optically-actuated organic electronics, optically switchable charge storage devices, electrically-actuated organic electronics, electrically switchable charge storage devices, scalable magnetoresistive elements for memory or data processing, photoactive catalysts, and functional MRI for biomedical and biosensing applications. While certain embodiments described herein illustrate that the complexes can exhibit activity induced by changes in light (e.g., optical inducement), the disclosed complexes also can be activated by other suitable methods that induce shifts in the electronic state of the photochrome component of the complex. For example, dielectric changes, electric field application changes, solvation changes, dielectric changes of a host polymer matrix, or combinations thereof can be used to activate the complexes. By shifting the electronic state of the photochrome, it is possible to cause shifts in the dipole moment of the complex, which may be useful for modulating charge mobility and exciton migration/dissociation in organic electronic materials for organic transistors, and organic photovoltaics. In additional embodiments, the change in spin state triggered by light during biologically relevant events may lead to changes in contrast in MRI or other magnetic resonance imaging techniques that allow temporal and spatial resolution for magnetic imaging of biological processes. In yet additional embodiments, the change in electronic state triggered by changes in membrane potential of single cells or multicellular organisms during biologically relevant events may also lead to a magnetic response that can be monitored by MRI or other magnetic resonance techniques.

Conventional materials that exhibit photomagnetic effects can only exhibit suitable lifetimes of photoinduced spin states when cooled to cryogenic temperatures. To date there has been no ability to obtain single molecule complexes exhibiting increased lifetimes in spin states at room temperature and in the solid state, particularly optically gated (that is, optically controlled) changes in magnetization. The barrier to achieving optically induced spin states (i) in isolated molecules, (ii) in the solid state, and (iii) at ambient temperatures arises from challenges associated with controlling the lifetime of metal-centered excited states, optical density, cooperative interactions, solvation, and site defects of metal-organic lattices. The novel complexes described herein, however, can be used in combination with fundamentally different strategies of generating photoinduced spin states. In some embodiments, a Photoisomerization-Induced Spin-Charge Excited State (referred to herein as “PISCES”) process can be used. In some embodiments, the PISCES process can involve coupling ligand field switching to spin-coupled charge transfer. By incorporating a ligand that undergoes optical switching into a class of electronically bistable metal complexes, optically induced and reversible changes in charge and spin state occur. In yet additional embodiments, the complexes can be activated/induced using other methods, such as by dielectric changes, electric field application changes, solvation changes, dielectric changes of a host polymer matrix, or combinations thereof. Due to the surprising and unusually long lifetime of the photoinduced charge/spin state obtained using the novel complexes described herein, the changes in oxidation and spin states are directly observable for the first time by, for example, magnetometry, and electronic absorption spectroscopy at ambient temperatures and/or 300 K-320 K in the solid state.

### III. Complexes

Disclosed herein are complexes capable of being activated into different charge and spin states using light changes, dielectric changes, electric field application changes, solvation changes, dielectric changes of a host polymer matrix, or combinations thereof. In particular disclosed embodiments, the complexes described herein can undergo a PISCES process, as described herein. As such, the complexes can exist in different magnetic or charge states in view of the various components making up the complexes. The complexes can comprise one or more transition metals (or transition metal ions), one or more ligands that may or may not be redox active, and one or more photoisomerizable ligands. The complexes described herein can be converted to alternate complex species (thus forming a system comprising different complex species that can interconvert) by changing the driving force for charge transfer between a ligand and the metal with which it is associated, or between two metal complexes through ligand-mediated events, such as ligand structural changes induced by light or thermal processes, spin-charge excitation, or combinations thereof. Such complexes can be formed as distinct molecular complexes, clusters, and polymeric 1D, 2D, and 3D materials.

The components of the complexes disclosed herein are described in more detail below. In particular embodiments, the complexes comprise an optically bistable photoisomerizable component and an electronically bistable metal-containing component, which can comprise a charge transfer induced spin transition complex (or a CTIST complex, which is a complex exhibiting charge transfer induced spin transitions or a charge transfer coupled spin transition process), a bimetallic cyanide, and/or an organic-metal complex (e.g., a complex having a formula M(L^{a})_{z}(L^{r})_{y}, wherein M is a metal selected from a transition metal, a lanthanide metal, a rare earth metal, or a mixture or alloy thereof; L^{r} is a redox active ligand capable of charge transfer with M, L^{a} is an ancillary ligand, and each of y and z is an integer selected from 1 to 8). In some embodiments, the bistable metal-containing component typically comprises at least one metal, one or more ancillary ligands, one or more redox active ligands, and any combination thereof. In particular disclosed embodiments, the complexes comprise at least one metal, a photoisomerizable ligand, and one or more redox active ligands. In some embodiments, the complexes are electronically bistable complexes that include metal complexes of non-innocent redox active ligands that exhibit metal-to-ligand charge transfer processes, including but not limited to any combination of a metal center and redox active ligand such as metal-semiquinones, metal-anilate complexes, and metal-tetrathiafulvalene complexes, comprising metals (or metal ions) selected from Ni, Co, Fe, Mn, or combinations thereof.

In some embodiments, complexes described herein can have structures satisfying Formula I.

M_{w}Pₓ(L^{r})_{y}(L^{a})_{z} Formula I

With respect to Formula I, M can be selected from a transition metal, a lanthanide metal, a rare earth metal, or an alloy or mixture thereof; L^{r} is a redox active ligand capable of undergoing ligand-to-metal charge transfer processes (“LMCT processes”) with M; L^{a} is an ancillary ligand capable of facilitating a metal-to-metal charge transfer process (“MMCT processes”) between two possible metal centers M; P is a photoisomerizable ligand capable of forming a complex with the metal and that can undergo an isomerization change upon exposure to light; and each of w, x, y, and z are integers independently selected from 1 to 8. In some embodiments, M, L^{a} and/or L^{r}, P are coupled together to form a metal complex that exhibits (i) photochromism and (ii) two or more electronically bistable states that interconvert through a metal-to-ligand or metal-to-metal charge transfer processes. The coexistence of these two properties can facilitate use of the complexes in a PISCES-based process and/or device utilizing a PISCES process.

In particular disclosed embodiments, the complex can comprise two or more different metal species, wherein the two or more different metals are coupled to one another through a bridging ligand (L^{b}). The two or more different metals (M^{a} and M^{b}) can further be coupled to one or more additional ancillary ligands (L^{a}) and/or redox active ligands (L^{r}). In such complexes, metal-to-metal charge transfer processes can also give rise to electronic bistability. When coupled with a photoisomerizable ligand, such complexes can exhibit PISCES processes. In some embodiments, complexes comprising two or more different metals can have a structure satisfying Formula IIA and/or Formula IIB.

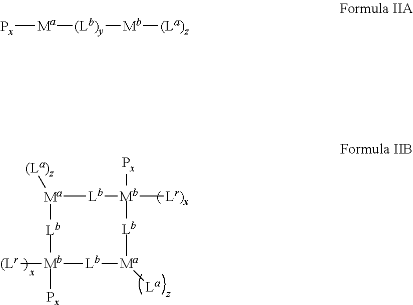

With reference to Formulas IIA and IIB, each M^{a} independently can be selected from Ti, V, Co, Mo, Cr, Fe, Mn, Ni, Zr, Mo, W, Cu, or any combination or an alloy thereof; each M^{b} independently can be selected from a metal that may or may not be the same metal as M^{a}, with particular embodiments using at least one M^{b} that is different from M^{a}; each L^{b} independently can be selected from cyano or N₃; each L^{a} independently can be an ancillary ligand; each P independently can be a photoisomerizable ligand; and each of x, y, and z are integers independently selected from 1 to 8.

In some embodiments, the complexes disclosed herein can have a structure satisfying general Formula III, illustrated below, or a cluster of such complexes.

PₓM_{y}(L^{r})_{z} Formula III

With reference to Formula III, each P independently can be a photoisomerizable ligand that can be monodentate or bidentate; each M independently can be a metal selected from the series of first row transition metals; each L^{r} independently can be a redox active ligand capable of undergoing a charge transfer with the metal; and each x, y, and z independently are integers selected from 1 to 8. In particular disclosed embodiments, x can be an integer selected from 1 to 3, such as 1, 2, or 3; y can be an integer selected from 1 to 8, such as 1 to 6, or 1 to 4, such as 1, 2, 3, or 4; and z can be an integer selected from 1 to 8, such as 1 to 6, or 1 to 4, such as 1, 2, 3, or 4.

In particular disclosed embodiments, the metal (or metal ion) of the complexes described herein can be a metal (or metal ion) capable of forming an electronically bistable metal complex, metal-based polymeric network, or a hybrid organic-inorganic complex that is capable of metal-to-ligand charge transfer or metal-to-metal charge transfer processes. In particular disclosed embodiments, the metal (or metal ion) can be selected from any metal capable of forming an electronically bistable metal complex. Such complexes can exist in two electronic states that are close in energy to each other. A change in the relative energy of these two states leads to a change in oxidation state of the metal (or metal ion) center. In particular disclosed embodiments, the change in relative energy can be, but need not be, coupled to a spin transition process. Suitable metals include, but are not limited to, transition metals, lanthanide metals, rare earth metals, or an alloy or mixture thereof. Exemplary metals include, but are not limited to, Ti, V, Co, Mo, Cr, Fe, Mn, Ni, Zr, Mo, W, Cu, or combinations or alloys thereof. In particular disclosed embodiments, the metal(s) are Co, Fe, or combinations or alloys thereof.

The ancillary ligands disclosed herein can be selected from ligands that are capable of undergoing a metal-to-metal charge transfer process and/or that are capable of complexing first row transition metal ions. In particular disclosed embodiments, the ancillary ligands can be selected from cyano ligands, azide ligands, pyrazole ligands, alkoxy ligands, other organic ligands, and combinations thereof. In some embodiments, the ancillary ligands can be organic ligands having a structure satisfying Formula IV.

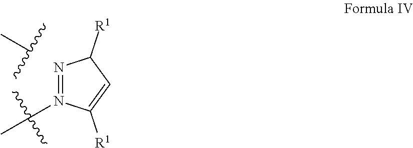

With reference to Formula IV, each R¹ independently can be selected from hydroxyl, aliphatic, aryl, heteroaliphatic, or heteroaryl. In particular disclosed embodiments, R¹ can be hydroxyl, alkoxy, aliphatic, such as alkyl or lower alkyl (e.g., methyl, ethyl, propyl, isopropyl, butyl, isobutyl, tertbutyl, cyclopentyl, cyclohexyl, and the like). In some embodiments, the ancillary ligand is a cyano group, an azide, a pyrazole ligand having a structure

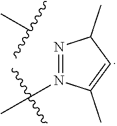

The redox active ligands disclosed herein can be selected from ligands that are capable of undergoing a ligand-to-metal charge transfer process. In particular disclosed embodiments, the redox active ligands can be an organic ligand having a Formula V or a similar compound having a different oxidation state (e.g., a catecholate, a semiquinone, or a quinone).

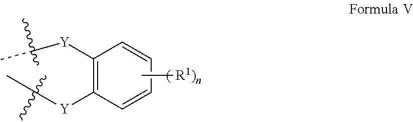

With reference to Formula V, each Y independently can be selected from O, S, or NR^{a}, wherein R^{a} is selected from hydrogen, aliphatic, aryl, heteroaliphatic, or heteroaryl; each R¹ independently can be selected from hydroxyl, aliphatic, aryl, heteroaliphatic, or heteroaryl; and n can be an integer selected from 1 to 4. In particular disclosed embodiments, R¹ can be hydroxyl, alkoxy, aliphatic, such as alkyl or lower alkyl (e.g., methyl, ethyl, propyl, isopropyl, butyl, isobutyl, tertbutyl, cyclopentyl, cyclohexyl, and the like). In some embodiments, the organic ligand is a dioxolene. In particular disclosed embodiments, each Y is oxygen. In yet additional embodiments, each Y is oxygen or hydroxyl, n is 2, and each R¹ independently is lower alkyl. In a particular disclosed embodiment, each Y is oxygen, n is 2, and each R¹ is tert-butyl. In some embodiments, the organic ligand can have a structure

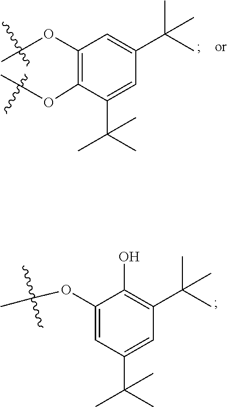 [SMILES: *Oc1cc(C(C)(C)C)cc(C(C)(C)C)c1O* ; *Oc1cc(C(C)(C)C)cc(C(C)(C)C)c1O]

or
a similar compound having a different oxidation state (e.g., a catecholate, a semiquinone, or a quinone).

The photoisomerizable ligands used in the complexes disclosed herein are ligands that are capable of isomerizing upon exposure to light, changes in dielectric of the medium, changes in temperature, or changes in electric field. Isomerization can involve a transition from a ring-closed structure form of the compound to a ring-open structure form of the compound (or vice versa), or a transition from one double bond conformation (e.g., Z or E) to a different double bond conformation (e.g., Z to E or E to Z). In particular disclosed embodiments, the photoisomerizable ligands have structures satisfying Formulas IVA or IVB, illustrated below. As indicated above, ligands having such structures can exist in the ring-closed form, which is illustrated in Formula VIA, or in a ring-open form, which is illustrated in Formula VIB.

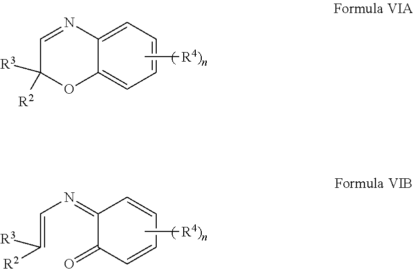

With reference to Formulas VIA and VIB, R² and R³ can combine to form a 5- to 8-membered aliphatic, aromatic, heteroaromatic, or heteroaliphatic cyclic ring or aliphatic or heteroaliphatic bicyclic ring; each R⁴ independently can be selected from a functional group comprising —NH₂, —OH, —OR⁵, —C(O)H, —C(O)OH, —C(O)R⁵, —C(O)OR⁵, —SH, —SR⁵, —P(R⁵)₃, and cyano; or two R⁴ groups can be positioned on adjacent carbons and combined to form a fused aromatic ring, which can be bound to one or more (e.g., 1-8) additional aromatic or heteroaromatic groups comprising one or more heteroatoms selected from N, O, S, or Se; or two R⁴ groups can be positioned on adjacent carbons and combined to form a fused heteroaromatic ring comprising one or more heteroatoms selected from N, O, S, or Se, which can be bound to one or more (e.g., 1-8) additional aromatic or heteroaromatic groups comprising one or more heteroatoms selected from N, O, S, or Se. In particular disclosed embodiments, the photoisomerizable ligand can exist in the closed form illustrated above, or it can exist in the open form, whereby the bond between the spiro carbon and the oxygen atom is broken and the compound has tautomerized to an iminocyclohexadienone-containing compound, or a functionalized iminocyclohexadienone-containing compound (wherein n is 1 or more).

In yet further embodiments, the photoisomerizable ligands can have structures satisfying any one or more of the formulas illustrated below.

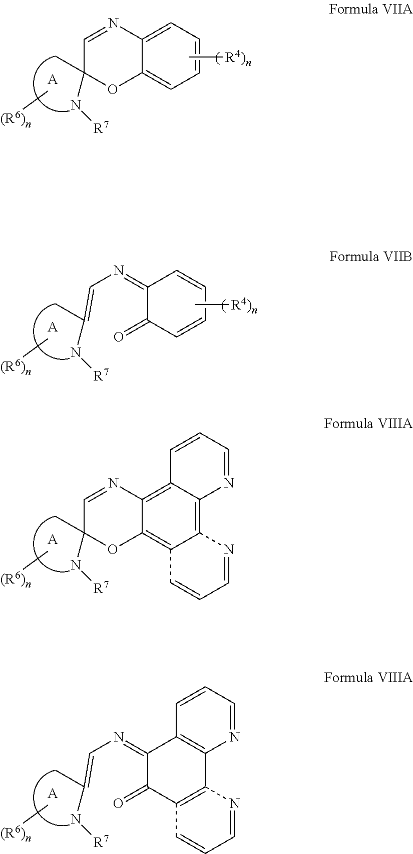

With reference to Formula VIIA and VIIB, each R⁴ independently can be as described above for the formulas described above. With reference to both Formulas VIIA, VIIB, VIIIA, and VIIIB ring A can be a single or bicyclic ring structure comprising the depicted nitrogen atom, such as azahomoadamantyl or indole; each R⁶ can be a heteroatom-containing functional group, aliphatic, heteroaliphatic, aryl, or heteraryl; R⁷ can be hydrogen, a heteroatom-containing functional group (e.g., carboxylic acid, hydroxyl, —NH₂, ketone, or aldehyde), aliphatic, or aryl; and each n independently can be an integer ranging from 0 to 8.

In exemplary embodiments, the photoisomerizable ligands can be selected from any of the following ligands shown in Tables 1A and 1B. In some embodiments, the complexes are not, or are other than, spin transition complexes, such as Fe(II) spin crossover complexes. Such spin transition complexes are not electronically bistable and therefore are not included in the scope of the present disclosure. In an independent embodiment, such as when the redox active ligand is 3,5-di-tert-butylbenzene-1,2-diol, 2,4-di-tert-butyl-6-hydroxycyclohexa-2,5-dien-1-one, or a catecholate, a semiquinone, or a quinone form thereof, and M is cobalt, the photoisomerizable ligand is not, or is other than, 1,3,3-trimethylspiro[indoline-2,2′-[1,4]oxazino[2,3-f][1,10]phenanthroline], which has a structure:

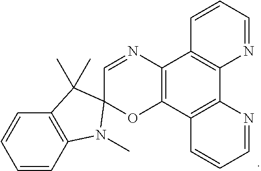 [SMILES: CN1c2ccccc2C(C)(C)C12C=Nc1c(c3cccnc3c3ncccc13)O2]

Such independent embodiments, however, can be used as a component of the devices disclosed herein and/or in the cluster embodiments described below in Table 2.

TABLE 1A
Exemplary Photoisomerizable Ligands

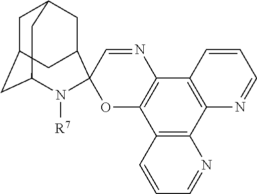

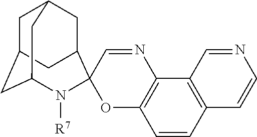

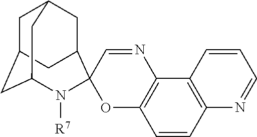

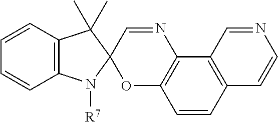

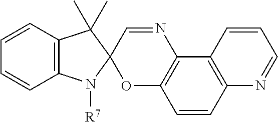

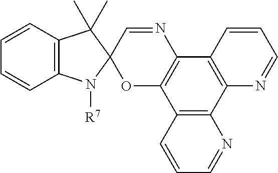

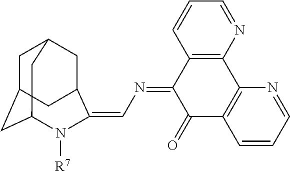

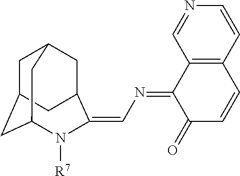

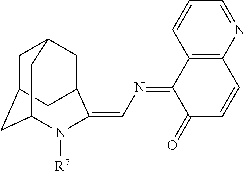

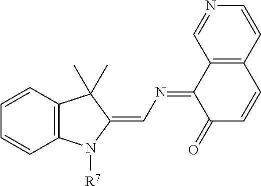

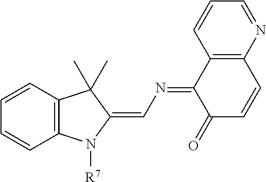

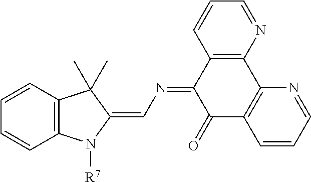

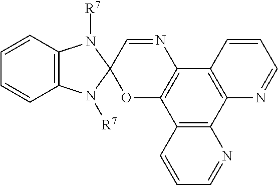

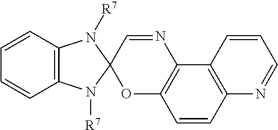

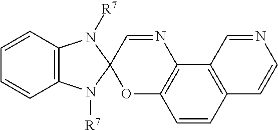

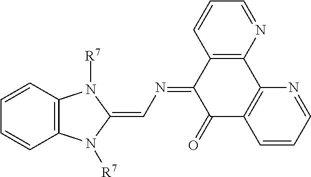

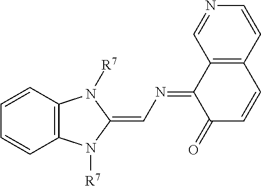

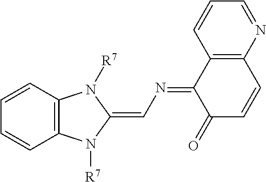

TABLE 1B
Exemplary Photoisomerizable Ligands

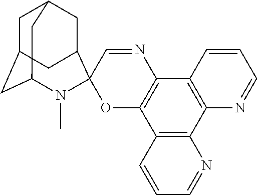 [SMILES: CN1C2CC3CC(C2)CC(C3)C12C=Nc1c(c3cccnc3c3ncccc13)O2]

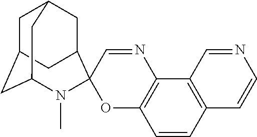 [SMILES: CN1C2CC3CC(C2)CC(C3)C12C=Nc1c(ccc3ccncc13)O2]

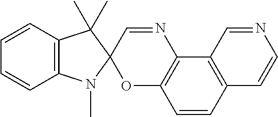 [SMILES: CN1c2ccccc2C(C)(C)C12C=Nc1c(ccc3ccncc13)O2]

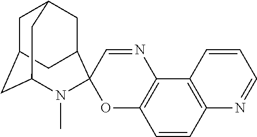 [SMILES: CN1C2CC3CC(C2)CC(C3)C12C=Nc1c(ccc3ncccc13)O2]

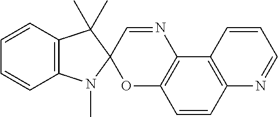 [SMILES: CN1c2ccccc2C(C)(C)C12C=Nc1c(ccc3ncccc13)O2]

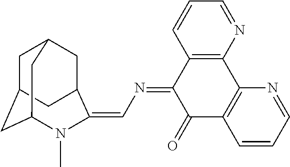 [SMILES: CN1/C(=C/N=C2\C(=O)c3cccnc3-c3ncccc32)C2CC3CC(C2)CC1C3]

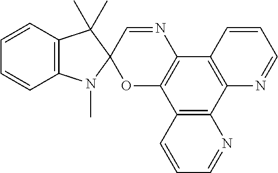 [SMILES: CN1c2ccccc2C(C)(C)C12C=Nc1c(c3cccnc3c3ncccc13)O2]

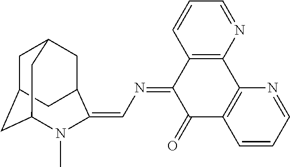 [SMILES: CN1/C(=C/N=C2\C(=O)c3cccnc3-c3ncccc32)C2CC3CC(C2)CC1C3]

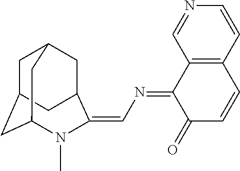 [SMILES: CN1/C(=C/N=C2\C(=O)C=Cc3ccncc32)C2CC3CC(C2)CC1C3]

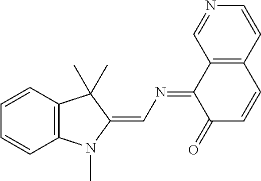 [SMILES: CN1/C(=C/N=C2\C(=O)C=Cc3ccncc32)C(C)(C)c2ccccc21]

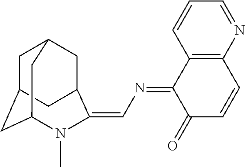 [SMILES: CN1/C(=C/N=C2\C(=O)C=Cc3ncccc32)C2CC3CC(C2)CC1C3]

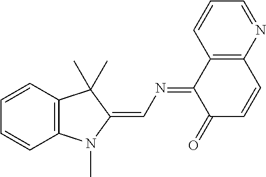 [SMILES: CN1/C(=C/N=C2\C(=O)C=Cc3ncccc32)C(C)(C)c2ccccc21]

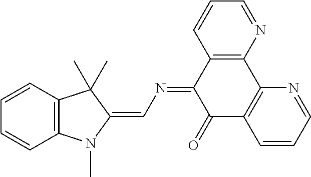 [SMILES: CN1/C(=C/N=C2\C(=O)c3cccnc3-c3ncccc32)C(C)(C)c2ccccc21]

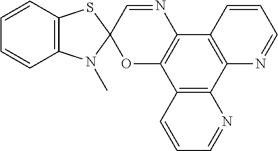 [SMILES: CN1c2ccccc2SC12C=Nc1c(c3cccnc3c3ncccc13)O2]

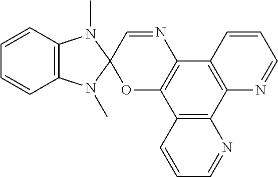 [SMILES: CN1c2ccccc2N(C)C12C=Nc1c(c3cccnc3c3ncccc13)O2]

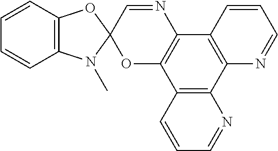 [SMILES: CN1c2ccccc2OC12C=Nc1c(c3cccnc3c3ncccc13)O2]

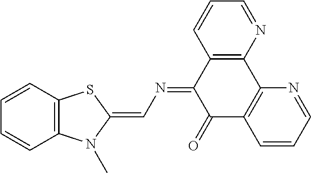 [SMILES: CN1/C(=C/N=C2\C(=O)c3cccnc3-c3ncccc32)Sc2ccccc21]

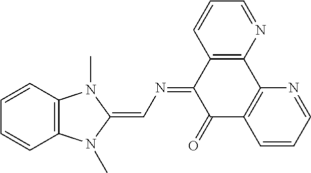 [SMILES: CN1C(=C/N=C2\C(=O)c3cccnc3-c3ncccc32)N(C)c2ccccc21]

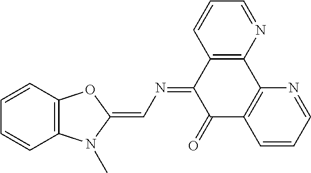 [SMILES: CN1/C(=C/N=C2\C(=O)c3cccnc3-c3ncccc32)Oc2ccccc21]

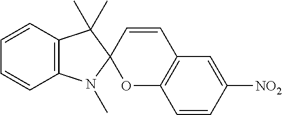 [SMILES: CN1c2ccccc2C(C)(C)C12C=Cc1cc([N+](=O)[O-])ccc1O2]

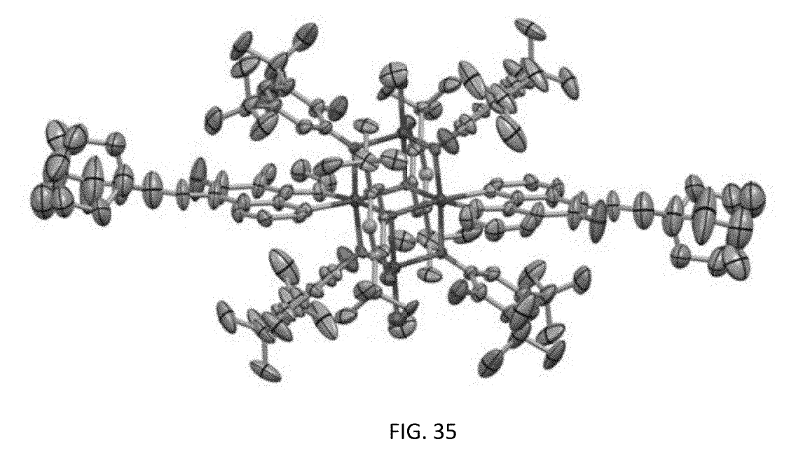

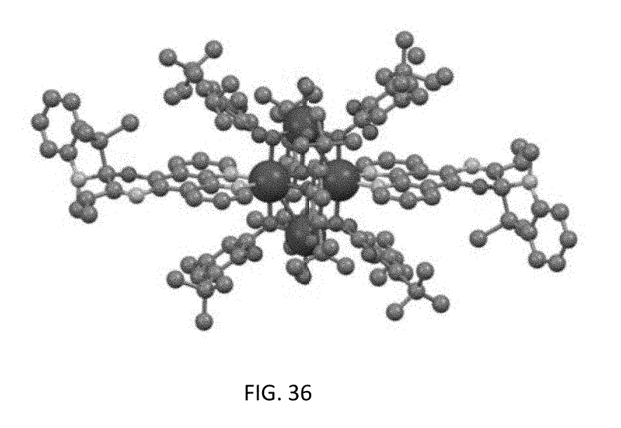

In particular disclosed embodiments, a plurality of complexes can be combined to provide di, tri, and tetrameric clusters of the complexes disclosed herein. As such, the complexes described herein can be used in higher order clusters. Some embodiments concern clusters having 2-8 metal-containing complexes that can be coupled together, wherein each complex of the cluster can have the same or different structure. In some embodiments, the clusters can have 2 to 4 metal-containing complexes wherein each complex can have the same or different structure. In particular disclosed embodiments, tetrameric metal-based clusters can be made. In some embodiments, the tetrameric clusters can all comprise Co, Fe, or a combination thereof. Clusters of the complexes disclosed herein also exhibit the unique optical and magnetic properties of the complexes that make up the clusters. Representative clusters are shown below in Table 2 as well as in FIGS. 35 and 36. Table 2 also provides representative monomeric complex structures. Some embodiments are illustrated with a particular formal oxidation state; however, other redox states are contemplated (such as catecholate, semiquinone, and/or quinone forms of the illustrated redox ligands).

TABLE 2
Representative Complexes and Clusters

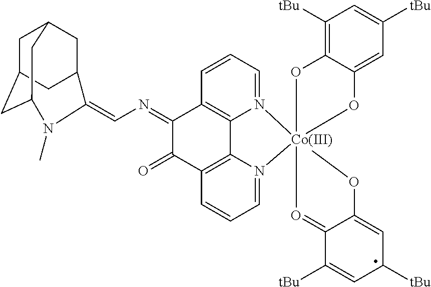

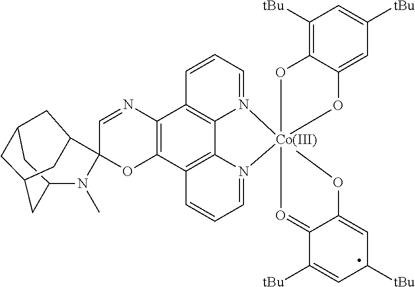

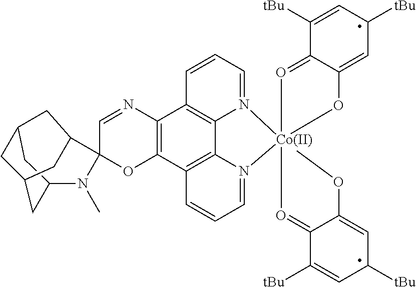

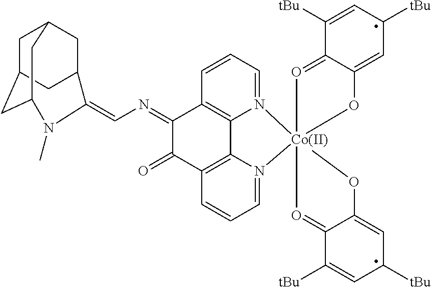

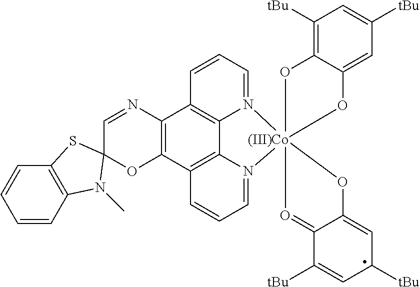

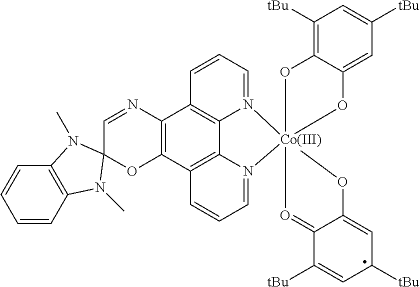

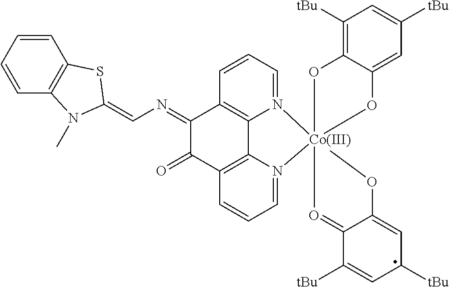

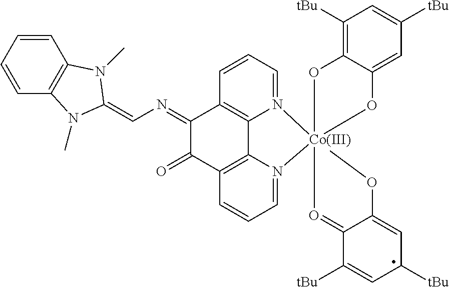

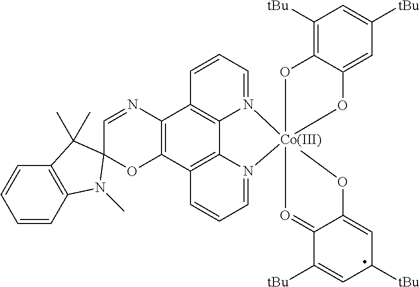

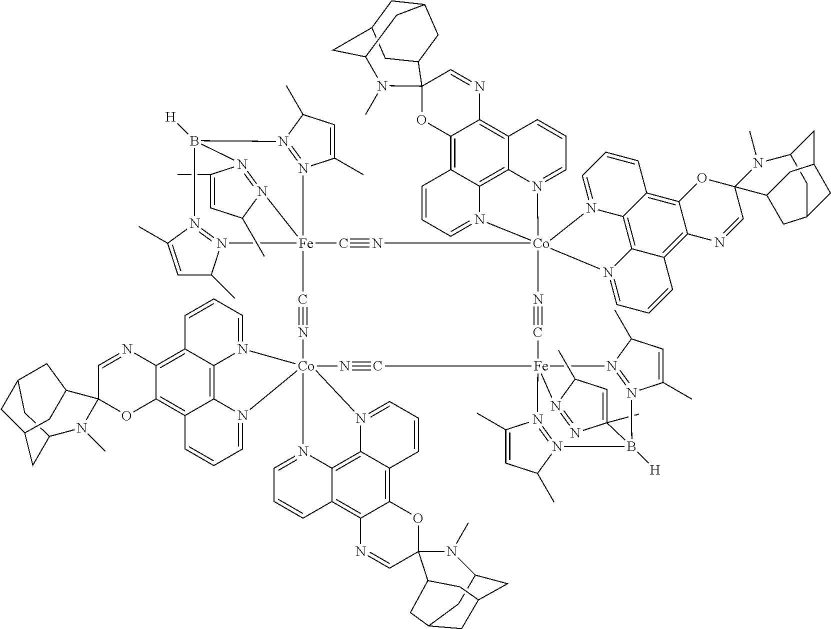

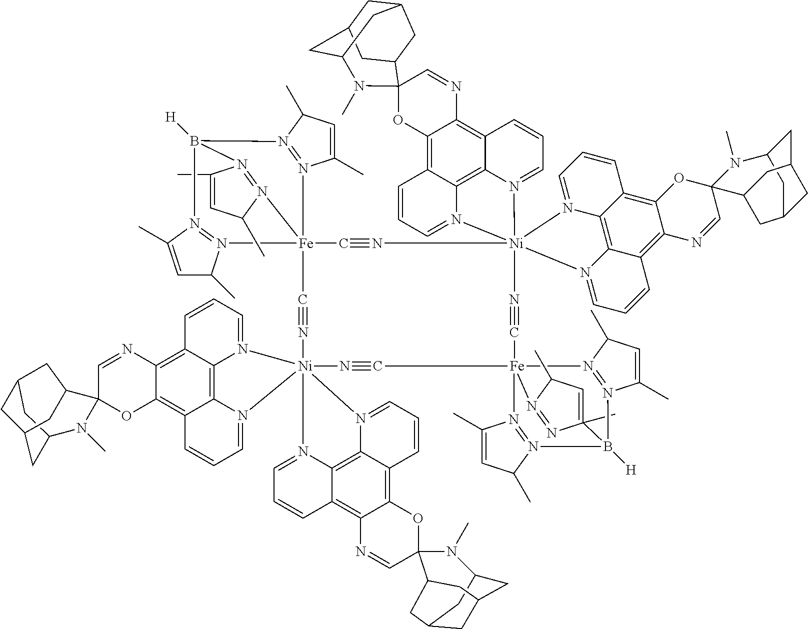

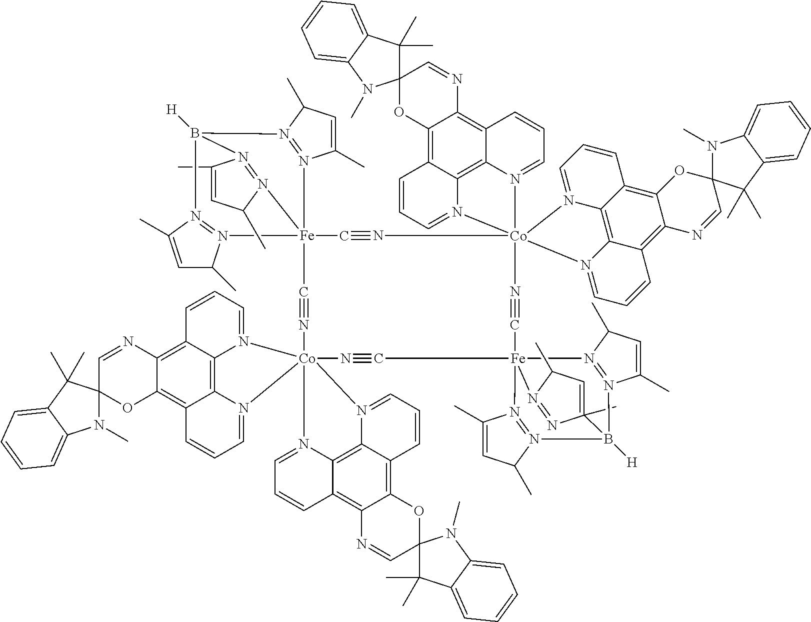

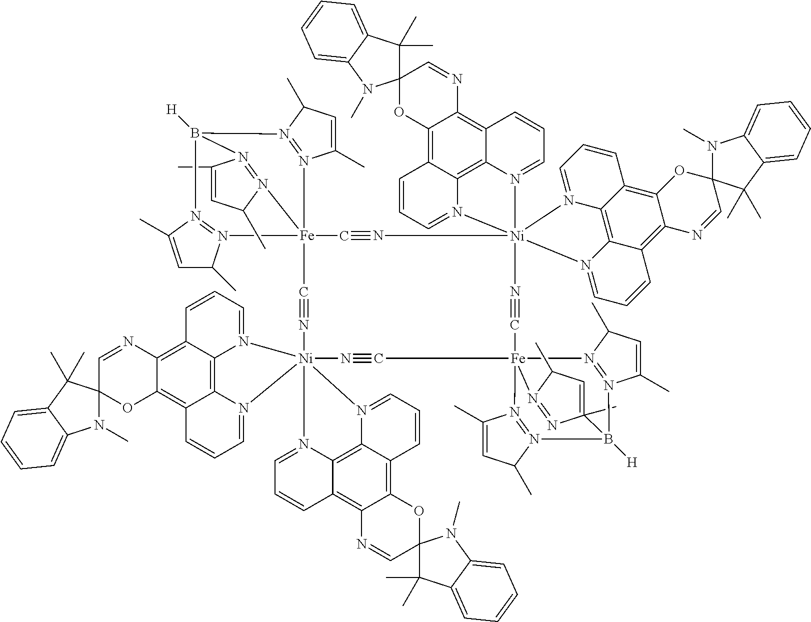

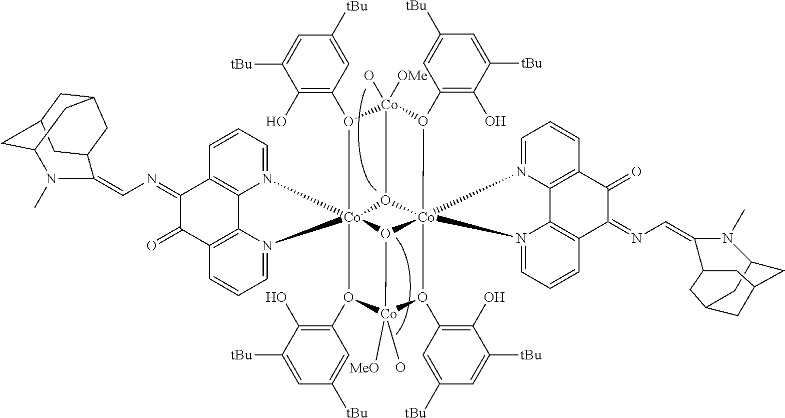

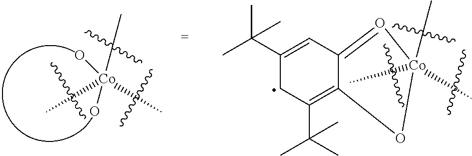

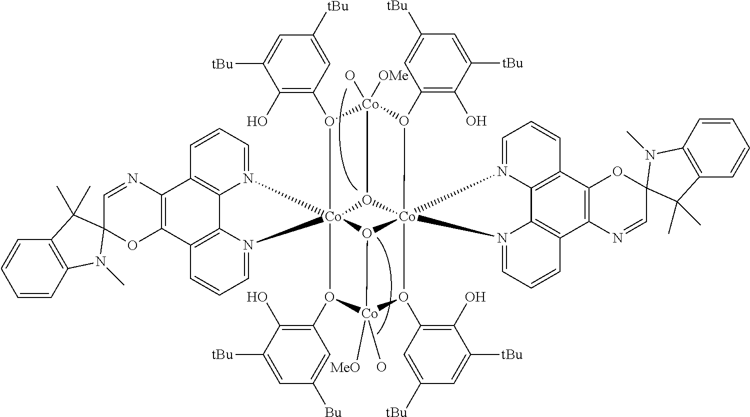

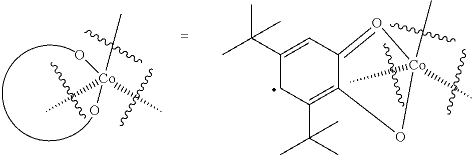

In some embodiments, if the redox active ligand is 3,5-di-tert-butylbenzene-1,2-diol, 2,4-di-tert-butyl-6-hydroxycyclohexa-2,5-dien-1-one, or a catecholate, a semiquinone, or a quinone form thereof, and the photoisomerizable ligand is spiro[azahomoadamantyl-phenanthrolinoxazine] or spiro[indoline-phenanthrolinoxazine], then M is not cobalt. In an independent embodiment of the individual non-clustered complexes, a solution-state complex is not or is other than

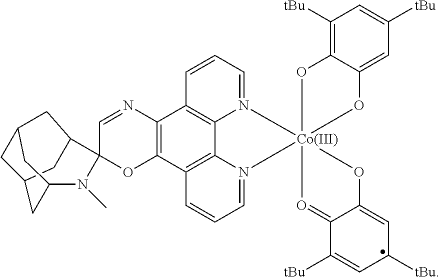

In another independent embodiment of the individual non-clustered complexes, a solid-state complex is not or is other than

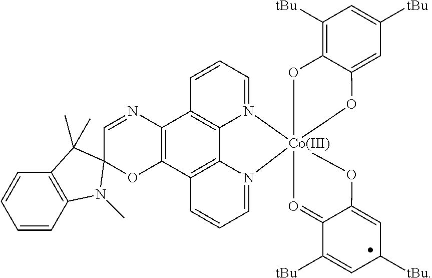

In some embodiments, a metal complex precursor can be coupled to one or more photoisomerizable ligands comprising a photoisomerizable moiety and a metal-coordinating component. When this representative metal complex precursor is combined with one or more such photoisomerizable ligands, the resulting complex can exhibit bistability between two distinct charge/spin states sensitive to external stimuli and environment due to redox-active (charge transfer induced spin transition) character. In some embodiments, a lower reduction potential of the photoisomerizable ligand correlates with a lower T_{1/2} due to stabilization of the lower metal oxidation state of the metal species within the complex; therefore, combining the metal complex precursors described herein with one or more such photoisomerizable ligands can provide the ability to optically or electrically modulate the reduction potential of the photoisomerizable ligand via isomerization of the ligand. In some exemplary embodiments, a cobalt-dioxolene complex, Co(diox)₂, or Co(diox)₂(pyridine)₂ can be used as a metal complex precursor to which one or more additional photoisomerizable ligands are added.

In particular disclosed embodiments, the photoisomerizable ligand can comprise a photoisomerizable spirooxazine functional group. The photoisomerizable spirooxazines disclosed herein exhibit the ability to open and close between the open form of the spirooxazine and the closed form (or vice versa) with rapid switching times (for example, on the picoseconds level) high fatigue resistance (for example, they are capable of use in >1000 cycles), and solid-state photochromism. UV irradiation of a ring-closed spirooxazine form (also referred to herein as “RC”) induces isomerization to the ring-opened photomerocyanine form (also referred to herein as “RO”), such as an iminocyclohexadienone-containing compound (or iminohexadienone compound), while reverse RO→RC conversion occurs with visible light irradiation. In some embodiments, the visible irradiation used to induce an RO→RC conversion form can range from 800 nm to 450 nm, such as 650 nm to 500 nm, or 600 nm to 555 nm. In some embodiments, the UV light used to irradiate the sample and thereby induce a RC→RO conversion can have wavelengths ranging from 320 nm to 450 nm, such as 320 nm to 400 nm, or 360 nm to 380 nm. In exemplary embodiments, photoresponsive spirooxazine ligands, such as spiro[indoline-phenanthroline]oxazines or spiro[azahomoadamantyl-phenthroline]oxazines can efficiently coordinate first-row transition metals in which RC→RO and RO→RC conversion modifies the reduction potential of the spirooxazine ligand. In some embodiments, the reduction potential of the spirooxazine ligand can be modified by 0.1 eV to 0.8 eV, such as 0.3 eV. The photoinduced ligand field changes occurring upon photoisomerization can therefore be used as a driving force for metal-centered charge-transfer and spin-transition processes.

In some embodiments, photoisomerizable spirooxazine ligands offer the potential to optically modulate the reduction potential of diimine ligands in the disclosed cobalt dioxolenes complexes via photoisomerization. A common indolyl spirooxazine variant has been previously incorporated into a cobalt-dioxolene complex to give a four-state photoisomerizable electronically bistable system with a gradual magnetic transition at low temperature, but in this previous method, the indolyl-containing complex did not exhibit the ability to undergo the PISCES process described herein. In some embodiments, this may result from the indolyl-containing complex existing in the Co(II)/Co(III) RC form as the dominant form in the ground state. In some embodiments, photoisomerization of the ligand to the open form can lead to a very small change in the Co(II)/Co(III) ratio due to a very low transition temperature (50 K) for the complex. Thus, in some embodiments, irradiation at room temperature may not lead to a significant change in the Co(II)/Co(III) ratio. In some embodiments, an azahomoadamantyl-containing complex can be used, which exhibits an abrupt magnetic transition at 325 K due to the dominant form being the RO/Co(III) state. As the RO and RC form induce two different transition temperatures, switching between the Co(II)/Co(III) state can be achieved by optically gating the photoisomerizable ligand between the RO and RC forms. Without being limited to a particular theory of operation, it is currently believed that photoisomerization at room temperature leads to isomerization to the RC form, which causes conversion to the Co(II) state and an increase in magnetization.

In some embodiments, a representative indolyl-containing complex possesses a thermal ground state in the closed RC form, while the open RO form is a short lived metastable state. Irradiation with UV can be used to switch the photochrome to the metastable state (open RO form), which is high energy and thus can be degradative to other organic/inorganic materials that may be present in the complex. It can render the complex inoperable for biological systems, due to the damaging effects of UV light on biological tissues. In some embodiments, an azahomoadamantyl-containing complex can be used instead. Such complexes are inverted as compared to the representative indolyl-containing complex (that is, are negative photochromes), in which the thermal ground state is the open RO form, while the closed RC form is the metastable state. Switching therefore can be accomplished with visible irradiation (e.g., 550-600 nm), which allows such complexes to be used with non-damaging wavelengths both for materials applications, as well as biological environments.

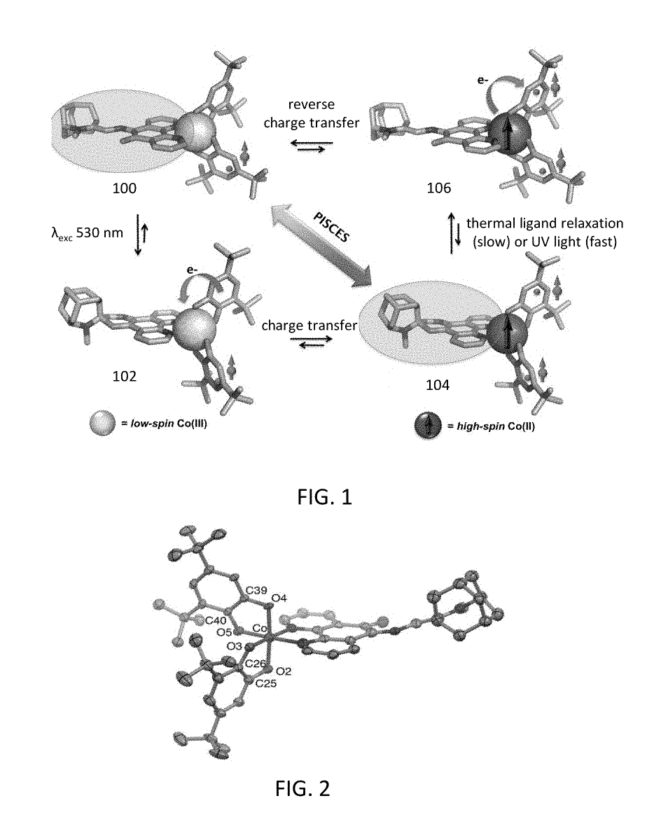

The photoisomerizable ligands disclosed herein can be incorporated into the metal complex precursors to shift the ground-state structure to an open RO or closed RC form. As long as the shift in structure occurs around the thermal transition temperature for the metal complex (referred to herein as “T_{1/2}”) a shift in the population of electronic states will result. In some embodiments, the change in population of the metastable state can increase from 0% to 100%, such as 10% to 80% K, or 60% to 90%. The T_{1/2} should be centered around 300 K, but the “hysteresis loop” can in principle be quite large, that is the operating range of most devices on the market are is 10-30° C., but a greater range (0-60° C.) is often desirable. In exemplary embodiments, the T_{1/2} is increased to 325 K. A representative PISCES complex system and the different complexes obtained in such a system are illustrated in FIG. 1. As is illustrated in FIG. 1, visible light irradiation from the ground-state RO-ls-Co(III) form (100) leads to ring closure (102), and a rapid charge transfer/spin transition to a RC-hs-Co(II) sextet state (104) with a resultant increase in magnetization. Without being limited to a particular theory, it is currently believed that the lifetime of the photoinduced magnetic state is dictated not by metal-centered excited states, which decay rapidly at room temperature, but by the lifetime of the metastable state of the photoisomerizable ligand (104→106). Accordingly, the systems and complexes disclosed herein provide advancements in the art, such as the fact that the optical modulation of spin state originates at the single molecule level, and can be controlled by the optical gating of the photoisomerizable ligand, and, because the ligand undergoes photoisomerization in the solid state, the disclosed complexes and the systems arising from such complexes can be incorporated into device architectures.

### IV. Methods of Making Complexes

Disclosed herein are embodiments of methods of making the disclosed complexes and systems. In particular disclosed embodiments, the methods described herein can be used to make a metal complex, such as a PISCES complex, comprising one or more photoisomerizable ligands. These complexes can provide numerous embodiments of a system wherein the metal complexes are converted to alternate species through charge transfer, thermal ligand relaxation, excitation, spin-charge excitation, or combinations thereof.

In particular embodiments, a metal complex precursor having any of the formulas described above can be combined with one or more photoisomerizable ligands having any one of the formulas described above to produce a complex as described herein. The metal complex precursors can be obtained commercially and/or can be made using methods known to those of ordinary skill in the art. In some embodiments, 1 equivalent of the metal complex precursor can be combined with 1 to 8 equivalents of the photochromic ligand per metal center. In a representative embodiment, a cobalt bis(dioxolene) spiro[azahomoadamantyl-phenanthrolinoxazine], Co(diox)₂(APSO) (1), was made by condensing spiro[azahomoadamantyl-phenanthrolinoxazine] (APSO) with a mononuclear cobalt di-tert-butyl benzoquinone (DTBQ) complex [Co(3,5-DTBQ)₂(pyridine)₂] in diethyl ether to give 1 as purple needles in high yield (79%).

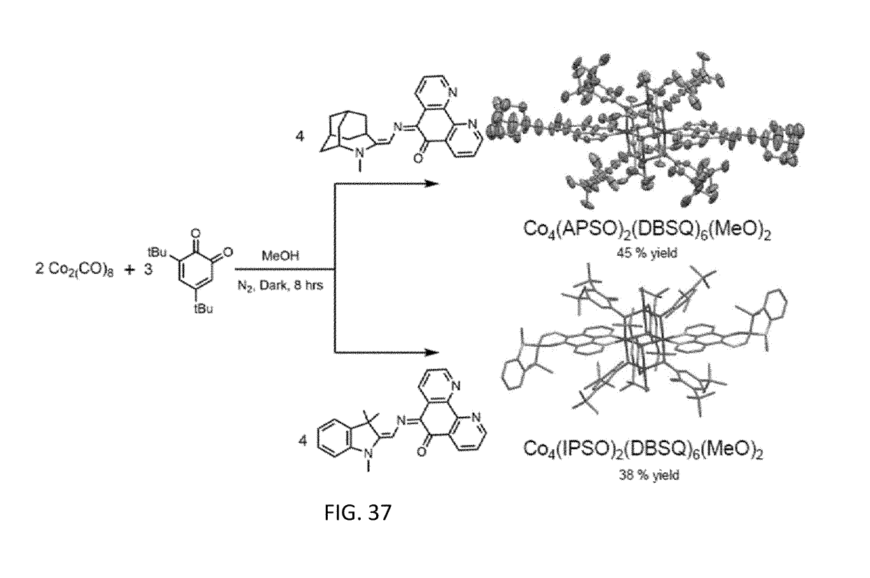

Complex clusters as described above also can be made. In particular disclosed embodiments, these clusters can be made by combining a metal cluster precursor with one or more ancillary ligands and one or more photoisomerizable ligands. Solely by way of example, a representative metal cluster precursor, Co₄CO₈, can be combined with one or more organic ligands (e.g., an organic ligand having a structure satisfying Formula VII) and a photoisomerizable ligand having a structure satisfying Formula IIIA or Formula IIIB. Representative synthetic schemes are illustrated in FIG. 37. Another representative embodiment is illustrated below in Scheme 1.

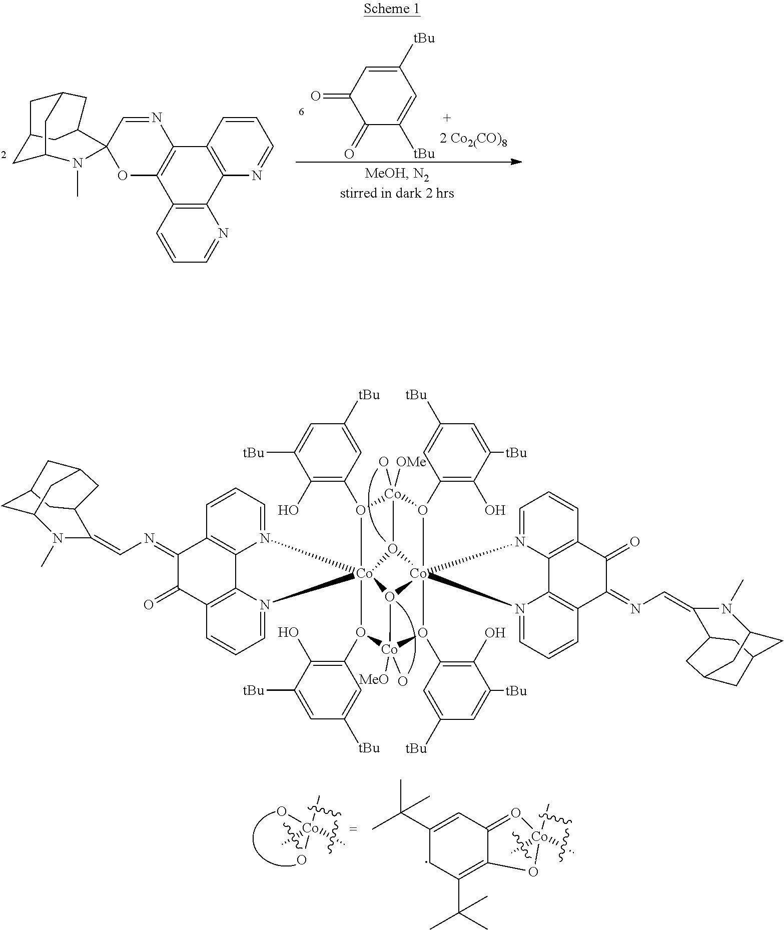

Ligands disclosed herein can be made using synthetic methods. An exemplary synthetic scheme for making representative ligands is illustrated below in Scheme 2.

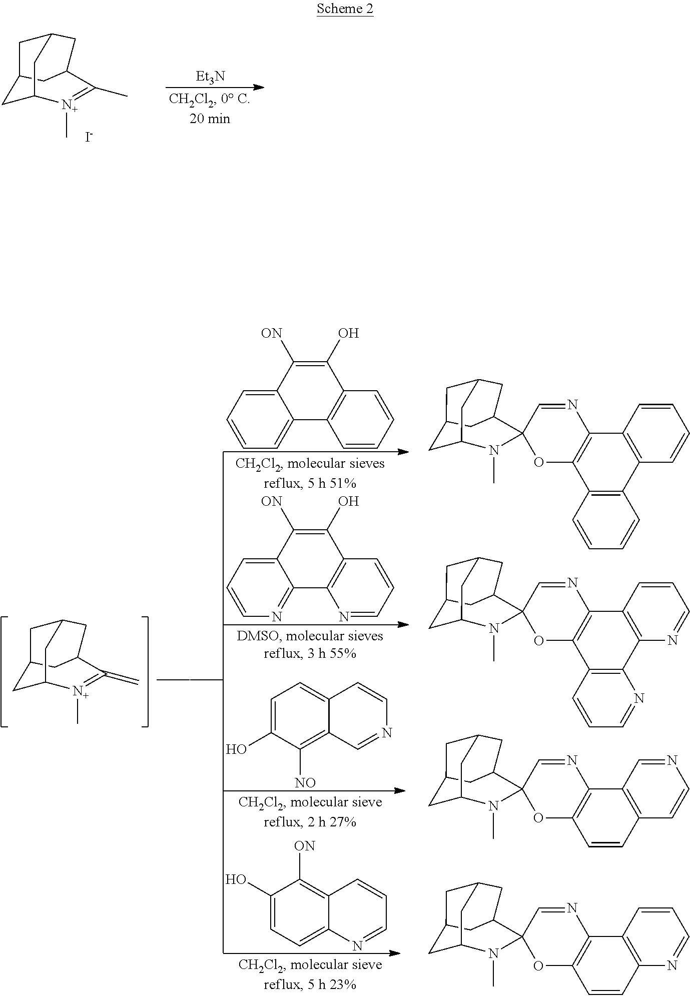

The complex embodiments disclosed herein can exhibit a number of different electronic states due to the photoisomerizable ligand(s) coupled to the metal of the complex. In some embodiments, this photoisomerization can occur because the photoisomerizable ligand comprises a spirooxazine moiety that can open and close due to bond breakage and formation, respectively. The spirooxazine moiety can undergo ring opening upon exposure to an energy source capable of producing energy sufficient to break a carbon-oxygen bond, such as UV light having wavelengths ranging from 330-370 nm. When energy is no longer focused on the photoisomerizable ligand, it can relax back to a closed state whereby the spirooxazine moiety is reformed. In some embodiments, the relative population of one of these electronic states can be influenced by environmental factors, such as temperature, medium, dielectric, field effects, and combinations thereof.

The complex embodiments disclosed herein also can exhibit electronic bistability between different states of the metal ligands of the complex. In some embodiments, charge transfer between the metal and the metal ligands can occur thereby contributing to the electronic bistability. In some embodiments, the relative population of one of these electronic states can be influenced by environmental factors, such as temperature, medium, dielectric, electric field effects, and combinations thereof.

The ground state of the complex embodiments disclosed herein can be determined using characterization techniques, such as low-temperature single-crystal X-ray diffraction (XRD) analysis, temperature-dependent solution spectroscopy, and combinations thereof. In additional embodiments, characterization techniques like nuclear magnetic resonance spectrometry, temperature-dependent optical absorption spectroscopy, and variable-temperature magnetic susceptibility measurements can be used to analyze the different electronic states of the complexes disclosed herein.

Solely by way of example, complex 1 can exist in four possible electronic states (100), as illustrated in FIG. 1. Two of the possible electronic states arise due to the coexistence of ligand isomerization between the open form (RO, 100/106) and closed form (SO, 102/104) of the APSO ligand. The other two electronic states arise due to electronic bistability between the ls-Co(III) (100/102) and hs-Co(II) (104/106) states of the cobalt complex. In exemplary embodiments, the thermodynamic ground state of 1 was determined using low-temperature single-crystal X-ray diffraction (XRD) and temperature-dependent solution spectroscopy. In exemplary embodiments, the ground state was determined to be the RO-ls-Co(III) form (100) using such techniques.

Magnetic bistability and PISCES processes also can be observed with the clustered complexes described herein. In particular disclosed embodiments, irradiating the clustered complexes with excitation at a particular wavelength results in ring closure or ring opening to the closed RC form or open RO form of the photoisomerizable ligand(s) present in the clustered complex. In some embodiments, this transformation can be evidenced by a decrease in the pi-pi* band of the RO form and can result in a PISCES process. In additional embodiments, clustered complexes can exhibit a PISCES process due to the fact that the direction of ligand field change is in the right direction to induce a Co(II)-Co(III) transition.

### V. Devices and Uses

The disclosed complexes can be used for a variety of applications due to their physical and chemical properties. For example, particular embodiments of the complexes disclosed herein have spin states that can be optically gated, even in a solid state at ambient temperature. The ability to optically gate these materials at ambient temperatures and in the solid state allows their integration into a variety of devices.

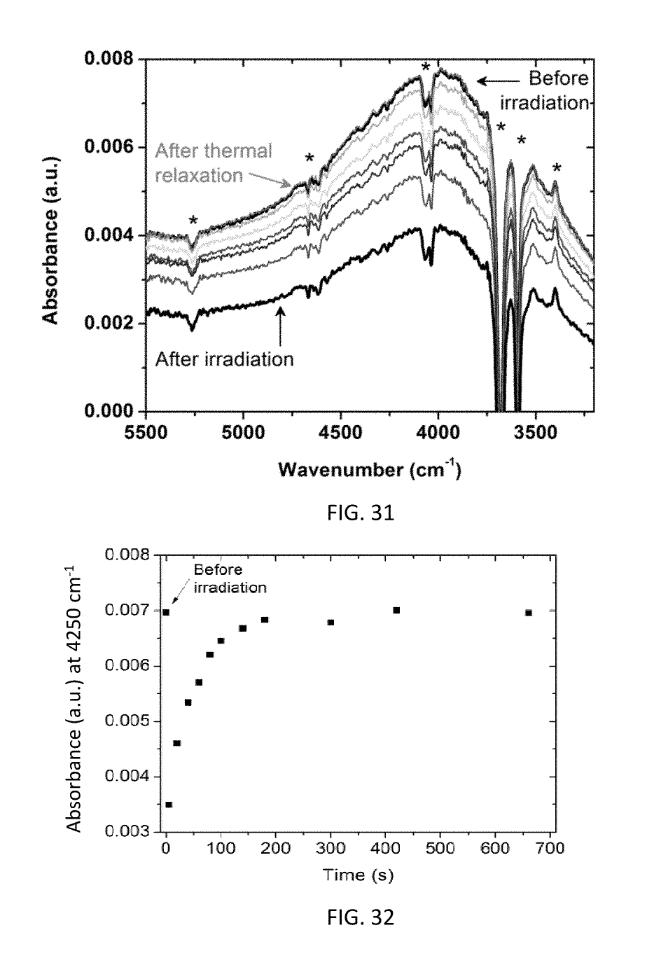

Disclosed herein is also the preparation of a photoresponsive metal-organic thin film exhibiting photomagnetic effects at room temperature. A photoisomerization-induced spin-charge excited state (PISCES) mechanism, leading to photomagnetic effects at room temperature, was demonstrated through solution-state IR, NIR (e.g., FIG. 31), and UV-vis spectroscopy on organic thin films, as well as magnetization and photomagnetization measurements on organic thin films at room temperature. In most embodiments, the RC photoisomer was found to stabilize the hs-Co(II) state. The spectroscopic data is consistent with the theoretical prediction that the RC form, having a lower-energy LUMO+1, preferentially stabilizes the hs-Co(II) form at room temperature via π-backbonding, as well as with ground-state energy DFT calculations. The presented PISCES system provides a powerful strategy to access ligand-gated spin states on a molecular level for quantum information processing technologies, in which the spin state of the complex has two possible values, S=½ and S=5/2, that can be “switched” by switching the state of the ligand. The photochromes themselves undergo both RC→RO conversion with UV light or with heat, and the reverse process, RO→RC conversion with visible light within the thermal half-life. It is expected therefore that reversible gating of this system could be achieved with alternating UV/visible light at times shorter than the half-life (10 s at 300 K). Lastly, as complex 1 exhibits photoinduced switching of both the magnetization and redox state at ambient temperature, this system is of great interest in the development of switching materials for a range of technologies for memory applications, organic electronics, photoactive catalysis, and functional MRI for biomedical and biosensing applications.

This photochrome-coupled redox-active complex and system affords a novel mechanism for realizing light-controlled magnetic effects via a PISCES process, through which magnetic and electrical properties may be modulated by gating charge-transfer processes in both solution and the solid state at room temperature.

In particular disclosed embodiments, the complexes described herein can be used in complementary metal-oxide-semiconductor (CMOS) compatible device architectures for nonvolatile memory applications. For example, the complexes described herein can be used in magnetic tunnel junctions, which can be used in magnetic tunnel junctions (MTJs), in magnetic random access memory-like (MRAM), and spin transfer torque random access memory-like (STTRAM); or as organic electronic layers in phase-change random access-like memory devices (PCRAM) for nonvolatile memory applications, data storage, quantum information processing, organic-based electronics, and the like. While normal MRAM and STTRAM devices offer low power consumption and good scalability, the write current required is high, the cell sizes limited by the bit line size, and the write speed significantly slower than SRAM. The present inventors have discovered that the complexes described herein can be used in devices that instead rely on light-induced magnetization changes that can exhibit significantly longer lifetimes of photoinduced spin states in the solid state and as such can be used in light-responsive devices. In particular disclosed embodiments, the complexes disclosed herein can be used in magnetic tunnel junctions that are in turn implemented into light-induced RAM technology/devices (or LI-RAM). LI-RAM devices disclosed herein use light to switch the magnetization states of a thin film at room temperature (e.g., 300 K to 350 K) with long lifetimes. Thus, the “write” function of the device can be controlled with light excitation and the “read” function can be controlled with resistivity through the magnetic tunnel junction as a function of light-driven or electric-field driven write state.

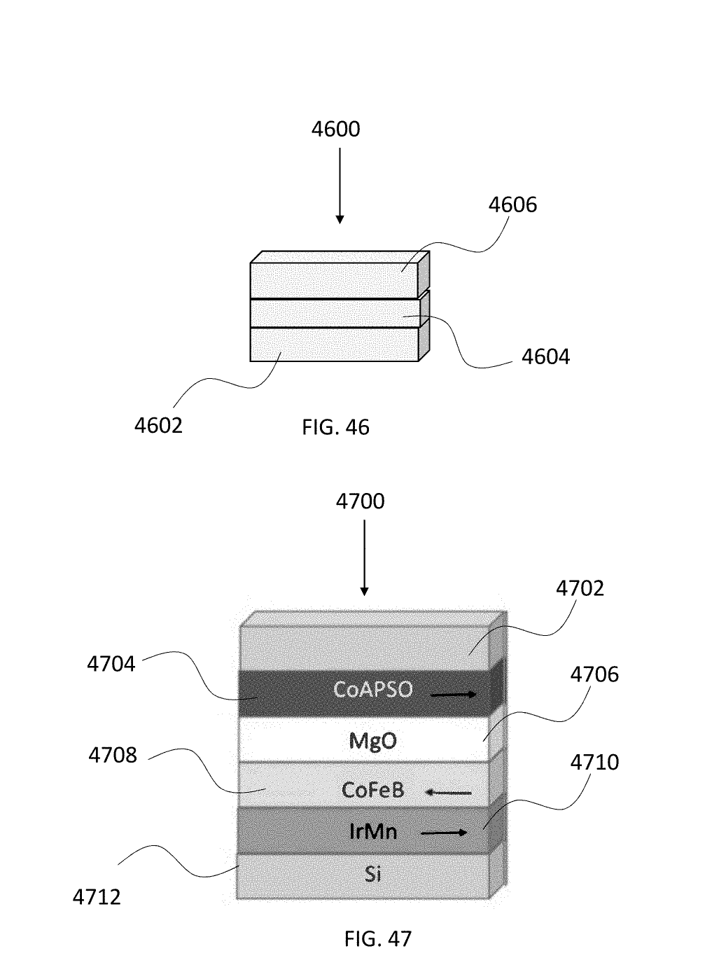

In particular disclosed embodiments, the complexes described herein can be used in magnetic tunnel junctions as a storage/write layer. Magnetic tunnel junctions incorporating the complexes described herein can comprise a plurality of layers that can be fabricated using standard fabrication techniques. In particular disclosed embodiments, the magnetic tunnel junctions can comprise one or more magnetic layers and a tunnel barrier layer. In some embodiments, the tunnel junction comprises a photomagnetic layer comprising a complex (or mixture of complexes) disclosed herein, a tunnel barrier layer, and a ferromagnetic layer, such as a fixed magnetic layer. The tunnel barrier layer can be positioned between the photomagnetic layer and the ferromagnetic layer. A representative embodiment of magnetic tunnel junction comprising the complexes described herein is illustrated in FIG. 46. FIG. 46 shows a layered magnetic tunnel junction 4600 comprising a ferromagnetic layer 4602, a tunnel barrier layer 4604, and a photomagnetic layer 4606. Though not illustrated in FIG. 46, the magnetic tunnel junction can further comprise one or more additional magnetic layers and/or non-magnetic spacer layers, one or more electrode layers (such as a top electrode layer and a bottom electrode layer), one or more capping layers, and/or one or more seed layers. The electrode layers can be used to drive currents through the device. In some embodiments, at least one of the electrode layers can be transparent so as to allow light to pass through to the photomagnetic layer. In particular disclosed embodiments, the electrode positioned adjacent to or near the photomagnetic layer will be transparent. The one or more seed layers such as silver, calcium, gold, indium tin-oxide, cobalt, iron-cobalt, or iridium-manganese, can be used to promote or aid in growing subsequent layers of the magnetic tunnel junction device during the fabrication process. The one or more organic or inorganic capping layers can comprise materials selected from, but not limited to ZnO, ZnSe, tetradecyltrimethylammonium bromide [TTAB], and the like), hexadecylamine (HDA), hexadecylthiol (HDT), and poly(vinylpyrrolidone) (PVP), (N,N-di(naphthalene-1-yl)-N,N-diphenyl-benzidine (NPB), ITO, silicon oxide, aluminum oxide, silicon nitride, or combinations thereof. The one or more organic or inorganic cappling layers can have a thickness ranging from greater than 0 nm to 180 nm. These layers can be used to modify the optical structure of the device and/or to protect the magnetic tunnel junction from damage and are optional. Another exemplary embodiment is illustrated in FIG. 47. The magnetic tunnel junction 4700 illustrated in FIG. 47 includes a transparent electrode layer 4702, a photomagnetic layer 4704 comprising an APSO-containing cobalt complex, a tunnel barrier layer 4706, a ferromagnetic layer 4708, a pinning layer 4710, and a silicon electrode 4712.

The photomagnetic layer of the magnetic tunnel junction device can comprise at least one complex as described herein, or a plurality of different complexes, or a clustered complex. Due to the presence of the complex within the photomagnetic layer, this layer can exhibit a changeable magnetization that can be switched upon exposure to light of a particular wavelength. In particular disclosed embodiments, the photomagnetic layer comprises a complex in an amount ranging from greater than 0% (w/w) to 100% (w/w), such as 10% (w/w) to 100% (w/w), such as 15% (w/w) to 95% (w/w), or 20% (w/w) to 90% (w/w). In particular disclosed embodiments, the photomagnetic layer comprises a complex that is in the solid state. For example, a film of the complex can be used to provide the photomagnetic layer and/or the complex can be embedded in a polymeric matrix for use in the photomagnetic layer. In embodiments comprising films of the complexes, the film can be a thin film having a thickness ranging from 1 Å to 1 μm or higher, such as 10 Å to 1 μm, or 100 Å to 1 μm. In some embodiments, the thin film can be formed by vapor phase deposition, solution drop casting, spin coating, and solution deposition techniques. In particular disclosed embodiments, the thin film can be deposited on substrates that may contain graphene, silicon, gold, a metal oxide, or a combination thereof. Characterization of the thin film can be carried out using any suitable method, such as atomic force microscopy, magnetic force microscopy, scanning tunneling microscopy, and electron microscopy. The properties of these thin films can be measured by magneto-optical effects, magnetoresistance measurements, or by electrical resistivity measurements.

In some embodiments, the complex can be combined with a polymeric resin to provide a polymeric matrix that is deposited as the photomagnetic layer. In such embodiments, polymeric resins or inorganic matrices (e.g., matrices comprising Fe, Co, Fe—Co, Mn, or IrMn), semiconductor metal oxides (e.g., indium tin oxide, lead oxide, and the like) or III-V semiconductors (e.g., CdSe, ZnO, or the like) or organic matrices (such as a polymer matrix or colloidal suspension containing one or more of the following: conducting polymers, such as polythiophene, polyacetylene, polypyrrole, or polyaniline; carbon black; and nonconducting polymers, such as PMMA, PVC, or PP. In some embodiments, the photomagnetic layer may be a single layer or it can comprise a plurality of layers. As the complexes disclosed herein can be used in the solid state, it is possible to alter or modify the magnetic or shape anisotropy of the complex to obtain a maximum desired magnetic anisotropy. In particular disclosed embodiments, at least a portion of the photomagnetic layer comprising a complex can have a biaxial anisotropy, a cone anisotropy, a uniaxial anisotropy, a perpendicular anisotropy, a planar anisotropy, or the like. In particular disclosed embodiments, ordered photomagnetic layers comprising the complexes disclosed herein can be obtained by annealing the photomagnetic layer over a range of temperatures and evaluating the resulting degree of order by AFM/MFM/STM imaging. Photomagnetic layer morphology can be correlated to magnetic order, by correlating the AFM/MFM/STM imaging results with magneto optical measurements of the layer. Also, changes in the electrical properties of the photomagnetic layer in response to light irradiation can be modified by determining the electrical properties as a function of the temperature through I-V curves in the presence and absence of light. As there is a known electrical field effect on the Co(II)/Co(III) equilibrium, and because light irradiation can lead to redox switching at the metal center of the complexes, changes in magnetization and electrical properties of the material can lead to changes in magnetoresistance as a function of light irradiation.

The tunnel barrier layer of the disclosed magnetic tunnel junctions typically are nonmagnetic. In some embodiments, the tunnel barrier layer is an insulator. In particular disclosed embodiments, the tunnel barrier layer can comprise a metal oxide capable of enhancing the tunneling magnetoresistance (TMR) of the magnetic junction, such as Al₂O₃, MgO, titanium oxide, and the like. In some embodiments, the tunnel barrier layer may be a conductor, such as Cu. In alternate embodiments, the tunnel barrier layer can comprise a granular layer including conductive channels in an insulating matrix. The thickness of the tunnel barrier layer can range from greater than 0 nm to 25 nm, such as 1 nm to 20 nm, or 1 nm to 15 nm, or 1 to 10 nm. The ferromagnetic layer can comprise a magnetic material, such as a metal or metal alloy composition. In particular disclosed embodiments, the ferromagnetic layer can comprise Co, Fe, B, Ni, or combinations or alloys thereof. In some embodiments, the ferromagnetic layer can be a fixed magnetic layer. In particular embodiments, the ferromagnetic layer comprises a CoFeB alloy blend. The ferromagnetic layer may comprise a single layer or it may comprise a plurality of layers. For example, the ferromagnetic layer may be comprised of a reference layer (e.g., CoFeB, Co, Fe, CoFe, Ni, FeNi, or Heusler alloys, such as MnGax, MnGex, and the like), an interlayer (such as Ru), a pinned layer (e.g., CoFe, CoFeB, Co, Fe, Ni, FeNi, and the like), and an AFM layer (e.g., PtMn) which is a synthetic antiferromagnetic layer including magnetic layers antiferromagnetically or ferromagnetically coupled through thin layers, such as an Ru interlayer. In such an embodiment, multiple magnetic layers that are interwoven with thin layer(s) of Ru or other material may be used. In additional embodiments, the magnetic tunnel junction can comprise one or more additional layers, such as a pinning layer, which can act as an antiferromagnet pinning layer for the ferromagnetic layer. If a pinning layer is used, it can comprise a metal alloy including metals selected from Ir, Mn, Co, Fe, B, Ni, or any mixture or alloy thereof.

Disclosed herein are methods for making the magnetic tunnel junctions described herein. In particular disclosed embodiments, the methods may comprise more or fewer steps and while some embodiments are described in the context of fabricating a single magnetic junction, the methods also can be used to form multiple magnetic junctions in parallel. In some embodiments, individual layers of the components of the magnetic tunnel junction can first be made and then subsequently combined to form the stacked magnetic tunnel junction. In yet other embodiments, one or more of the individual layers of the magnetic tunnel junction can be made in a sequential process whereby a first layer is made and a second or subsequent layer is deposited on the first layer (or any such layer that had been previously deposited before the subsequent layer). In particular disclosed embodiments, a ferromagnetic layer is deposited on a surface of a substrate and the tunnel barrier layer is deposited on an exposed surface of the ferromagnetic layer. The photomagnetic layer may be deposited onto an exposed layer of the tunnel barrier layer. In some embodiments, a pinning layer can first be deposited on a surface of a substrate, followed by the ferromagnetic layer. In yet additional embodiments, the substrate may be an electrode or it may comprise an electrode layer. In additional embodiments, the substrate can be a silicon substrate, such as a thermally oxidized silicon substrate. Film deposition techniques, such as shadow mask techniques using DC magnetron and/or ion beam sputtering, can be used to form each layer of the magnetic tunnel junctions. Other suitable deposition techniques also may be used, including dip-coating, spin-coating, and/or the like. In some embodiments, the magnetic tunnel junction may be annealed at any point during the fabrication process. In exemplary embodiments, the finally-constructed magnetic tunnel junction can be annealed. Annealing can be carried out at temperatures higher than from 60° C. to 300° C., such as 70° C. to 250° C., or 80° C. to 200° C., or 90° C. to 150° C. In some embodiments, the annealing temperatures may be at least four hundred degrees.

In some embodiments, the performance of the magnetic tunnel junction can be modified by increasing the ferromagnetic polarization of the magnetic layers used in the junction; exchange-biasing an electrode component of the tunnel junction to improve switching at low magnetic fields by depositing electrode layers in the presence of a magnetic field; adjusting the angle of magnetization polarization; and/or adjusting the bias voltage and/or temperature used with the tunnel junction. By making any one or more of these modifications, the magnetoresistance ratio of the tunnel junction can be maximized. In particular disclosed embodiments, room temperature magnetoresistance can be achieved on the order of 15%-70% (or 15% to 50%, or 15% to 25%, or 15% to 22%) at low magnetic fields with spatial and temporal resolution due to the scalability of the photomagnetic material. Solution-based processing also can be used to allow inkjet printing of substrates. Also, fast read/write speeds can be obtained due to the ability to control optical inputs via numeral apertures.

Also disclosed herein are embodiments of LI-RAM (and LI-RAM devices) that comprise a plurality of the magnetic tunnel junctions disclosed herein, which act as storage cells. Such arrays comprise the plurality of magnetic tunnel junctions, a plurality of word lines coupled to the magnetic tunnel junctions, a plurality of source lines coupled to the magnetic tunnel junctions, a plurality of bit lines coupled to the magnetic tunnel junctions, a sense amplifier, and optionally one or more transistors coupled to the magnetic tunnel junctions. In particular disclosed embodiments, these components can be arranged in an array format. The LI-RAM cells disclosed herein may have sizes ranging from greater than 1 to 9 F², such as 2 to 8 F², or 3 to 6 F².

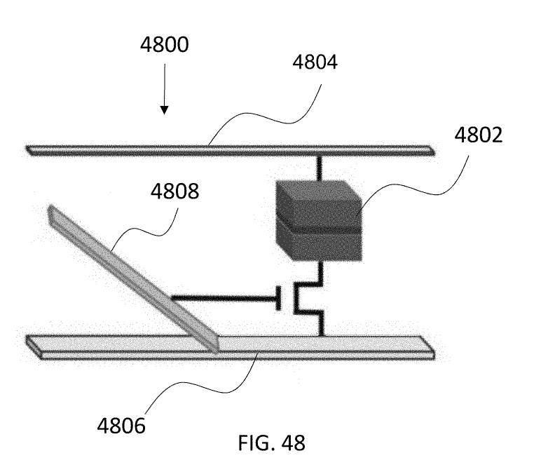

The magnetic tunnel junctions and or LI-RAM (or LI-RAM devices) comprising such tunnel junctions can be used in a magnetic memory. The magnetic memory can comprise reading/writing column select drivers, as well as word line select driver. Additional components may be provided, such as those described above. The storage region of the memory includes magnetic storage cells. One or more of the magnetic storage cells can comprise at least one magnetic junction as disclosed herein and at least one selection device. In some embodiments, the selection device can be a transistor. One or more magnetic junctions can be provided per cell. As such, the magnetic memory can exhibit lower soft error rate and a low critical switching current that conventional devices. A representative cell for LI-RAM is illustrated in FIG. 48. Solely by way of example, FIG. 48 illustrates a storage cell 4800 comprising a magnetic tunnel junction 4802, a bit line 4804, a source line 4806, and a word line 4808.

In particular disclosed embodiments, the tunnel junction used in the LI-RAM can be operated using magneto-optics techniques. The light source can be used directly as a write mode, rather than as a photothermal heat source, and the temporal and spatial limits of the cell size can be determined by optics utilized in the device. In some embodiments, the cell size can be limited by the numerical aperature and wavelength of light. Solely by way of example, at 400 nm, and a numerical aperture (NA) of 0.6, a minimum cell size of 130 nm is possible and, with varying optics, a range of 60 nm to 250 nm is possible. The power of light used to switch the complexes used in the photomagnetic material is small, such as on the order of 1-2 mW per cm². The write current can be determined based on the power required by the light source (which in turn depends on the light source chosen) and the switching current can be the same or different as the write current. In some embodiments, the write time for LI-RAM embodiments disclosed herein can be on the order of picoseconds to nanoseconds. The write time can be increased or decreased by adjusting the matrix surrounding the complexes used in the photomagnetic layer. For example, a rigid polymeric matrix could be used to slow the switching speed, or a polymeric matric could be omitted or modified to provide a more elastic matric, which can increase the switching speed.

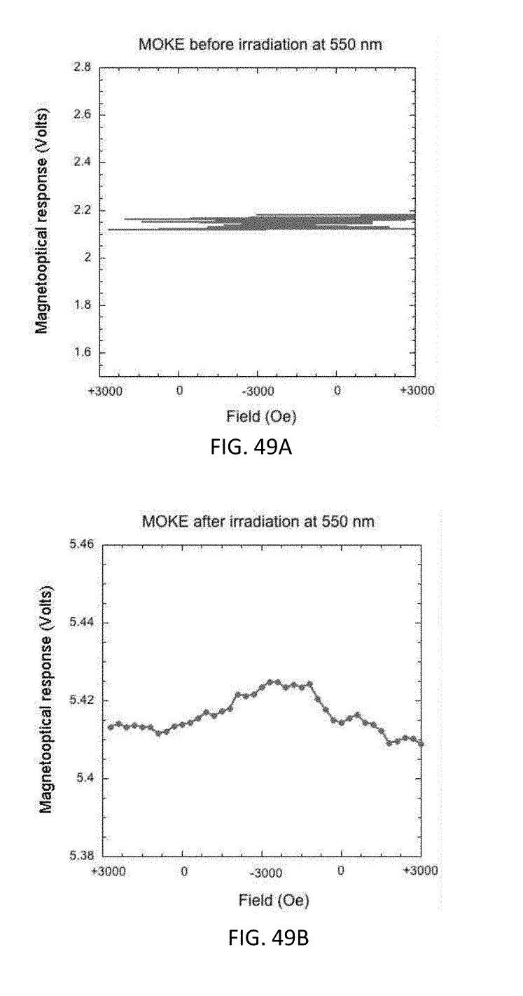

The light induced magnetization switching process has high endurance with a fatigue resistance of <10% over 103 cycles, and can be very high in the solid state. The current measurement of endurance in the thin film as a function of constant irradiation at λ_{exc} 550 nm is shown in FIG. 49. In most materials endurance or fatigue resistance is determined as the extent of fatigue or decomposition over 1000 cycles. The cycling of magnetic and optical states as a function of excitation/relaxation cycles can be measured in increasing time intervals for evaluation of the endurance of the photomagnetic layer within the magnetic tunnel junction. For example, the optical signature of the material at 555 nm can be followed as a function of time for 1000-5000 cycles. Typically, while light-induced degradation of the photoisomerizable ligand of the complex is minimal, embedding the complex into a less oxygen-permeable matrix (e.g., such as the polymeric matrices described above) can alleviate any observed oxygen mediated degradation. Time-resolved spectroscopy can be used to determine the Co(II)/(III) switching speeds with continuous and ultrafast laser pulses in the thin film state and in the magnetic tunnel junction. In some embodiments, the photoisomerizable ligands of the complex can undergo ring opening/closing on the order of 2 picoseconds in solution and/or solid states. In some embodiments, the morphology of the thin films of the photomagnetic layer can be modified using polymeric resins discussed above and other deposition techniques, which provides another way to modify the read/write times.

Also disclosed herein are embodiments of a phase change memory cell (or a “PCM cell”) comprising the complex and/or cluster embodiments described herein. Phase Change memory (PCM) traditionally uses the change in a chalcogenide glass between ordered and amorphous phases as the switching mechanism. Upon heating, the material is switched to an amorphous phase, accompanied by a large change in resistivity, in which resistivity through the device is the “read-out”. The disclosed PCM cell devices disclosed herein comprise a layer comprising a complex and/or cluster as described herein and can exhibit improved performance over traditional PCM cells.

In some embodiments, the structure of the disclosed PCM cell includes a top electrode, which can be silicon or a metal; an active layer comprising a phase change material, such as a layer comprising a complex and/or cluster described herein; a heating layer; and a bottom electrode. The PCM cell embodiments can have two operating states: a high resistance state, 0, and a low resistance state, 1. The READ and WRITE mechanisms of the device embodiments involve (i) a SET state (writing bit “1” in which the phase change material is switched through a source of external voltage to a low resistance state, short latency, and high power consumption and (ii) a RESET state (writing bit “0,” which involves a high resistance state, sustained low voltage pulse, long latency, and low power consumption). To READ the state of the phase change material, a low enough voltage pulse is applied to the material to read the resistivity state.

In embodiments of the PCM cell device, the phase change is defined as a switch between the SO-hs-Co(II) state and PMC-ls-Co(III) state of the phase change material. Heating drives the material to the SO-hs-Co(II) state, which is a high magnetization, lower resistivity state. Cooling or application of an external voltage switches the material back to a high resistivity PMC-ls-Co(III) state. Embodiments of the PCM cell device can comprise two electrodes (a top and bottom electrode), an active layer comprising a bistable complex described herein, a heating component (such as a heating material), and an insulator component. In particular disclosed embodiments, the active layer can be positioned adjacent to the top electrode and can comprise a region effective to undergo a phase change upon heating. This region can be located within any portion of the active layer, but typically can be located in the center of the active layer. In some embodiments, the heating material can be positioned proximal to the active layer and in some embodiments can be positioned indirectly and proximally to the active layer (such that these two components are separated by an intermediate layer) or it can be positioned directly and proximally to the active layer (such that these two components have physical contact). In yet additional embodiments, the cell can further comprise an insulator material that surrounds at least a portion of the heating material. In some embodiments, the insulator material can be wrapped around the heating material such that it surrounds or substantially surrounds the perimeter of the material. In yet additional embodiments, the cell further comprises a bottom electrode that is positioned adjacent to the insulator material.

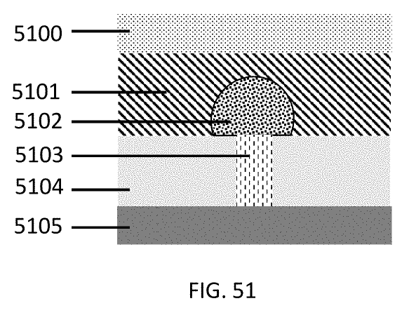

A representative device architecture is shown in FIG. 51. With reference to the device shown in FIG. 51, the cell can comprise a top electrode (5100), which can be gold, silver, or silicon; an active layer (5101) comprised of a phase change material (e.g., CoAPSO) with a region (e.g., region 5102) that is effective to undergo a phase change upon heating; a heating material (5103), which typically can be TiN or TiW; an insulator (5104), which can be SiO₂; and a bottom electrode (5105), which can be gold, silver, platinum, or silicon and can be the same or different as the top electrode.

### VI. Overview of Several Embodiments

Disclosed herein are embodiments of a magnetic tunnel junction, comprising: a photomagnetic layer comprising a magnetically bistable complex or cluster thereof, wherein the magnetically bistable complex comprises an optically bistable photoisomerizable component, and an electronically bistable metal-containing component; wherein the optically bistable photoisomerizable component is coupled to a metal of the electronically bistable metal-containing component; a tunnel barrier layer positioned adjacent or substantially adjacent to the photomagnetic layer; and a ferromagnetic layer positioned adjacent or substantially adjacent to the tunnel barrier layer.

In some embodiments, the electronically bistable metal-containing component comprises a CTIST complex, a bimetallic cyanide, or an organic-metal complex.

In any or all of the above embodiments, the organic-metal complex has a formula M_{w}(L^{a})_{z}(L^{r})_{y}, wherein M is a metal selected from a row 1 transition metal, L^{r} is a redox active ligand capable of charge transfer with M, L^{a} is an ancillary ligand, and each of w, y and z independently is an integer selected from 1 to 8.

In any or all of the above embodiments, the redox active ligand has a formula

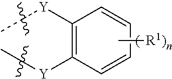

wherein each Y independently is selected from O, S, or NR^{a}, wherein R^{a} is selected from hydrogen, aliphatic, aryl, heteroaliphatic, or heteroaryl; each R¹ independently is selected from a heteroatom-containing functional group, aliphatic, aryl, heteroaliphatic, or heteroaryl; and n is an integer selected from 1 to 4.

In any or all of the above embodiments, each Y is oxygen or hydroxyl and each R¹ independently is selected from aliphatic comprising 1 to 10 carbon atoms.

In any or all of the above embodiments, each R¹ independently is selected from methyl, ethyl, propyl, isopropyl, butyl, isobutyl, tert-butyl, cyclopentyl, or cyclohexyl.

In any or all of the above embodiments, the redox active ligand is a dioxolene ligand.

In any or all of the above embodiments, the redox active ligand is

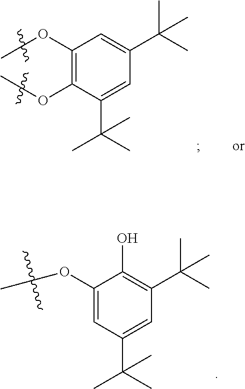 [SMILES: *Oc1cc(C(C)(C)C)cc(C(C)(C)C)c1O* ; *Oc1cc(C(C)(C)C)cc(C(C)(C)C)c1O]

In any or all of the above embodiments, the optically bistable photoisomerizable component is a spirooxazine ligand.

In any or all of the above embodiments, the spirooxazine ligand has a structure satisfying a formula selected from

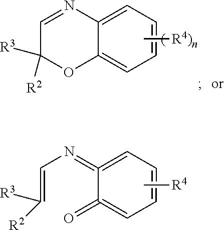

wherein R² and R³ combine to form a 5- to 8-membered aliphatic or heteroaliphatic cyclic ring or aliphatic or heteroaliphatic bicyclic ring; each R⁴ independently is selected from a functional group comprising —NH₂, —OH, —OR⁵, —C(O)H, —C(O)OH, —C(O)R^{b}, —C(O)OR^{b}, —SH, —SR^{b}, —P(R^{b})₃, and cyano, wherein R^{b} is selected from aliphatic, aryl, heteroaliphatic, or heteroaryl; or two R⁴ groups are positioned on adjacent carbons and form a fused aromatic ring, which is optionally bound to one or more additional aromatic or heteroaromatic groups comprising one or more heteroatoms selected from N, O, S, or Se; or two R⁴ groups can be positioned on adjacent carbons and form a fused heteroaromatic ring comprising one or more heteroatoms selected from N, O, S, or Se, which is optionally bound to one or more additional aromatic or heteroaromatic groups comprising one or more heteroatoms selected from N, O, S, or Se; and n is an integer selected from 1 to 4.

In any or all of the above embodiments, the spirooxazine ligand has a structure satisfying a formula selected from

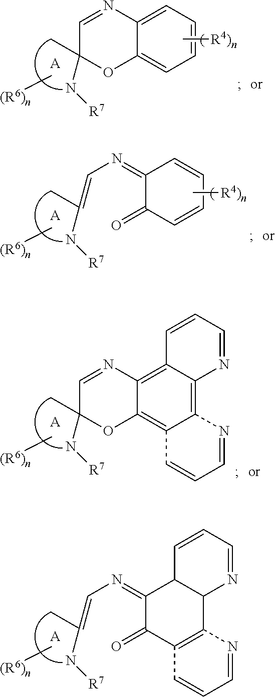

wherein ring A is an indole ring or an azahomoamantyl ring; each R⁶ is a heteroatom-containing function group aliphatic, aryl, heteroaliphatic, or heteroaryl; R⁷ is hydrogen, a heteroatom-containing functional group, aliphatic, or aryl; and each n independently can be an integer ranging from 0 to 8.

In any or all of the above embodiments, ring A is an indole ring, each of R⁶ and R⁷ independently is aliphatic, and n is 2.

In any or all of the above embodiments, ring A is an azahomoadamantyl ring, R⁷ is aliphatic, and n is 0.

In any or all of the above embodiments, the spirooxazine ligand exists in a ring-closed form or a ring-opened form.

In any or all of the above embodiments, the spirooxazine ligand is spiro[azahomoadamantyl-phenanthrolinoxazine or spiro[indoline-phenanthrolinoxazine].

In any or all of the above embodiments, the spirooxazine ligand is a ring-opened or ring-closed form of spiro[azahomoadamantyl-phenanthrolinoxazine] or a ring-opened or ring-closed form of spiro[indoline-phenanthrolinoxazine].

In any or all of the above embodiments, the ring-opened form of the spiro[azahomoadamantyl-phenanthrolinoxazine] has a structure

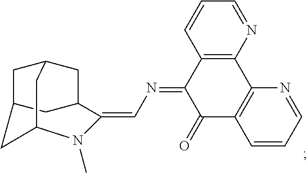 [SMILES: CN1/C(=C/N=C2\C(=O)c3cccnc3-c3ncccc32)C2CC3CC(C2)CC1C3]

and
the ring-opened form of the spiro[indoline-phenanthrolinoxazine] has a structure

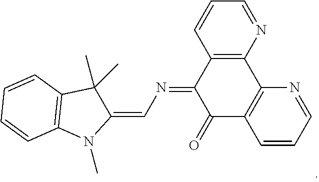 [SMILES: CN1/C(=C/N=C2\C(=O)c3cccnc3-c3ncccc32)C(C)(C)c2ccccc21]

In any or all of the above embodiments, a metal of the electronically bistable metal-containing component is a transition metal selected from Ti, V, Co, Mo, Cr, Fe, Mn, Ni, Zr, Mo, W, Cu, and combinations or alloys thereof.

In any or all of the above embodiments, the magnetically bistable complex has a formula

PₓM_{w}(L^{r})_{y}(L^{a})_{z}

wherein M is a metal of the electronically bistable metal-containing component; each of L^{r} and L^{a} are ligands of the electronically bistable metal-containing component; P is the optically bistable component; and each of w, x, y, and z independently is an integer selected from 1 to 8.

In any or all of the above embodiments, the magnetically bistable complex or cluster thereof is selected from a complex or cluster provided by Table 2 or any other complex or cluster described herein.

In any or all of the above embodiments, the tunnel barrier layer comprises an oxide.

In any or all of the above embodiments, the oxide is a metal oxide.

In any or all of the above embodiments, the metal oxide is selected from a magnesium oxide, an aluminum oxide, titanium oxide, or mixtures thereof.

In any or all of the above embodiments, the ferromagnetic layer comprises a ferromagnetic material.

In any or all of the above embodiments, the ferromagnetic material comprises iron, cobalt, boron, nickel, manganese gallium oxides, manganese germanium oxide, or any mixture or alloy thereof

In any or all of the above embodiments, the fixed layer comprises CoFeB, CoFe, NiFe, Co, Fe, manganese gallium oxides, manganese germanium oxide.

In any or all of the above embodiments, the magnetic tunnel junction can further comprise one or more electrode layers positioned adjacent or substantially adjacent to the photomagnetic layer and/or the ferromagnetic layer.

In any or all of the above embodiments, the magnetic tunnel junction can further comprise a pinning layer, a reference layer, a multilayer structure layer, or any combination thereof.

In any or all of the above embodiments, the pinning layer is positioned adjacent to or substantially adjacent to the ferromagnetic layer comprises Ir, Mn, Co, Fe, B, Ni, or any mixture or alloy thereof.

Also disclosed herein are embodiments of an array, comprising a plurality of magnetic tunnel junctions according to any or all of the above embodiments.

Also disclosed herein are embodiments of a light-induced magnetic memory device, comprising: one or more magnetic storage cells, wherein at least one magnetic storage cell comprises a magnetic tunnel junction comprising a photomagnetic layer comprising a magnetically bistable complex comprising an optically bistable photoisomerizable component; and an electronically bistable metal-containing component; wherein the optically bistable photoisomerizable component is coupled to a metal of the electronically bistable metal-containing component; a tunnel barrier layer positioned adjacent or substantially adjacent to the photomagnetic layer; and a ferromagnetic layer positioned adjacent or substantially adjacent to the tunnel barrier layer.

In any or all of the above embodiments, the light-induced magnetic memory device can comprise one or more bit lines, one or more word lines, one or more source lines, or a combination thereof, wherein the one or more bit lines, word lines, and/or source lines are coupled to the one or more magnetic storage cells.

Also disclosed herein are embodiments of a magnetically bistable complex or cluster thereof, wherein the magnetically bistable complex has a structure satisfying a formula

PₓM_{w}(L^{r})_{y}(L^{a})_{z}

wherein:
M is a row 1 transition metal selected from Ti, V, Co, Mo, Cr, Fe, Mn, Ni, Zr, Mo, W, Cu or an alloy or mixture thereof;
L^{r} is a redox active ligand having a structure satisfying a formula

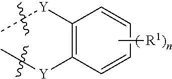

wherein each Y independently is selected from O, S, or NR^{a}, wherein R^{a} is selected from hydrogen, aliphatic, aryl, heteroaliphatic, or heteroaryl; each R¹ independently is selected from hydroxyl, aliphatic, aryl, heteroaliphatic, or heteroaryl; and n is an integer selected from 1 to 4;
L^{a} is an ancillary ligand selected from a cyano ligand, an azide ligand, or other organic ligand capable of undergoing a metal-to-metal charge transfer process with M;
P is a photoisomerizable ligand having a structure satisfying a formula

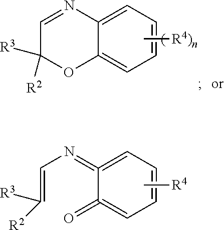

wherein R² and R³ combine to form a 5- to 8-membered aliphatic or heteroaliphatic cyclic ring or aliphatic or heteroaliphatic bicyclic ring; each R⁴ independently is selected from a functional group comprising —NH₂, —OH, —OR⁵, —C(O)H, —C(O)OH, —C(O)R^{b}, —C(O)OR^{b}, —SH, —SR^{b}, —P(R^{b})₃, and cyano, wherein R^{b} is selected from aliphatic, aryl, heteroaliphatic, or heteroaryl; or two R⁴ groups are positioned on adjacent carbons and combined to form a fused aromatic ring, which is optionally bound to one or more additional aromatic or heteroaromatic groups comprising one or more heteroatoms selected from N, O, S, or Se; or two R⁴ groups can be positioned on adjacent carbons and combined to form a fused heteroaromatic ring comprising one or more heteroatoms selected from N, O, S, or Se, which is optionally bound to one or more additional aromatic or heteroaromatic groups comprising one or more heteroatoms selected from N, O, S, or Se; and n is an integer selected from 1 to 4; and each of w, x, y, and z are integers independently selected from 1 to 8; and provided that if the redox active ligand is 3,5-di-tert-butylbenzene-1,2-diol, 2,4-di-tert-butyl-6-hydroxycyclohexa-2,5-dien-1-one, or a catecholate, a semiquinone, or a quinone form thereof, and the photoisomerizable ligand is spiro[azahomoadamantyl-phenanthrolinoxazine] or spiro[indoline-phenanthrolinoxazine], then M is not cobalt.

In yet other embodiments, a solid state magnetically bistable complex or cluster thereof is disclosed, wherein the magnetically bistable complex has a structure satisfying a formula

PₓM_{w}(L^{r})_{y}(L^{a})_{z}

wherein:
M is a row 1 transition metal selected from Ti, V, Co, Mo, Cr, Fe, Mn, Ni, Zr, Mo, W, Cu or an alloy or mixture thereof;
L^{r} is a redox active ligand having a structure satisfying a formula

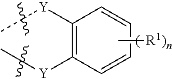

wherein each Y independently is selected from O, S, or NR^{a}, wherein R^{a} is selected from hydrogen, aliphatic, aryl, heteroaliphatic, or heteroaryl; each R¹ independently is selected from hydroxyl, aliphatic, aryl, heteroaliphatic, or heteroaryl; and n is an integer selected from 1 to 4;
L^{a} is an ancillary ligand selected from a cyano ligand, an azide ligand, or other organic ligand capable of undergoing a metal-to-metal charge transfer process with M;
P is a photoisomerizable ligand having a structure satisfying a formula

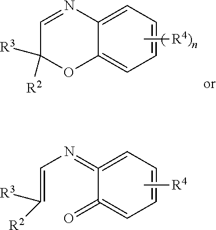

wherein R² and R³ combine to form a 5- to 8-membered aliphatic or heteroaliphatic cyclic ring or aliphatic or heteroaliphatic bicyclic ring; each R⁴ independently is selected from a functional group comprising —NH₂, —OH, —OR⁵, —C(O)H, —C(O)OH, —C(O)R^{b}, —C(O)OR^{b}, —SH, —SR^{b}, —P(R^{b})₃, and cyano, wherein R^{b} is selected from aliphatic, aryl, heteroaliphatic, or heteroaryl; or two R⁴ groups are positioned on adjacent carbons and combined to form a fused aromatic ring, which is optionally bound to one or more additional aromatic or heteroaromatic groups comprising one or more heteroatoms selected from N, O, S, or Se; or two R⁴ groups can be positioned on adjacent carbons and combined to form a fused heteroaromatic ring comprising one or more heteroatoms selected from N, O, S, or Se, which is optionally bound to one or more additional aromatic or heteroaromatic groups comprising one or more heteroatoms selected from N, O, S, or Se; and n is an integer selected from 1 to 4; and
each of w, x, y, and z are integers independently selected from 1 to 8; wherein the magnetically bistable complex exhibits a PISCES process at room temperature when in the solid state and provided that if the redox active ligand is 3,5-di-tert-butylbenzene-1,2-diol, 2,4-di-tert-butyl-6-hydroxycyclohexa-2,5-dien-1-one, or a catecholate, a semiquinone, or a quinone form thereof, and the photoisomerizable ligand is spiro[indoline-phenanthrolinoxazine], then M is not cobalt.

In any or all of the above embodiments, each Y independently is oxygen or hydroxyl and each R¹ is aliphatic selected from methyl, ethyl, propyl, isopropyl, butyl, isobutyl, tert-butyl, cyclopentyl, or cyclohexyl.

In any or all of the above embodiments, the redox active ligand is a dioxolene ligand.

In any or all of the above embodiments, the redox active ligand is

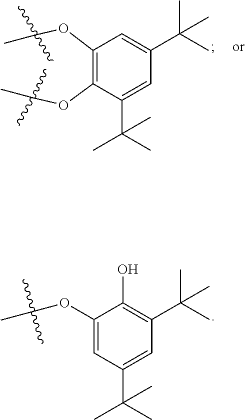 [SMILES: *Oc1cc(C(C)(C)C)cc(C(C)(C)C)c1O* ; *Oc1cc(C(C)(C)C)cc(C(C)(C)C)c1O]

In any or all of the above embodiments, each P independently is a spirooxazine ligand.

In any or all of the above embodiments, the spirooxazine ligand has a structure satisfying a formula selected from

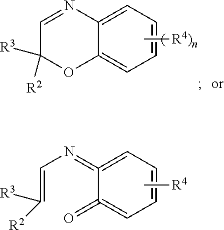

wherein R² and R³ combine to form a 5- to 8-membered aliphatic or heteroaliphatic cyclic ring or aliphatic or heteroaliphatic bicyclic ring; each R⁴ independently is selected from a functional group comprising —NH₂, —OH, —OR⁵, —C(O)H, —C(O)OH, —C(O)R^{b}, —C(O)OR^{b}, —SH, —SR^{b}, —P(R^{b})₃, and cyano, wherein R^{b} is selected from aliphatic, aryl, heteroaliphatic, or heteroaryl; or two R⁴ groups are positioned on adjacent carbons and combined to form a fused aromatic ring, which is optionally bound to one or more additional aromatic or heteroaromatic groups comprising one or more heteroatoms selected from N, O, S, or Se; or two R⁴ groups can be positioned on adjacent carbons and combined to form a fused heteroaromatic ring comprising one or more heteroatoms selected from N, O, S, or Se, which is optionally bound to one or more additional aromatic or heteroaromatic groups comprising one or more heteroatoms selected from N, O, S, or Se; and n is an integer selected from 1 to 4.

In any or all of the above embodiments, the spirooxazine ligand has a structure satisfying a formula selected from

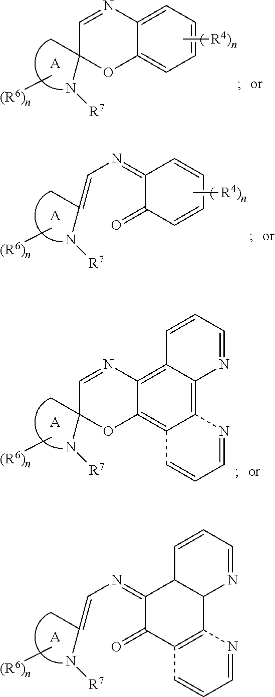

wherein ring A is an indole ring or an azahomoamantyl ring; each R⁶ is a heteroatom-containing function group aliphatic, aryl, heteroaliphatic, or heteroaryl; R⁷ is hydrogen, a heteroatom-containing functional group, aliphatic, or aryl; and each n independently can be an integer ranging from 0 to 8.

In any or all of the above embodiments, ring A is an indole ring, each of R⁶ and R⁷ independently is aliphatic, and n is 2.

In any or all of the above embodiments, ring A is an azahomoadamantyl ring, R⁷ is aliphatic, and n is 0.

In any or all of the above embodiments, the spirooxazine ligand exists in a closed form or an open form.

In any or all of the above embodiments, the spirooxazine ligand is spiro[azahomoadamantyl-phenanthrolinoxazine].

In any or all of the above embodiments, the spirooxazine ligand is a ring-opened form of spiro[azahomoadamantyl-phenanthrolinoxazine] at room temperature.

In any or all of the above embodiments, the opened form of the spiro[azahomoadamantyl-phenanthrolinoxazine] has a structure

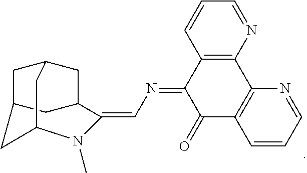 [SMILES: CN1/C(=C/N=C2\C(=O)c3cccnc3-c3ncccc32)C2CC3CC(C2)CC1C3]

In any or all of the above embodiments, M is cobalt.

In any or all of the above embodiments, the magnetically bistable complex or cluster is selected from those recited in Table 2.

Also disclosed herein are embodiments of a method for making a magnetically bistable complex, comprising combining a solution comprising a metal complex precursor with a photoisomerizable ligand to obtain a reaction mixture, wherein the metal complex precursor has a formula M(L^{r})₂(pyridine)₂, wherein M is a row 1 transition metal, L^{r} is a redox active ligand; and the photoisomerizable ligand has a structure satisfying a formula

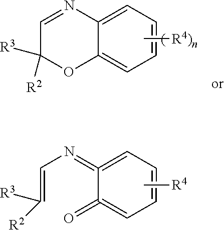

wherein R² and R³ combine to form a 5- to 8-membered aliphatic or heteroaliphatic cyclic ring or aliphatic or heteroaliphatic bicyclic ring; each R⁴ independently is selected from a functional group comprising —NH₂, —OH, —OR⁵, —C(O)H, —C(O)OH, —C(O)R^{b}, —C(O)OR^{b}, —SH, —SR^{b}, —P(R^{b})₃, and cyano, wherein R^{b} is selected from aliphatic, aryl, heteroaliphatic, or heteroaryl; or two R⁴ groups are positioned on adjacent carbons and combined to form a fused aromatic ring, which is optionally bound to one or more additional aromatic or heteroaromatic groups comprising one or more heteroatoms selected from N, O, S, or Se; or two R⁴ groups can be positioned on adjacent carbons and combined to form a fused heteroaromatic ring comprising one or more heteroatoms selected from N, O, S, or Se, which is optionally bound to one or more additional aromatic or heteroaromatic groups comprising one or more heteroatoms selected from N, O, S, or Se; and n is an integer selected from 1 to 4.

In any or all of the above embodiments, the method can further comprise isolating the magnetically bistable complex by filtering the magnetically bistable complex from the reaction mixture using a solvent.

In any or all of the above embodiments, 1 equivalent of the metal complex precursor is combined with 1 to 8 equivalents of the photochromic ligand per metal center.

In any or all of the above embodiments, M is a transition metal selected from cobalt, iron, nickel, copper, manganese, chromium, molybdenum, rhodium, ruthenium, tungsten; and each Lₘ independently is an organic ligand.

In any or all of the above embodiments, the redox active ligand has a structure satisfying a formula

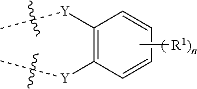

wherein each Y independently is selected from O, S, or NR^{a}, wherein R^{a} is selected from hydrogen, aliphatic, aryl, heteroaliphatic, or heteroaryl; each R¹ independently is selected from hydroxyl, aliphatic, aryl, heteroaliphatic, or heteroaryl; and n is an integer selected from 1 to 4;

In any or all of the above embodiments, the photochromic ligand has a structure satisfying a formula selected from

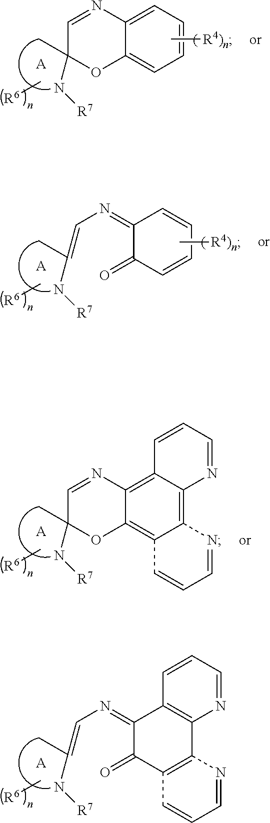

wherein ring A is an indole ring or an azahomoamantyl ring; each R⁶ is a heteroatom-containing function group aliphatic, aryl, heteroaliphatic, or heteroaryl; R⁷ is hydrogen, a heteroatom-containing functional group, aliphatic, or aryl; and each n independently can be an integer ranging from 0 to 8.

In any or all of the above embodiments, the magnetically bistable complex is

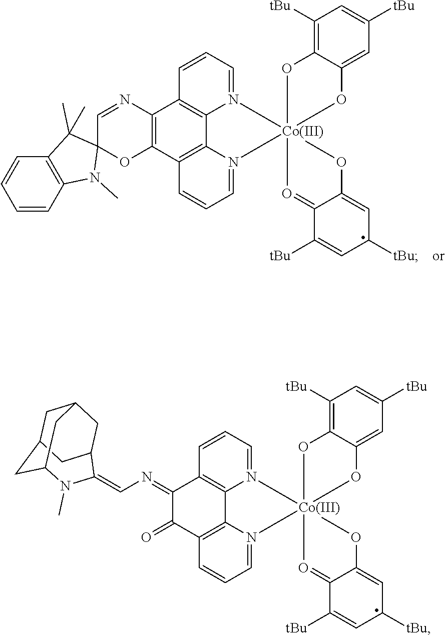

or another possible redox form thereof.

### VII. Examples

### General Synthetic Methods and Reagent/Solvent Preparation

The synthesis of APSO was carried out under inert conditions using standard Schlenk techniques, with final work up carried out under aerobic conditions. Solvents were purified by distillation under inert conditions as described. DMF was dried over P₂O₅, distilled under nitrogen, and stored under inert atmosphere over molecular sieves (4 Å). Prior to use, DMF was further degassed by three freeze/pump/thaw cycles. Triethylamine was pre-dried over KOH followed by drying over CaH₂, distilled under nitrogen, and stored over molecular sieves (4 Å). The synthesis and purification of the complexes were carried out under argon using standard Schlenk techniques. The tetrameric cobalt complex precursor [Co₄(3,5-DTBQ)₈] was prepared using a manner consistent with the procedure published in Buchanan, R. M.; Fitzgerald, B. J.; Pierpont, C. G., Semiquinone Radical Anion Coordination to Divalent Cobalt and Nickel. Structural Features of the Bis(3,5-di-tert-butyl-1,2-semiquinone)cobalt(II) Tetramer, Inorg. Chem. 1979, 18, 3439-3444]. In some examples, the cobalt tetramer, prepared from cobalt carbonyl and di-tertbutyl-benzoquinone [Co4(3,5-DTB SQ)8]⋅toluene[1] is suspended in pyridine (15 mL) and heated to reflux for 1 hour, resulting in a clear blue-green solution. After cooling to room temperature, dark blue-green crystals were formed. The reaction mixture was left undisturbed for 24 hours, and the resultant crystals filtered off, washed with pyridine, and dried in vacuo. The as prepared [Co(3,5-DTBSQ)2(py)2] was dissolved in diethyl ether, resulting in a deep blue solution. APSO was slowly added over 5 minutes, and the mixture was stirred for 8 hours and left to stand for an additional 12 hours. Fine purple needles were formed, which were isolated by filtration, washed with diethyl ether (2×5 mL) followed by pentane (2×5 mL), and dried in vacuo. A bright purple microcrystalline solid was obtained. The monomeric complex [Co(3,5-DTBQ)₂(py)₂] was prepared utilizing the procedure described below. All solvents used were spectroscopic-grade, dry, and deoxygenated. CH₂Cl₂ was acquired from an MBraun solvent purification system. Diethyl ether and toluene were dried over Na/benzophenone, and distilled under argon. CCl₄ was washed with NaOH_{(aq)}, washed with water, passed through a silica gel plug, dried over MgSO₄, distilled from P₂O₅, and freeze-pump-thawed. Due to the high oxygen-sensitivity of complex 1 in solution all solvents were additionally degassed after purification by three freeze-pump-thaw cycles. The synthesis of 4-methylspiro[4-azahomoadamantane-5,2′-[2H-1,4]ox-azino-[2,3-f][1,10] phenanthroline] (APSO) was carried out as described below.

### Preparation of 4-methylspiro[4-azahomoadamantane-5,2′-[2H-1,4]ox-azino-[2,3-f][1,10] phenanthroline] (APSO)

4,5-Dimethyl-4-azahomoadamant-4-enium iodide (454 mg, 1.5 mmol) was dissolved in DMF (10 mL), and cooled to 0° C. in an ice bath. Triethylamine (280 μL, 1.2 equiv.) was added, and the solution was stirred for a further 30 min. 5-Hydroxy-6-nitroso-1,10-phenanthroline (335 mg, 1.5 mmol) and molecular sieves (4 Å) were added. The mixture was allowed to warm to 22° C. followed by heating to 65° C. for 3 h during which time the color of the solution became purple. The solution was cooled to room temperature, the solvent removed in vacuo, and the resultant purple solid taken up in CH₂Cl₂ (60 mL), filtered, washed with water (2×10 mL), and dried over MgSO₄. The solvent was removed in vacuo, and the compound pre-purified by column chromatography (neutral Al₂O₃, CH₂Cl₂ eluent) before recrystallization from acetone over 12 hours, resulting in the formation of green iridescent crystals. The crystals were isolated, washed with cold ethyl acetate, and dried under vacuum. Yield: 343 mg (60%). Spectroscopic characterization and purity was consistent with the previously published procedure.

### Preparation of the cobalt complex [Co(3,5-DTBSQ)₂(py)₂] [Co₄(3,5-DTBSQ)₈]⋅toluene

(510 mg, 0.244 mmol) was suspended in pyridine (15 mL) and heated to reflux for 1 h, resulting in a clear blue-green solution. After cooling to room temperature, dark blue-green crystals were formed. The reaction mixture was left undisturbed for 24 h, and the resultant crystals filtered off, washed with pyridine, and dried en vacuo (638 mg, 95% yield). FT-IR (KBr, cm⁻¹): ν 3051 (m), 2952 (vs), 2904 (vs), 2867 (m), 1607 (s), 1579 (s), 1505 (s), 1481 (vs), 1451 (vs), 1437 (s), 1421 (m), 1388 (w), 1358 (s), 1284 (vs), 1247 (s), 1210 (s), 1149 (m), 1095 (s), 1069 (vs), 1039 (s), 1017 (s), 986 (vs), 929 (m), 904 (s), 877 (w), 856 (m), 827 (w), 801 (w), 764 (w), 747 (m), 705 (s), 675 (w), 649 (m), 601 (vw), 579 (w), 546 (m), 514 (m), 497 (m), 472 (m).

Co(DTBQ)₂(APSO) (1).

[Co(3,5-DTBSQ)₂(py)₂] (60 mg, 0.09 mmol, 1.00 equiv.) was dissolved in diethyl ether (20 mL), resulting in a deep blue solution. APSO (33 mg, 0.95 equiv.) was slowly added over 5 minutes, and the mixture was stirred for 8 h and left to stand for an additional 12 h. Fine purple needles were formed, which were isolated by filtration, washed with diethyl ether (2×5 mL) followed by pentane (2×5 mL), and dried in vacuo. A bright purple microcrystalline solid was obtained. As a solid, complex 1 is stable in air and can be handled under aerobic conditions, but in some embodiments when used in solution, inert conditions can be utilized. On the basis of elemental analysis, the complex was isolated as the hydrate, 1.3H₂O (64 mg, 79% yield). Anal. Calcd for C₅₂H₆₄CoN₄O₅.3H₂O: C, 66.58; H, 7.52; N, 5.97. Found: C, 66.73; H, 7.14; N, 5.55. ESI-MS (MeOH, NaI): m/z (%) 1047 (50) [Co(APSO)₂(DTBQ)]⁺, 883 (5) [Co(APSO)(DTBQ)₂]⁺, 683 (40) [Na(DTBQ)₃]+, 663 (7) [Co(APSO)(DTBQ)]⁺, 463 (100) [Na(DTBQ)₂]+, 243 (55) [Na(DTBQ)]⁺. In the ESI spectrum, the peak for the parent complex ion [Co(DTBQ)₂(APSO)]⁺ is small (5%) compared to the more intense peak of a [Co(DTBQ)(APSO)₂]⁺ fragment (50%). It is noteworthy here that the rigorously characterized Co(DTBQ)₂(phen) complex shows the same fragmentation pattern. Moreover there are additional strong peaks at m/z values of 243, 463, and 683, which can be attributed to a sodium ion coordinated to either one, two or three 3,5-DTBQ molecules. This fact suggests that the [Co(DTBQ)(NN)₂]⁺ fragment is either a charged rearrangement product or, perhaps more likely, an oxidation product resulting from embodiments of the complex when in solution, rather than a low-abundance contaminant common to these systems. FT-IR (KBr, cm⁻¹): ν 3065 (m), 2951 (vs), 2914 (vs), 2866 (m), 1608 (m), 1571 (m), 1559 (m), 1476 (s), 1452 (vs), 1423 (s), 1415 (vs), 1387 (w), 1356 (vs), 1349 (vs), 1325 (m), 1317 (m), 1241 (m), 1227 (vs), 1130 (vs), 1102 (vs), 1087 (m), 1064 (m), 1037 (m), 1014 (m), 985 (m), 947 (m), 885 (m), 857 (w), 824 (w), 812 (w), 745 (m), 732 (m), 690 (w), 652 (vw), 634 (vw). ¹H NMR (500 MHz, toluene-d⁸) tentative assignment of RO form: δ 89 (br s, 1H, phen), 87 (br s, 1H, phen), 34.3 (br s, 1H, phen), 30.9 (br s, 1H, phen), 14.1 (br s, 18H, t-butyl), 12.8 (br s, 1H, phen), 12.6 (br s, 1H, phen), 9.3 (s, 1H, CH═N), 4.7 (s, 1H), 3.3 (s, 1H), 2.8 (s, 3H, CH₃), 2.1-0.9 (br m); tentative assignment of RC form: δ 99 (br s, 1H, phen), 97 (br s, 1H, phen), 36.0 (br s, 1H, phen), 33.1 (br s, 1H, phen), 14.6 (br s, 18H, t-butyl), 12.8 (br s, 1H, phen), 12.6 (br s, 1H, phen), 8.0 (s, 1H, CH═N), 4.3 (s, 3H, CH₃), 2.6 (s), 2.1-0.9 (br m).

### Characterization Methods

### Spectroscopic Methods—

Variable-temperature NIR spectroscopy of 1 was performed with a Perkin Elmer (PE) Lambda 1050 spectrophotometer, and temperature control was achieved using an Oxford OptistatCF continuous-flow static-exchange-gas cryostat system fitted with inner sapphire windows and middle and outer infrasil quartz windows. A thin-film of complex 1 was drop cast onto infrasil quartz discs from a concentrated spectroscopic-grade toluene solution inside an argon atmosphere glove box. Spectra were acquired in increments from 90 to 350 K with ˜30 min of equilibration at each temperature. Background corrections were performed by correcting for a blank spectrum of the cryostat containing a blank infrasil quartz disc at room temperature.

Solution-state variable-temperature UV-vis spectroscopy of 1 was performed with an Agilent 8453 spectrophotometer. A 10⁻⁵ M solution was prepared in toluene and transferred to a long-stemmed quartz cuvette sealed under argon. The cuvette was immersed in a quartz dewar filled with spectroscopic-grade acetone. A spectrum was acquired at ˜300 K before cooling the acetone solution to 196 K with dry ice and acquiring a low-temperature spectrum. A final spectrum was acquired after warming the solution to near room temperature.

### Irradiation Experiments—

UV-vis irradiation experiments on 1 were performed with an Agilent 8453 spectrophotometer. Sample solutions were prepared in toluene under argon, and transferred to long-stemmed quartz cuvettes under inert atmosphere. In the absence of ambient light, solutions were uniformly stirred while subjected to continuous visible multiline (450 to 550 nm) irradiation at 100 mW/cm², generated using a Spectra-Physics Stabilite 2018 mixed-gas Ar—Kr ion laser and directed through the top of the cuvette via a Newport liquid light guide. The rates of thermal relaxation were determined in the absence of light after generating a photostationary state by following the absorbance kinetics at the RO π-π* λₘₐₓ and fitting A_{∞}−Aₜ (where Aₜ represents the absorbance at a given time, t, and A_{∞} represents the absorbance after thermal relaxation or a close approximation thereof) to both first-order monoexponential (A=Aₒe^{kt}, where Aₒ is the initial absorbance) and, if appropriate, biexponential (A=Aₒe^{kt}+Bₒe^{k′t}) rate functions by linear least-squares methods. Exemplary absorbance data is provided by FIG. 32, which illustrates the kinetics of thermal relaxation of a representative complex at 4250 cm⁻¹ in toluene solution after generating a photostationary state upon irradiation with visible light for 180 seconds.

Solution-state NIR irradiation experiments of 1 were performed with a PE Lambda 1050 spectrometer similarly to those described above. For solution-state experiments, a saturated solution was prepared in spectroscopic-grade toluene and filtered into a quartz solution sample cell. Spectra were acquired at 300 K with a toluene background subtraction. In the absence of ambient light, solutions were subjected to multiline steady-state visible (450 to 550 nm) irradiation at 100 mW/cm². The rates of thermal return were determined by following the absorbance kinetics at the NIR band at 4250 cm⁻¹ and fitting A_{∞}−Aₜ to a first-order monoexponential (A=Aₒe^{kt}) rate function. For solid-state experiments, thin-film samples prepared from toluene solution were drop-cast onto infrasil quartz disks and irradiated from the top at a 45° angle. The rates of thermal return were determined by fitting A_{∞}−Aₜ to a first-order biexponential (A=Aₒe^{kt}+Bₒe^{k′t}) rate function.

### Solid-State Magnetic Measurements—

Magnetometry measurements were carried out on samples of 1 in the temperature range 2-350 K with a Quantum Design Magnetic Property Measurement System (MPMS XL-5) at a field of 10,000 Oe. Polycrsytalline samples were measured in gelule/straw sample holders, with diamagnetic corrections applied for the sample and sample holder. The diamagnetic contribution to the susceptibility of the samples was calculated using Pascal's constants with constitutive corrections (−5.277×10⁻¹ emu·K·mol⁻¹) for the molecular formula Co(II)(DTBQ)₂(APSO). The sample was corrected for the diamagnetic susceptibility of the gelule and insertion tube (−2.4×10⁻⁷ emu·K·mol⁻¹), which is negligible relative to the sample magnetization.

### Solution-State Magnetic Measurements (Evan's Method)—

In an inert atmosphere argon glove box, compound 1 (2.2 mg) was dissolved quantitatively in toluene-d₈ (1.00 mL), and the solution was transferred to a 5-mm NMR tube fitted with a coaxial insert tube and filled with toluene-d₈. Spectra were acquired with a Bruker AVANCE 500 MHz NMR spectrometer between 200 and 350 K at 10 K intervals. Evan's method was used to determine the solution-state magnetic susceptibility of the sample by monitoring the frequency shift of the CHD₂-C₆D₆ proton resonance. The gram magnetic susceptibility of the sample, χ_{g}, was calculated with Eq. 1,

$${χ}_{g} = - \frac{3 Δ v}{4 π mv} + {χ}_{g 0} + {χ}_{g 0} \frac{{ρ}_{0} - {ρ}_{s}}{m} \qquad ( 1 )$$

where Δν (Hz) is the shift between the resonances for the solute-containing solvent and the reference solvent, ν (Hz) is the operating frequency of the NMR spectrometer, m is the mass (g) of paramagnetic solute in 1.00 mL of solvent, χ_{g0} is the gram magnetic susceptibility of the solvent, ρ₀ is the density of the pure solvent, and ρₛ is the density of the solute-containing solvent. The m value was corrected for the change in solvent density at each temperature. The temperature-dependent density of the solvent was approximated by applying the very nearly linear behaviour of the density of toluene between 200 and 350 K to the density of toluene-d₈ at 298 K (0.943 g/mL). The second and third terms in Eq. 1 were neglected. The molar susceptibilities, χ_{M}, were calculated from the χ_{g} values and were subsequently corrected for the diamagnetic contribution of the complex, χ_{d} (same as those used for the solid-state magnetic measurements; vide infra), to obtain the paramagnetic contribution to the molar magnetic moment, χ_{M}T.

### Photomagnetism Measurements on Thin-Film Samples—

DC-SQUID measurements on samples of 1 were obtained at 290, 300, and 310 K with a Quantum Design Magnetic Property Measurement System at a field of 30,000 Oe. Thin-film samples were prepared by drop-casting from a saturated toluene solution of 1 on a quartz disc followed by drying of the sample under vacuum for 24 h. The accurate mass of the sample was determined by weighing the quartz disc before and after thin-film deposition. The quartz disc was placed inside the Quantum Design fiber optic sample holder (FOSH) and subjected to multiline visible (457.9 to 568.2 nm) irradiation at either 2.5 or 5 mW/mm², generated using a Spectra-Physics Stabilite 2018 mixed-gas Ar—Kr ion laser coupled to the FOSH through a Quantum Design HM25 fiber optic bundle. Data points were collected every 20 s. The data were corrected for the magnetic moment of the blank FOSH (3×10⁻⁵ emu) determined under the same conditions.

### X-Ray Crystallographic Analysis—

A green, tablet-like crystal of C₅₂H₆₄N₄O₅Co having approximate dimensions of 0.02×0.05×0.05 mm was mounted on a fiber loop. All measurements were made with a Bruker APEX DUO diffractometer with cross-coupled multilayer optics Cu—K_{α} radiation (λ=1.54178 Å). The data were collected at a temperature of −183.0±0.1° C. to a maximum 2θ value of 89.0°. Data were collected in a series of ϕ and φ scans in 1.5° oscillations using 120.0-second exposures. The crystal-to-detector distance was 59.72 mm. Of the 12902 reflections that were collected, 3610 were unique (Rᵢₙₜ=0.150); equivalent reflections were merged. Data were collected and integrated using the Bruker SAINT software package. The linear absorption coefficient, μ, for Cu—Kα radiation is 33.11 cm⁻¹. Data were corrected for absorption effects using the multi-scan technique (SADABS), with minimum and maximum transmission coefficients of 0.769 and 0.936, respectively. The data were corrected for Lorentz and polarization effects. The structure was solved by direct methods. All non-hydrogen atoms were refined anisotropically. All hydrogen atoms were placed in calculated positions. The final cycle of full-matrix least-squares refinement Σw(Fₒ²−F_{c}²)² on F² was based on 3610 reflections and 572 variable parameters and converged (largest parameter shift was 0.00 times its esd) with unweighted and weighted agreement factors of R₁ [I>2σ(I)]=Σ∥Fₒ|−|F_{c}∥/Σ|Fₒ|=0.076 and wR₂ [all data]=[Σ(w(Fₒ² F_{c}²)²)/Σw(Fₒ²)²]^{1/2}=0.172. The standard deviation of an observation of unit weight {[Ew(Fₒ²−F_{c}²)²/(Nₒ−Nᵥ)]^{1/2} where Nₒ is the number of observations and Nᵥ is the number of variables was 1.03. The weighting scheme was based on counting statistics. The maximum and minimum peaks on the final difference Fourier map corresponded to 0.25 and −0.34 e⁻·Å⁻³, respectively. Neutral atom scattering factors were taken from Cromer and Waber. Anomalous dispersion effects were included in F_{calc}, and the values for Δf′ and Δf″ were those of Creagh and McAuley. The values for the mass attenuation coefficients are those of Creagh and Hubbell. All refinements were performed using SHELXL-2014 via the OLEX2 interface.

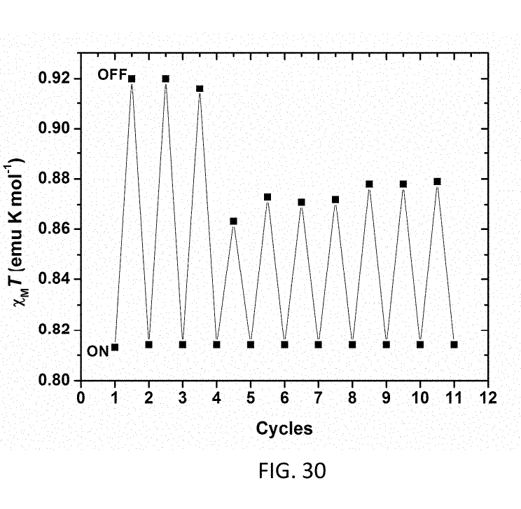

To rule out photothermal effects, the conversion efficiency was measured as a function of irradiation power. A decrease in power by a factor of two leads to a decrease in the photoinduced magnetization by the same factor (FIG. 30). This power dependence of the photomagnetic effect corroborates that the change in magnetization is dominated by a photoinitiated event, with minor contributions from photothermal effects.

The molecular structure of 1 with ellipsoids at 50% probability and hydrogen atoms omitted for clarity is illustrated in FIG. 2. X-ray data are provided in Tables 3-5.

### Example 1—Photoisomerization Effects

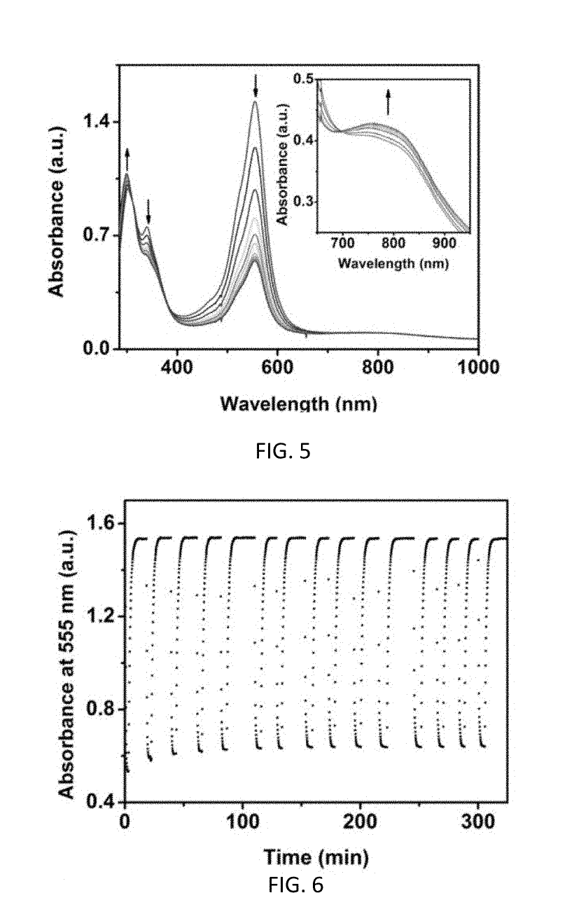

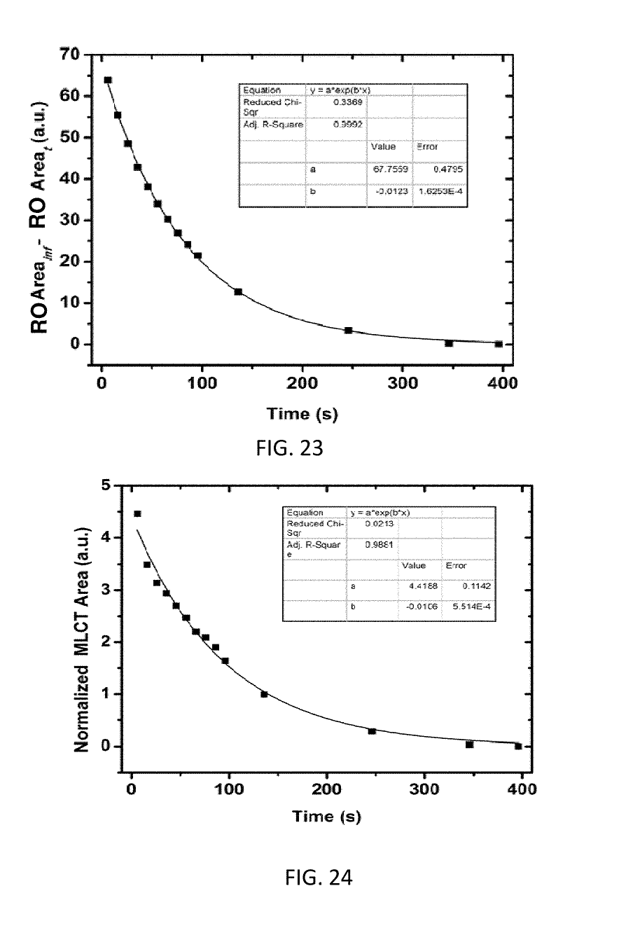

Direct evidence for a photoisomerization-induced spin-charge excited state (PISCES) process in both dilute solution and organic thin films can be observed by changes in the ligand- and cobalt-centered optical transitions with optical excitation. Green-light irradiation of a toluene solution of 1 at 300 K with a mixed-gas Ar—Kr ion laser (λ_{exc}≈450-550 nm, 100 mW) caused RO→RC conversion via photoisomerization, as shown by a decrease in the RO π-π* transition at Δₘₐₓ 555 nm (FIG. 5). Cessation of irradiation caused thermal relaxation to the RO form, which occurred with first-order kinetics and a monoexponential rate constant of k_{obs}=0.01 s⁻¹ (FIG. 23), an order of magnitude slower than thermal relaxation in the parent (APSO) spirooxazine ligand (k_{obs}=0.08 s⁻¹). This exemplary complex exhibited a remarkably high fatigue resistance both in solution and thin films, as evidenced by the minor changes in intensity of the RO π-π* band over multiple irradiation cycles (FIG. 6). In particular disclosed embodiments, the thermal coloration of various ligands (e.g., APeSO, APSO, AIQSO, and AQSO) decreased in the order of APeSO>APSO>AIQSO>AQSO. These ligands are illustrated in Table 1.

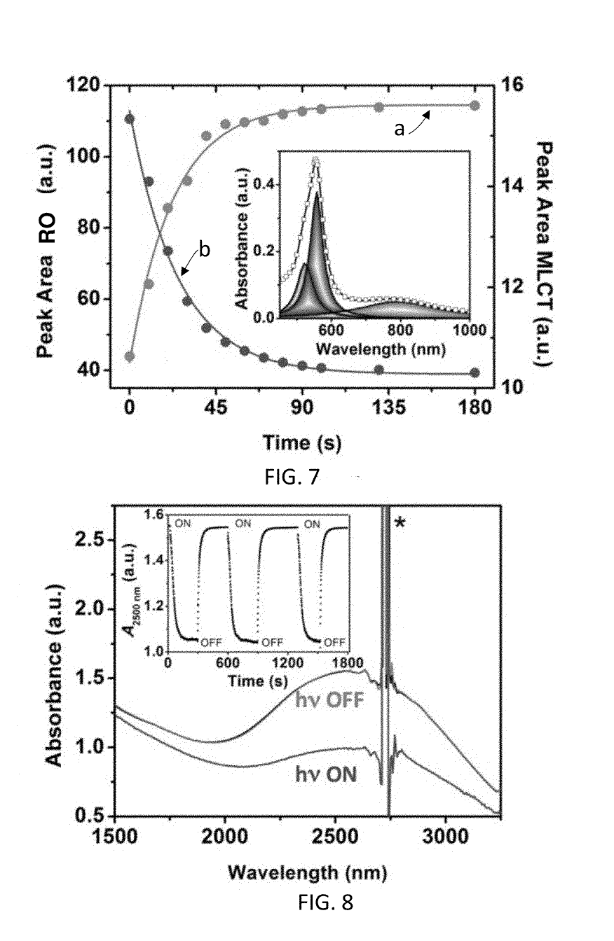

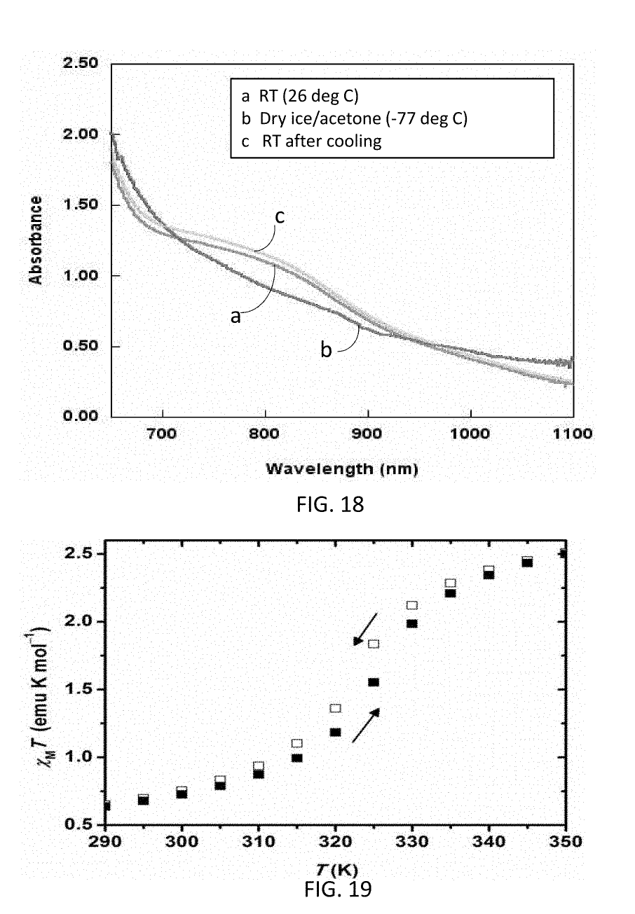

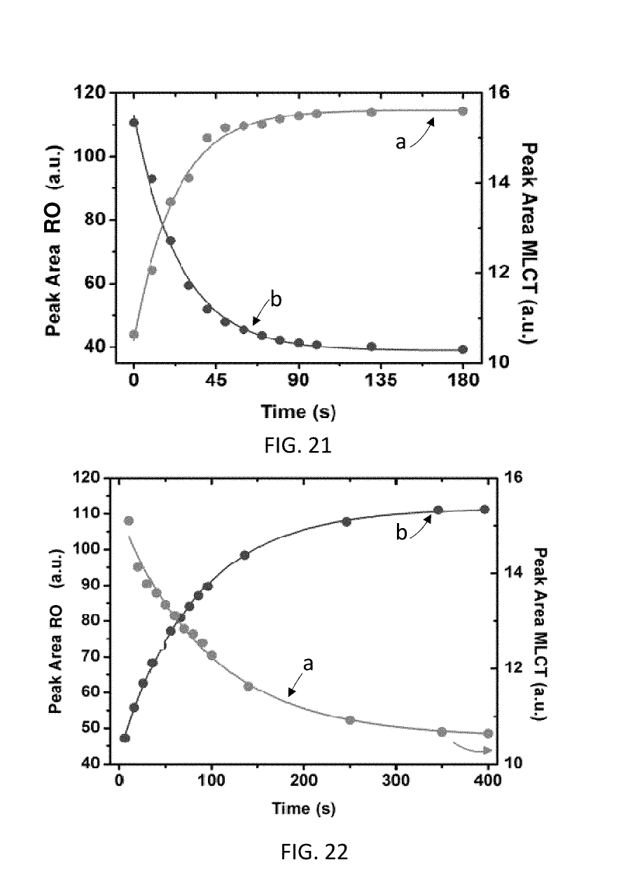

Along with the decrease in the intensity of the RO transition, an increase in the intensity of the hs-Co(II) MLCT band at ˜800 nm was simultaneously observed, with a hypsochromic shift from a Δₘₐₓ of 824 nm to one of 787 nm, and an isosbestic point at ˜700 nm (FIG. 5, inset and FIG. 18), which suggests coupling between the RO→RC photoisomerization and ls-Co(III)→hs-Co(II) charge-transfer/spin-transition processes. The bands in the visible region were deconvoluted into the two dominant vibronic bands ν(1) and ν(2) of the RO π-π* transition and the hs-Co(II) MLCT band, and the changing peak areas were fit to monoexponential rate functions (FIGS. 7, 21 and 22). The rate constants for thermal relaxation for both the RC→RO and hs-Co(II)→ls-Co(III) processes were identical (k_{obs}=0.01 s⁻¹), evidencing the coupling of photoisomerization and CTIST processes.

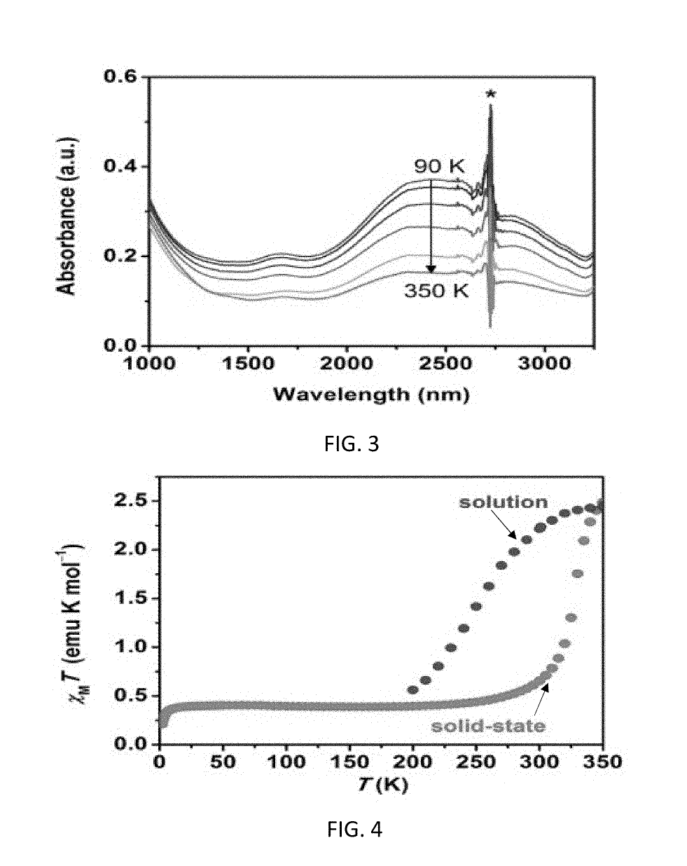

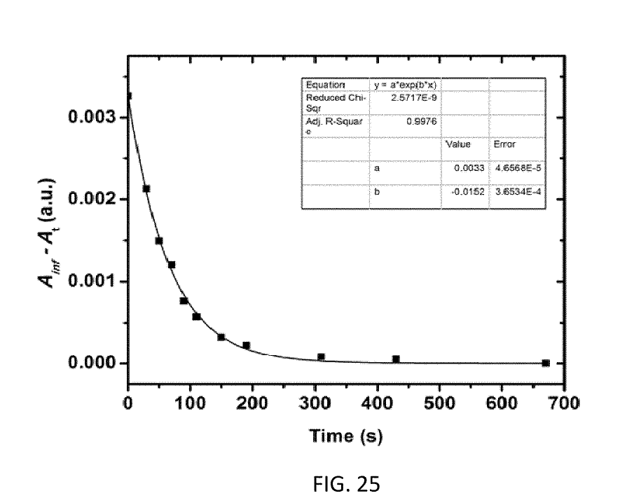

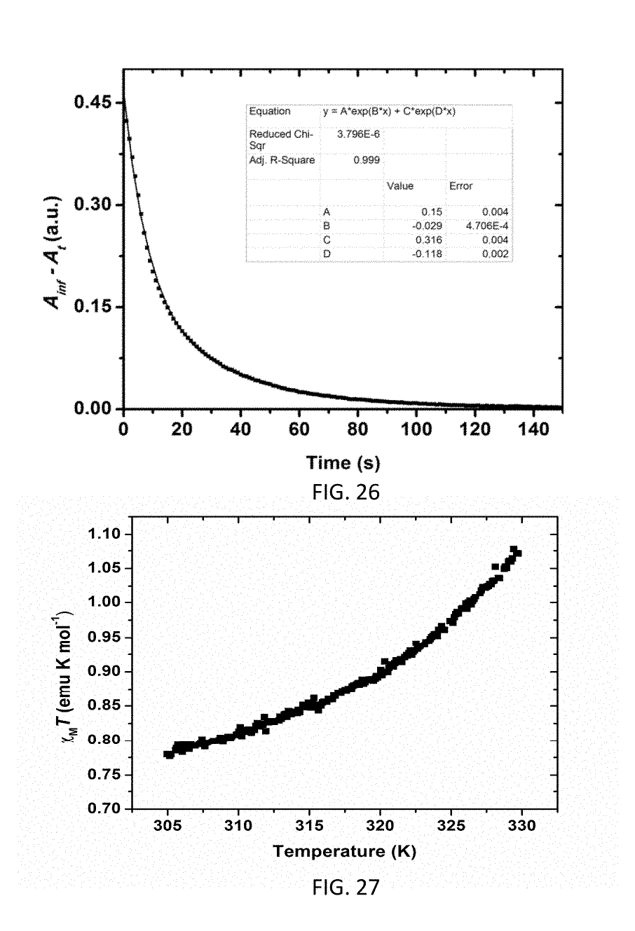

Additional evidence for the electronic coupling between photoisomerizable and electronic states was provided by the behavior of the ls-Co(III)-centered NIR CT band with irradiation. With green-light irradiation and RO→RC conversion, the ls-Co(III)-based NIR band decreased in intensity (toluene and organic thin film, 300 K; FIGS. 3 and 8) due to ls-Co(III)→hs-Co(II) conversion. Repopulation of the ls-Co(III) state occurred with subsequent RC→RO thermal isomerization with a rate constant of k_{obs}=0.01 s in solution (FIGS. 25 and 26), consistent with the thermal relaxation rates measured by optical spectroscopy in the visible region. The behavior of the NIR band with visible irradiation in the thin-film state, prepared by drop-casting from a toluene solution, was similar to that in solution. In this example, thermal relaxation in thin film form occurred with biexponential kinetics (k_{obs}=0.03 s⁻¹ (32%) and 0.1 s⁻¹ (68%); FIG. 26) most likely due to distinct surface and interior populations giving rise to different thermal relaxation rates, as is seen in solid-state samples of spirooxazines. This process is fully reversible and can be repeated for several cycles without significant fatigue (FIG. 8, inset). Optical spectroscopy also revealed that upon visible irradiation, photoisomerization from the RO to the RC form can occur (100→102), with a rapid conversion to the hs-Co(II) state (102→104). Estimates of the rates of hs-Co(II)→ls-Co(III) conversion in solution are 10⁷-10⁸ s⁻¹ for the phenanthroline embodiment. Thermal relaxation induced isomerization to the RO form (104→106), which in turn caused a slow relaxation (10⁻¹ s⁻¹) toward the ls-Co(III) state (106→100). This photochrome-coupled redox-active system affords a novel mechanism for realizing light-controlled magnetic effects via a PISCES process, through which spins may be optically modulated via charge-transfer processes in both solution and the solid state at room temperature.

### Example 2

### Optically Gating Spin States—

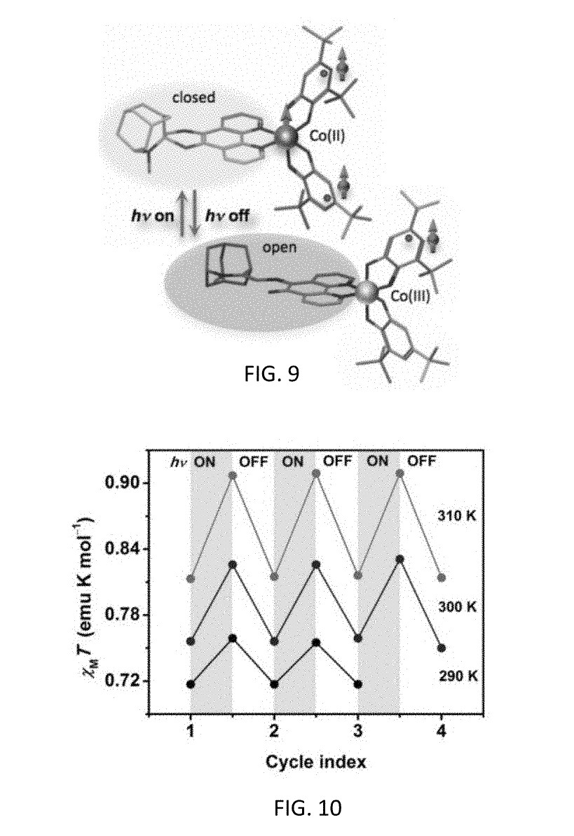

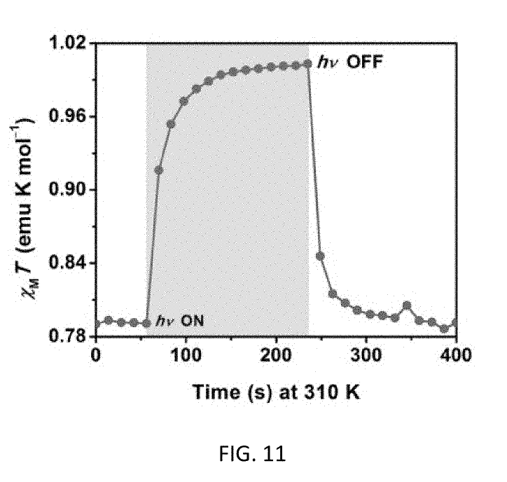

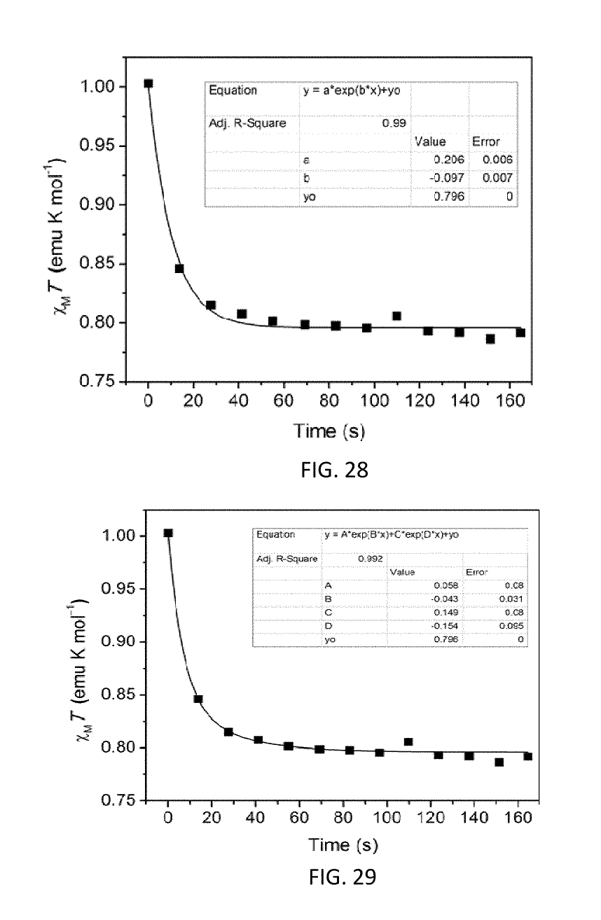

Optical gating of magnetization relies on generating photoinduced spin states with long enough lifetimes at room temperature for direct observation by magnetometry. In this example, steady-state visible irradiation (λ_{exc}≈450-550 nm, 5 mW·mm⁻²) of a thin-film sample in a magnetic property measurement system using a fiber optic sample holder at temperatures between 290-310 K exhibited a dramatic increase in magnetization due to PISCES ls-Co(III)→hs-Co(II) conversion (FIGS. 10 and 11). The process was thermally reversible over several cycles with an increase in the change in magnetization (ΔM) with increasing temperature due to PISCES generation closer to the magnetic transition temperature (T_{1/2}=325 K) (FIGS. 10 and 11). Thermal relaxation, in the absence of light, resulted in magnetization relaxation (FIG. 11) with monoexponential kinetics and a rate constant of k_{obs}=0.1 s⁻¹ at 300 K (FIGS. 28 and 29), driven by thermal relaxation from the RC to the RO form. Similar rate constants were determined for thermal relaxation of the ligand- and metal-centered optical transitions, supporting a PISCES mechanism rather than direct metal-centered excited-state formation, which has a shorter lifetime by six orders of magnitude.

In this example, a slight increase in the thermal relaxation time (and consequently conversion efficiency) was observed with increasing temperature consistent with a thermally activated process. The conversion efficiency was dependent on irradiation power, with a decrease in power by a factor of two leading to a decrease in the photoinduced magnetization by the same factor (FIG. 30). The linear power dependence of the photomagnetic effect in this example was consistent with a photoinitiated event rather than a process governed by photothermal effects. Metastable photoinduced magnetic states have been generated in the parent cobalt-dioxolene complex by formation of a metal-centered excited state with thermal relaxation at cryogenic temperatures. Irradiation of Co(diox)₂(phen) at the metal-ligand charge transfer energy at 10 K leads to a photoinduced CTIST process and population of the hs-Co(II) state, with an extrapolated lifetime of 200 ns at 300 K. Direct measurement of thermal relaxation at room temperature suggests a lifetime on the order of ns in solution. In this example, the photoinduced magnetic state generated by PISCES resulted in a lifetime of 10 s at 300 K, an increase in lifetime of 10⁶ over that of known cobalt-dioxolene complexes. The observed increase in lifetime was a direct result of coupling a photoisomerizable ligand, capable of solid-state ligand isomerization, to an electronically bistable cobalt-dioxolene metal complex capable of charge-transfer-coupled spin-transition processes.

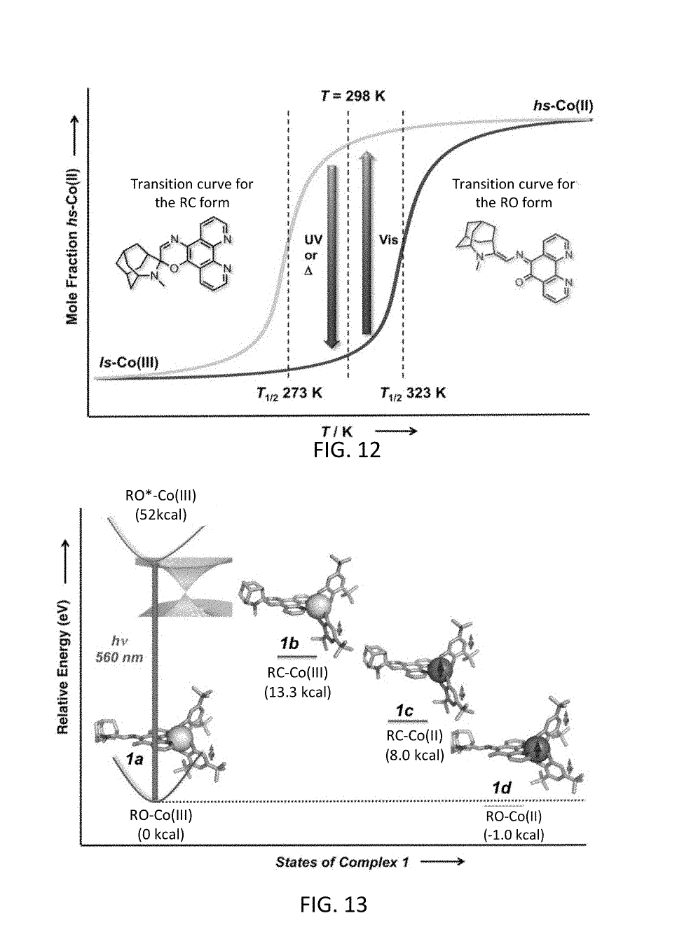

In some embodiments, the shift in ligand field upon photoisomerization should be significant enough to shift the driving force for charge transfer. The major π-backbonding pathway in metal complexes of phenanthroline-spirooxazines can involve overlap of the metal-based orbitals with the next highest lowest unoccupied orbital (LUMO) LUMO+1—and not the LUMO—as providing the dominant orbital interaction with a coordinated metal fragment. Using Koopman's theorem, the “effective reduction potential,” E_{(red,eff)}, can be calculated from the experimental reduction potentials compensated by the ΔE between LUMO+1 and LUMO extracted from theoretical modeling by density functional methods (DFT). The E(_{red,eff}) can then be used to extrapolate T_{1/2} values for the spirooxazine cobalt-dioxolene complexes from the linear fit of experimental reduction potentials for various diimine ligands (in CH₃CN) vs. T_{1/2} values (in toluene) previously established. Transition temperatures for the RC and RO forms of the Co(diox)₂(APSO) complex in this example are thus predicted to be 273 and 323 K, respectively (FIG. 12). The experimental T_{1/2} value for the polycrystalline sample of 1 of 325 K is virtually that predicted for the RO form. Therefore, at room temperature, the Co(diox)₂(APSO) complex can exist in either the ls-Co(III) or hs-Co(II) state as a function of whether the spirooxazine ligand is in the RC or RO form. Upon visible irradiation of 1, predominantly in the RO-ls-Co(III) form (100) at ˜300 K in the thin-film state, it is therefore predicted that ring closure to the RC form should take place (100→102) and induce a transition to the hs-Co(II) form (102→104) (FIG. 12). This result was confirmed using both optical absorption spectroscopy and photomagnetization studies disclosed herein.

In some embodiments, the PISCES mechanism can involve the relative ground state energies of the four states being such that conversion to the RC-hs-Co(II) form followed by relaxation to the RO-ls-Co(III) form occurs based on thermodynamic considerations. Unrestricted DFT computations (UB3LYP/6-311G(d,p)) were performed to assess the relative ground-state energies of states 100-106 (FIG. 13). Excitation into the RO-doublet/RO-sextet manifold led to the RO excited state (100*) which was ˜52 kcal (λ_{exc} 550 nm) above the ground state. Isomerization to the RC form occurred to the RC-ls-Co(III) state, which was ˜5 kcal higher in energy than the RC-hs-Co(II) state. Thermal relaxation to the RO manifold was then possible, in which the RO-ls-Co(III) (100) and RO-hs-Co(II) (106) states were practically degenerate (ΔE≈1 kcal). The relative ground-state energies predicted by unrestricted computation therefore support the observed behavior of complex 1, and provide insight into the driving force of PISCES. The thermodynamics and pathway of PISCES can therefore be predicted by analysis of the relative energies of the photoisomer forms, as well as relative stability of states as predicted by DFT.

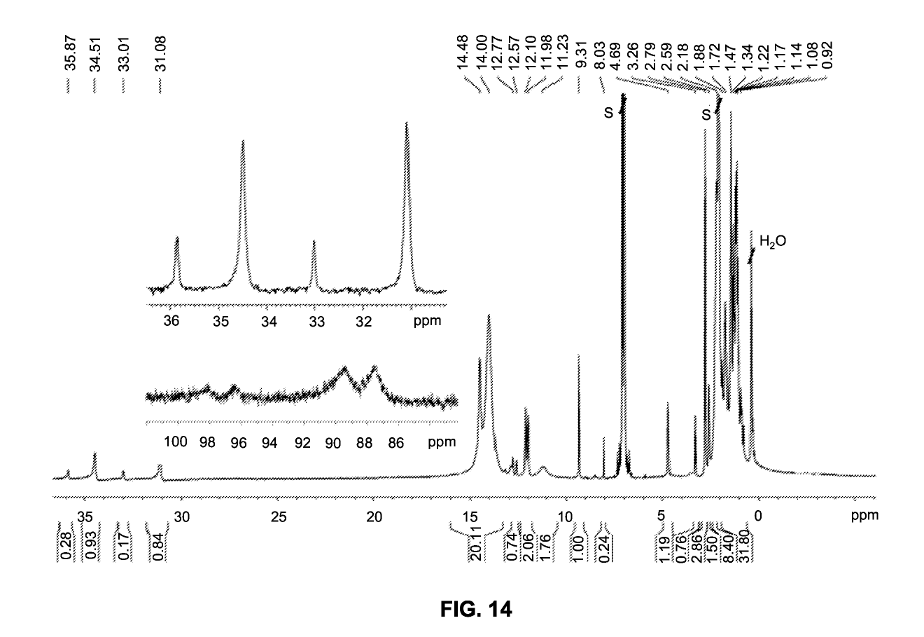

In some embodiments, structural analysis carried out at 90 K by XRD indicates a molecular structure consistent with the RO-ls-Co(III) state (100) (FIG. 2). The photoisomerizable APSO ligand crystallizes in the open RO form, with a trans-trans-cis geometry about the azomethine backbone, as in the parent ligand. The average Co—O and Co—N bond distances of 1.879 Å and 1.950 Å, respectively, lead to a bond valence sum analysis of 3.2 (theoretical value 3.0) consistent with the ls-Co(III) state. Subtle differences in the C—O bond lengths of the four dioxolene moieties were observed (FIG. 14) (C(39)-O(4) 1.322(11) Å, C(40)-O(5) 1.332(11) Å, C(26)-O(3) 1.331(10) Å, C(25)-O(2) 1.308(10) Å) suggesting delocalization between the catecholate (C—O 1.35 Å) and semiquinonate (C—O 1.29 Å) forms.

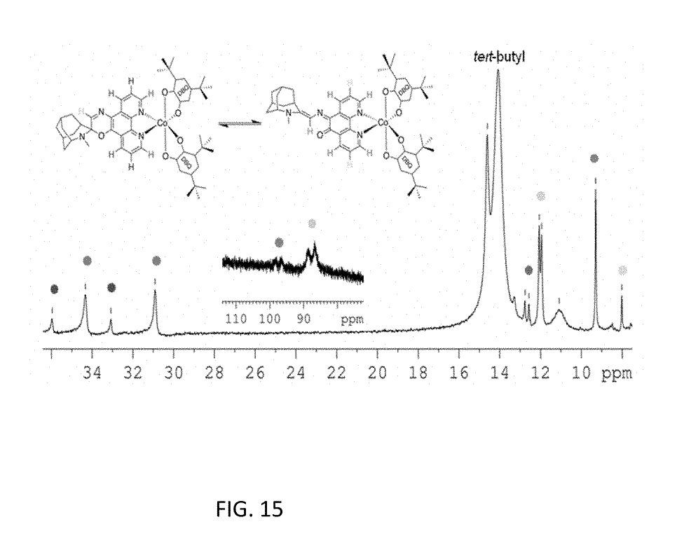

In solution at 300 K, ¹H NMR spectroscopy in toluene-d⁸ revealed a mixture of states 100-106 with the RO-hs-Co(II) form (106) as the dominant one (FIGS. 14 and 15). On the basis of a 4:1 ratio of RO (Co(II)+Co(III)) to RC (Co(II)+Co(III)) signals, the RO/SO thermal equilibrium constant, K_{T}=[RO]/[SO], was determined to be 4.0 (80% RO), corresponding to a free energy difference between RO (100/106) and RC (102/104) forms of ΔG^{o}=3.5 kcal/mol, with the RO form lower in energy. Distinct resonances for the ls-Co(III) and hs-Co(II) forms were not observed due to rapid interconversion relative to the NMR timescale (k≈10⁻⁸ s⁻¹ in the parent phenanthroline complex). Broadened and downfield-shifted phenanthroline-based resonances were associated with some degree of complexation to a paramagnetic hs-Co(II) metal center, and these exhibit narrowing and upfield shifts with decreasing temperature, consistent with equilibration toward the thermodynamically stable ls-Co(III) form.

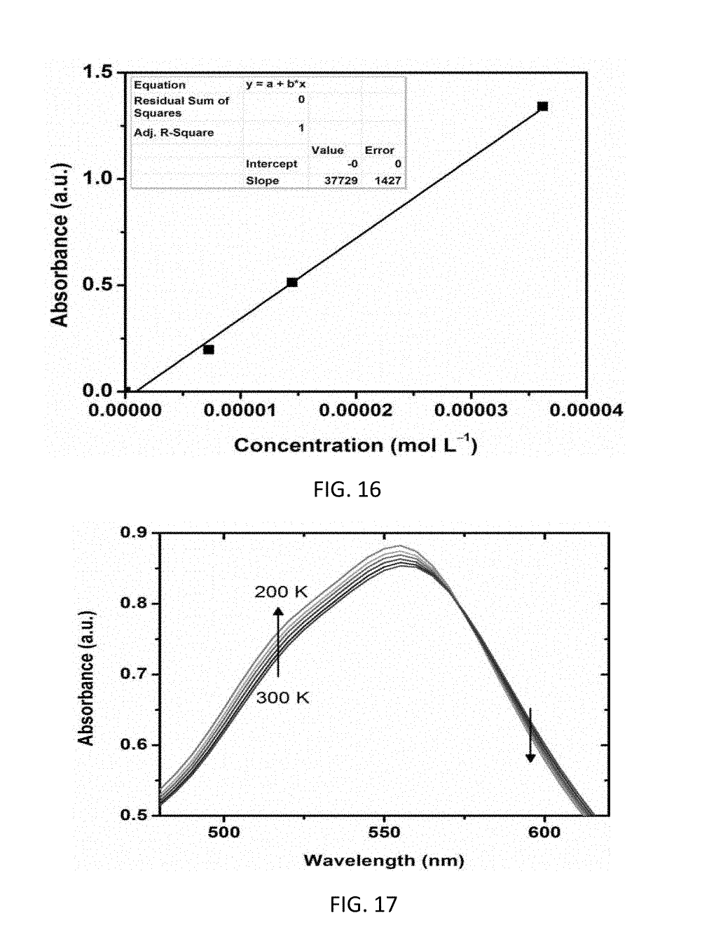

Electronically bistable cobalt complexes exhibit temperature-dependent behavior, with conversion to the ls-Co(III) ground state at low temperatures, as was observed in this example. Temperature-dependent optical absorption spectroscopy supports the RO-hs-Co(II) form as the dominant form in solution at 300 K with conversion to the ls-Co(III) form at lower temperatures. With decreasing temperature (300 to 200 K), the RO π-π* transition at λₘₐₓ=555 nm (ε˜47,500 M⁻¹, FIG. 16), increased in intensity (FIG. 17), consistent with the greater thermodynamic stability of the RO form. A broad absorption band at 824 nm, partially overlapping with the intense RO π-π* band and assigned to a hs-Co(II) metal-to-ligand-charge transfer (MLCT) transition (e_{g}-like orbitals on Co(II) to the SQ^{⋅-} and phenanthroline π* orbitals) decreased reversibly at lower temperatures (298 to 196 K), consistent with hs-Co(II) to ls-Co(III) conversion (FIG. 18). Lastly, a broad charge transfer band in the near infrared (NIR) region at ˜2500 nm, assigned to a Co(III)-based transition originating from either a catecholate (π*)—Co(III)(e_{g}*) ligand-to-metal charge-transfer (LMCT) excitation or a catecholate (π*)-semiquinonate (π) intervalence (IV) CT process intensified with decreasing temperature (350 to 90 K) due to hs-Co(II) to ls-Co(III) conversion (FIG. 3).

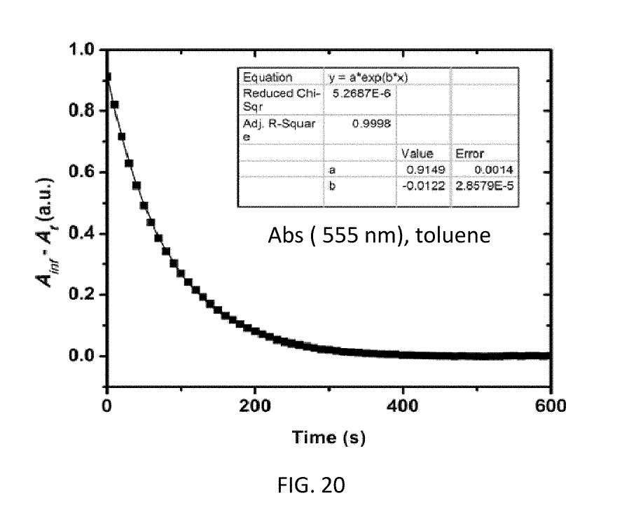

The conversion of the ls-Co(III) state to the hs-Co(II) state gave rise to an increase in magnetization with an abrupt transition above room temperature (FIG. 4). Variable-temperature magnetic susceptibility measurements were carried out at 10,000 Oe on a polycrystalline sample of 1. The magnetic moment (χT) at 350 K (2.49 emu·K·mol⁻¹) was in agreement with that expected for a spin-only magnetically isolated hs-Co(II) center (S=3/2, g≈1.93) with two semiquinonate ligands (S=½, g≈2.0). Slight lowering of the magnetic moment relative to the spin-only value occurred due to contributions from spin-orbit coupling and intramolecular exchange interactions. Decreasing the temperature induced an abrupt decrease in the magnetic moment at 200 K to 0.40 emu·K·mol⁻¹ due to cooperative conversion to the ls-Co(III)(semiquinonate)(catecholate) complex (S=½, g≈2.0), with a transition temperature of T_{1/2}=325 K. A small hysteresis of 3 K was observed at 325 K due to weak cooperative interactions in the solid state (FIG. 19). Below 20 K, the moment (χT) decreased further due to weak intermolecular antiferromagnetic exchange interactions. Field-dependent magnetization measurements at 4 K were consistent with a doublet S=½ ls-Co(III) ground state (FIG. 20). Solution-state variable temperature magnetic susceptibility measurements by Evan's method in toluene-d₈ revealed a non-cooperative hs-Co(II)→ls-Co(III) transition with decreasing temperature, evidenced by the gradual decrease in the magnetic moment (χT) with temperature, with a transition temperature (T_{1/2}) of 255 K, consistent with single-molecule hs-Co(II)→ls-Co(III) conversion via a Boltzmann population of states (FIG. 4).

TABLE 3
Crystallographic data and refinement parameters for complex 1.

| Empirical formula | C₅₂H₆₄N₄O₅Co |
|---|---|
| Formula weight/g · mol⁻¹ | 884.00 |
| Temperature/K | 90 |
| Crystal color, habit | green, tablet |
| Crystal dimensions/mm | 0.02 × 0.05 × 0.05 |
| Crystal system | triclinic |
| Space group | P-1 (no. 2) |
| Unit cell parameters | |
| a/Å | 10.5827(7) |
| b/Å | 13.954(1) |
| c/Å | 17.870(1) |
| α/° | 104.664(5) |
| β/° | 105.533(5) |
| γ/° | 104.296(6) |
| V/Å³ | 2315.2(3) |
| Z | 2 |
| D_{calcd}/g · cm⁻³ | 1.268 |
| F₀₀₀ | 942 |
| Max. and min. transmission | 0.936 and 0.769 |
| Reflections collected | 12902 |
| Independent reflections | 3610 (Rᵢₙₜ = 0.150) |
| Residuals (refined on F², all data): R₁; wR₂ | 0.173; 0.172 |
| GOF on F² | 1.03 |
| No. observations (I > 2σ(I)) | 1796 |
| Residuals (refined on F): R₁; wR₂ | 0.076; 0.142 |

TABLE 4
Bond lengths.

| Atom | Atom | Length/Å |
|---|---|---|
| C1 | C2 | 1.369(12) |
| C1 | N1 | 1.326(12) |
| C2 | C3 | 1.378(13) |
| C3 | C4 | 1.406(13) |
| C4 | C5 | 1.463(14) |
| C4 | C12 | 1.386(13) |
| C5 | C6 | 1.461(14) |
| C5 | O1 | 1.255(11) |
| C6 | C7 | 1.460(13) |
| C6 | N3 | 1.331(12) |
| C7 | C8 | 1.414(13) |
| C7 | C11 | 1.382(13) |
| C8 | C9 | 1.356(12) |
| C9 | C10 | 1.394(13) |
| C10 | N2 | 1.321(12) |
| C11 | C12 | 1.436(13) |
| C11 | N2 | 1.367(11) |
| C12 | N1 | 1.348(12) |
| C13 | C14 | 1.435(13) |
| C13 | N3 | 1.322(11) |
| C14 | C15 | 1.512(14) |
| C14 | N4 | 1.323(11) |
| C15 | C16 | 1.526(13) |
| C15 | C20 | 1.525(13) |
| C16 | C17 | 1.553(12) |
| C17 | C18 | 1.519(13) |
| C17 | C22 | 1.521(13) |
| C18 | C19 | 1.514(13) |
| C19 | C23 | 1.521(13) |
| C19 | N4 | 1.504(12) |
| C20 | C21 | 1.537(13) |
| C21 | C22 | 1.510(14) |
| C21 | C23 | 1.520(13) |
| C24 | N4 | 1.483(11) |
| C25 | C26 | 1.415(13) |
| C25 | C30 | 1.397(12) |
| C25 | O2 | 1.308(10) |
| C26 | C27 | 1.404(12) |
| C26 | O3 | 1.331(10) |
| C27 | C28 | 1.390(12) |
| C27 | C31 | 1.544(14) |
| C28 | C29 | 1.422(13) |
| C29 | C30 | 1.360(12) |
| C29 | C35 | 1.536(13) |
| C31 | C32 | 1.540(14) |
| C31 | C33 | 1.551(14) |
| C31 | C34 | 1.522(12) |
| C35 | C36 | 1.541(14) |
| C35 | C37 | 1.527(13) |
| C35 | C38 | 1.520(13) |
| C39 | C40 | 1.437(13) |
| C39 | C44 | 1.404(13) |
| C39 | O4 | 1.322(11) |
| C40 | C41 | 1.400(13) |
| C40 | O5 | 1.332(11) |
| C41 | C42 | 1.390(13) |
| C41 | C45 | 1.536(13) |
| C42 | C43 | 1.420(13) |
| C43 | C44 | 1.364(12) |
| C43 | C49 | 1.514(14) |
| C45 | C46 | 1.552(12) |
| C45 | C47 | 1.546(12) |
| C45 | C48 | 1.516(13) |
| C49 | C50 | 1.541(13) |
| C49 | C51 | 1.520(14) |
| C49 | C52 | 1.563(13) |
| N1 | Co1 | 1.955(8) |
| N2 | Co1 | 1.945(9) |
| O2 | Co1 | 1.895(6) |
| O3 | Co1 | 1.878(6) |
| O4 | Co1 | 1.869(6) |
| O5 | Co1 | 1.876(7) |

TABLE 5
Bond angles.

| Atom | Atom | Atom | Angle/° |
|---|---|---|---|
| N1 | C1 | C2 | 121.3(11) |
| C1 | C2 | C3 | 120.4(11) |
| C2 | C3 | C4 | 119.3(11) |
| C3 | C4 | C5 | 121.9(11) |
| C12 | C4 | C3 | 116.2(11) |
| C12 | C4 | C5 | 121.8(11) |
| C6 | C5 | C4 | 117.3(11) |
| O1 | C5 | C4 | 120.2(11) |
| O1 | C5 | C6 | 122.5(11) |
| C7 | C6 | C5 | 118.7(11) |
| N3 | C6 | C5 | 126.6(11) |
| N3 | C6 | C7 | 114.7(11) |
| C8 | C7 | C6 | 123.9(11) |
| C11 | C7 | C6 | 120.3(11) |
| C11 | C7 | C8 | 115.7(11) |
| C9 | C8 | C7 | 120.2(11) |
| C8 | C9 | C10 | 119.6(11) |
| N2 | C10 | C9 | 122.4(11) |
| C7 | C11 | C12 | 121.4(11) |
| N2 | C11 | C7 | 124.4(11) |
| N2 | C11 | C12 | 114.0(11) |
| C4 | C12 | C11 | 119.6(12) |
| N1 | C12 | C4 | 123.6(11) |
| N1 | C12 | C11 | 116.8(11) |
| N3 | C13 | C14 | 117.5(11) |
| C13 | C14 | C15 | 119.8(10) |
| N4 | C14 | C13 | 118.9(11) |
| N4 | C14 | C15 | 121.2(10) |
| C14 | C15 | C16 | 113.9(10) |
| C14 | C15 | C20 | 111.7(10) |
| C20 | C15 | C16 | 111.8(9) |
| C15 | C16 | C17 | 114.8(9) |
| C18 | C17 | C16 | 111.0(9) |
| C18 | C17 | C22 | 110.2(9) |
| C22 | C17 | C16 | 107.7(9) |
| C19 | C18 | C17 | 113.7(10) |
| C18 | C19 | C23 | 112.8(10) |
| N4 | C19 | C18 | 111.8(9) |
| N4 | C19 | C23 | 112.5(9) |
| C15 | C20 | C21 | 112.6(10) |
| C22 | C21 | C20 | 108.8(9) |
| C22 | C21 | C23 | 110.3(10) |
| C23 | C21 | C20 | 112.7(10) |
| C21 | C22 | C17 | 110.4(10) |
| C21 | C23 | C19 | 114.0(10) |
| C30 | C25 | C26 | 118.6(10) |
| O2 | C25 | C26 | 118.6(10) |
| O2 | C25 | C30 | 122.8(10) |
| C27 | C26 | C25 | 121.9(11) |
| O3 | C26 | C25 | 114.8(9) |
| O3 | C26 | C27 | 123.2(10) |
| C26 | C27 | C31 | 121.4(10) |
| C28 | C27 | C26 | 116.2(10) |
| C28 | C27 | C31 | 122.4(10) |
| C27 | C28 | C29 | 123.4(10) |
| C28 | C29 | C35 | 120.0(9) |
| C30 | C29 | C28 | 118.0(10) |
| C30 | C29 | C35 | 122.0(10) |
| C29 | C30 | C25 | 121.9(10) |
| C27 | C31 | C33 | 108.6(10) |
| C32 | C31 | C27 | 110.0(10) |
| C32 | C31 | C33 | 110.1(9) |
| C34 | C31 | C27 | 112.1(9) |
| C34 | C31 | C32 | 108.1(10) |
| C34 | C31 | C33 | 107.9(9) |
| C29 | C35 | C36 | 107.3(10) |
| C37 | C35 | C29 | 110.7(10) |
| C37 | C35 | C36 | 108.3(9) |
| C38 | C35 | C29 | 112.9(9) |
| C38 | C35 | C36 | 108.1(10) |
| C38 | C35 | C37 | 109.4(10) |
| C44 | C39 | C40 | 118.9(11) |
| O4 | C39 | C40 | 115.7(10) |
| O4 | C39 | C44 | 125.3(10) |
| C41 | C40 | C39 | 120.8(11) |
| O5 | C40 | C39 | 116.1(11) |
| O5 | C40 | C41 | 123.1(10) |
| C40 | C41 | C45 | 122.2(10) |
| C42 | C41 | C40 | 116.6(11) |
| C42 | C41 | C45 | 121.3(11) |
| C41 | C42 | C43 | 124.5(11) |
| C42 | C43 | C49 | 120.1(11) |
| C44 | C43 | C42 | 117.2(10) |
| C44 | C43 | C49 | 122.7(11) |
| C43 | C44 | C39 | 122.0(11) |
| C41 | C45 | C46 | 108.3(8) |
| C41 | C45 | C47 | 108.9(10) |
| C47 | C45 | C46 | 110.6(9) |
| C48 | C45 | C41 | 113.2(9) |
| C48 | C45 | C46 | 107.2(10) |
| C48 | C45 | C47 | 108.6(8) |
| C43 | C49 | C50 | 108.6(9) |
| C43 | C49 | C51 | 111.2(10) |
| C43 | C49 | C52 | 112.1(10) |
| C50 | C49 | C52 | 107.9(9) |
| C51 | C49 | C50 | 109.3(10) |
| C51 | C49 | C52 | 107.6(9) |
| C1 | N1 | C12 | 119.1(10) |
| C1 | N1 | Co1 | 128.6(8) |
| C12 | N1 | Co1 | 112.2(8) |
| C10 | N2 | C11 | 117.4(10) |
| C10 | N2 | Co1 | 129.3(8) |
| C11 | N2 | Co1 | 113.3(8) |
| C13 | N3 | C6 | 123.3(10) |
| C14 | N4 | C19 | 123.5(9) |
| C14 | N4 | C24 | 121.7(9) |
| C24 | N4 | C19 | 114.6(8) |
| C25 | O2 | Co1 | 107.0(7) |
| C26 | O3 | Co1 | 108.4(6) |
| C39 | O4 | Co1 | 107.9(6) |
| C40 | O5 | Co1 | 107.5(7) |
| N2 | Co1 | N1 | 83.6(4) |
| O2 | Co1 | N1 | 92.1(3) |
| O2 | Co1 | N2 | 91.4(3) |
| O3 | Co1 | N1 | 177.2(4) |
| O3 | Co1 | N2 | 93.7(4) |
| O3 | Co1 | O2 | 87.1(3) |
| O4 | Co1 | N1 | 91.2(3) |
| O4 | Co1 | N2 | 92.0(3) |
| O4 | Co1 | O2 | 175.5(3) |
| O4 | Co1 | O3 | 89.8(3) |
| O4 | Co1 | O5 | 87.9(3) |
| O5 | Co1 | N1 | 92.9(4) |
| O5 | Co1 | N2 | 176.5(4) |
| O5 | Co1 | O2 | 88.8(3) |
| O5 | Co1 | O3 | 89.8(3) |

### Theoretical Model

The sensitivity of the ls-Co(III)/hs-Co(II) equilibrium in Co(3,5-DTBQ)₂(NN) complexes to the ligand field of the ancillary diimine ligand (NN) has been investigated both experimentally and theoretically. In 1993, Adams et al. correlated the transition temperature, T_{1/2}, of a series of four Co(3,5-DTBQ)₂(NN) complexes with the reduction potential of their respective diimine ligands and found a remarkably linear correlation. Others in the field have conducted a computational analysis of Co(3,5-DTBQ)₂(phen), and concluded that a strong π-acceptor ligand stabilizes the hs-Co(II) form. Their results may be summarized as follows. Ligand field effects in Co(3,5-DTBQ)₂(phen) can result from both σ-donation and π-backbonding effects. From ligand field theory, a σ-donor ligand will interact with σ-bonding e_{g} metal orbitals (d_{z2}, d_{x2-y2}), while a π-acceptor ligand will interact with π-bonding t_{2g} metal orbitals (d_{xy}, d_{xz}, d_{yz}) (FIG. 34). In each case, the metal-based bonding orbitals are stabilized, and the octahedral ligand field splitting parameter, ΔOₕ, increases. In the Co(3,5-DTBQ)₂(phen) complex, σ-donation preferentially stabilizes the ls-Co(III) form. In the ls-Co(III) form, the increased energy of the antibonding e_{g}* orbitals resulting from σ-donation places them further above the π* orbitals of the SQ^{-⋅} and Cat²⁻ ligands, which makes intramolecular charge transfer (and therefore ls-Co(III) hs-Co(II) conversion) more energetically costly. Further, increasing the energy of the e_{g}* orbitals via σ-donation destabilizes the hs-Co(II) form which, unlike the ls-Co(III) form, has electron density in these orbitals. Conversely, greater π-backbonding preferentially stabilizes the hs-Co(II) form. Qualitatively, this can be understood from the fact that a strong π-acceptor ligand, able to accept electron density from a coordinated metal, will preferentially stabilize the more electron-rich hs-Co(II) form. More rigorously, in the hs-Co(II) form, spin polarization raises the energy of the minority-spin t_{2g} orbitals such that they become closer in energy to the phen(π*) orbitals and participate more significantly in a stabilizing π-backbonding interaction; this does not occur in the case of the ls-Co(III) form.

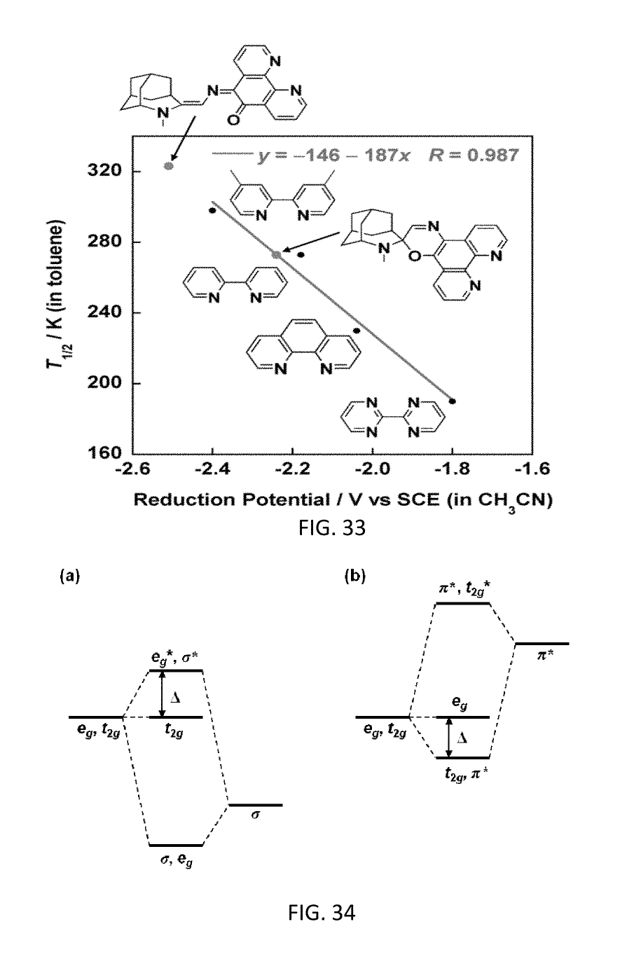

On the basis of the results shown in FIG. 33, it stands to reason that the T_{1/2} values for the RC and RO forms of the spiro[phenanthrolinoxazine] ligand may be predicted from their respective reduction potentials. Although both σ-donation and π-backbonding interactions can affect the relative stabilities of the ls-Co(III) and hs-Co(II) forms, the linear correlation between T_{1/2} and diimine ligand reduction potential suggests that the π-backbonding interaction plays a determining role in the overall stabilization effect. A fragment molecular orbital analysis of the metal-ligand bonding in molybdenum-tetracarbonyl-spiro[phenanthrolinoxazine] complexes revealed, however, that it is not, in fact, the LUMO of the phen-based ligand that interacts predominantly with the coordinated metal fragment to give the major t-backbonding pathway, but rather the LUMO+1. The experimental reduction potentials may therefore not be used directly in the prediction of T_{1/2} values. To circumvent this issue, “effective reduction potentials” were obtained by correcting LUMO-based experimental reduction potentials for the ΔE between LUMO and LUMO+1 extracted from DFT calculations. These effective reduction potentials were then fit to the linear correlation empirically established by Adams et al. (FIG. 33) to extract T_{1/2} values for the RC and RO forms of APSO (Table 6). Because the LUMO+1 is ˜0.3 eV lower in energy for the RC form than for the RO form, the RC form should behave as a stronger π-acceptor, consequently stabilizing the hs-Co(II) form and decreasing T_{1/2}. It should be noted that, in the study by Adams et al., the “true” reduction potential (based on LUMO energies) was used for the four diimine ligands. For the 2,2′-bipyridine-based ligands and the 2,2′-bipyrimidine ligands, the LUMO is in fact predicted to be the major π-bonding orbital, and for phenanthroline, the LUMO and LUMO+1 are effectively degenerate, and therefore either the “true” or “effective” reduction potential may be applied with the same results (this is not true for derivatized phenanthroline ligands, such as the spiro[phenanthrolinoxazines]).

TABLE 6
Estimation of the transition temperature, T_{1/2}, for ls-Co(III)
→ hs-Co(II) conversion of Co(3,5-DTBQ)₂(NN) complexes containing
the RC and RO forms of APSO using the “effective reduction
potential’ based on the orbital energy of the LUMO + 1.

| | Reduction Potential | Effective Red. Potential | Estimated |
|---|---|---|---|
| Ligand | (LUMO)/V^{a} | (LUMO + 1)/V | T_{1/2}/K |
| APSO-RC | | −2.24 | 273 |
| APSO-RO | −1.26 | −2.51 | 323 |

### Example 3

In this example, two cobalt clusters containing photochromic ligands are described. Xtal structure, VT UV/Vis spectroscopy and magnetization measurements suggest the RO-hs-Co(II) state is the dominant state at room temperature for the CoAPSO cluster (FIG. 35), while it is the RC-hs-Co(II) for CoIPSO cluster (FIG. 36). The clusters were prepared from Co₄CO₈, catecholate ligand, and spirooxazine in methanol at room temperature and the clusters crystallize out.

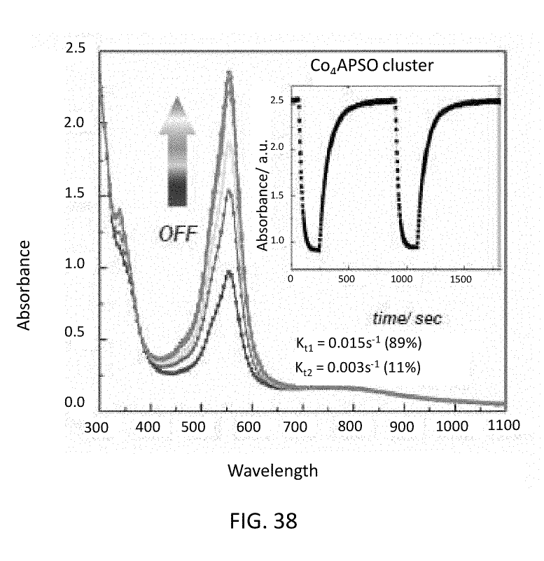

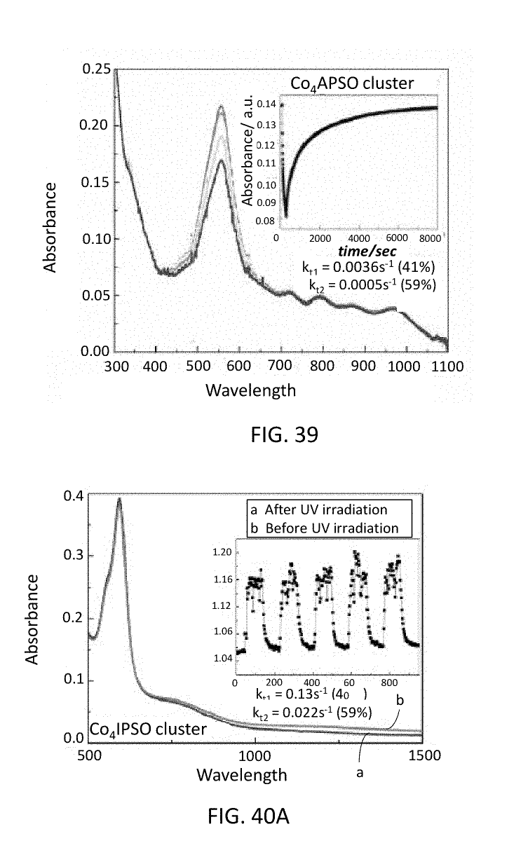

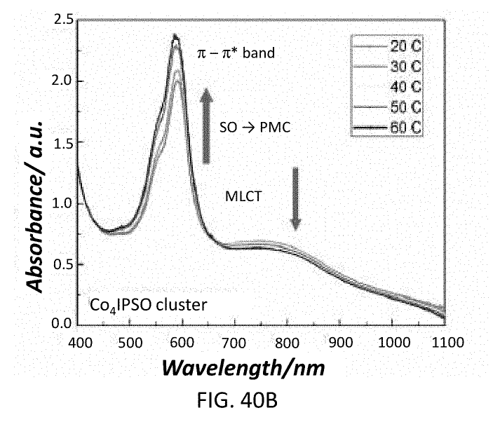

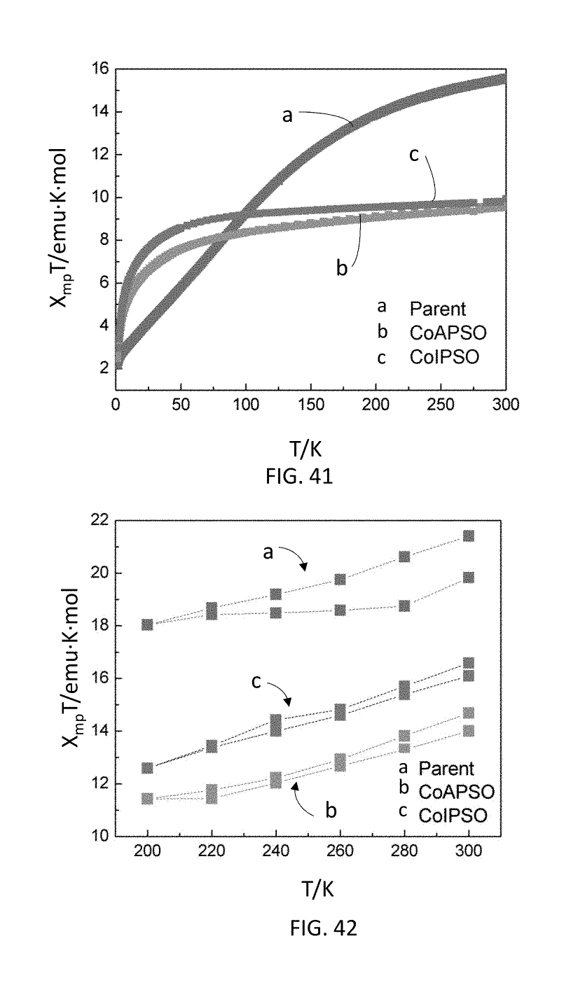

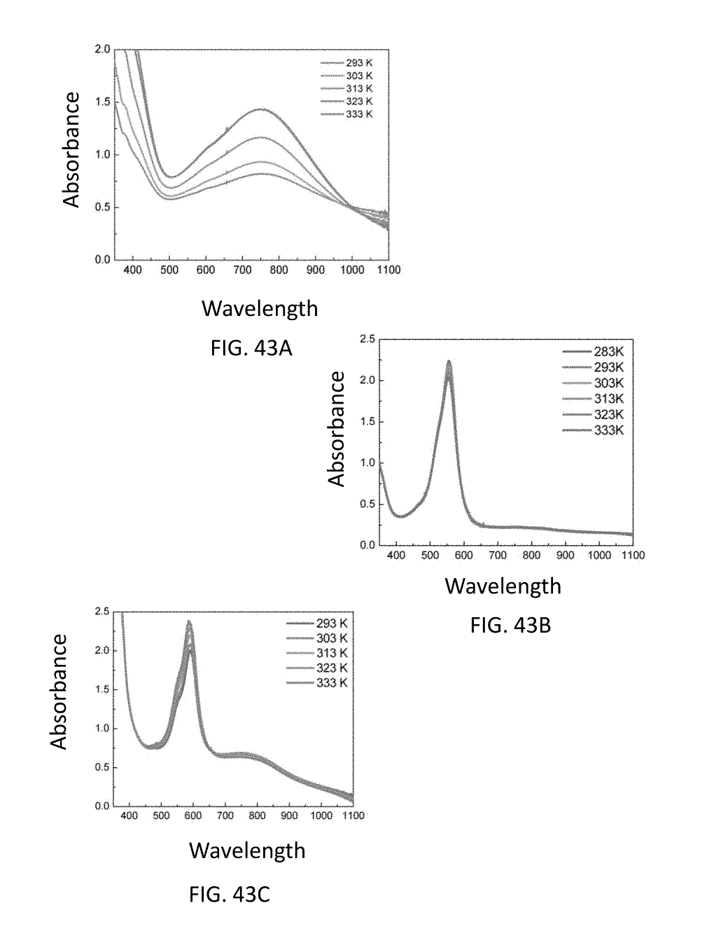

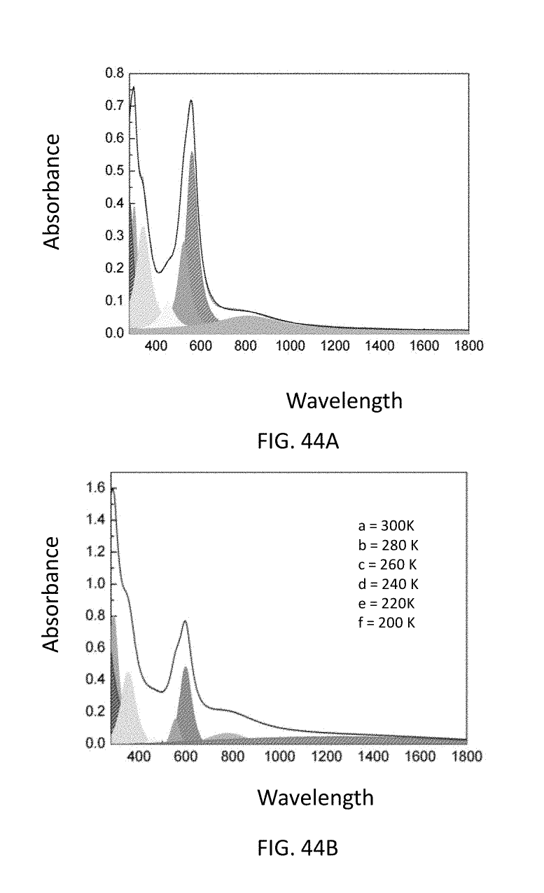

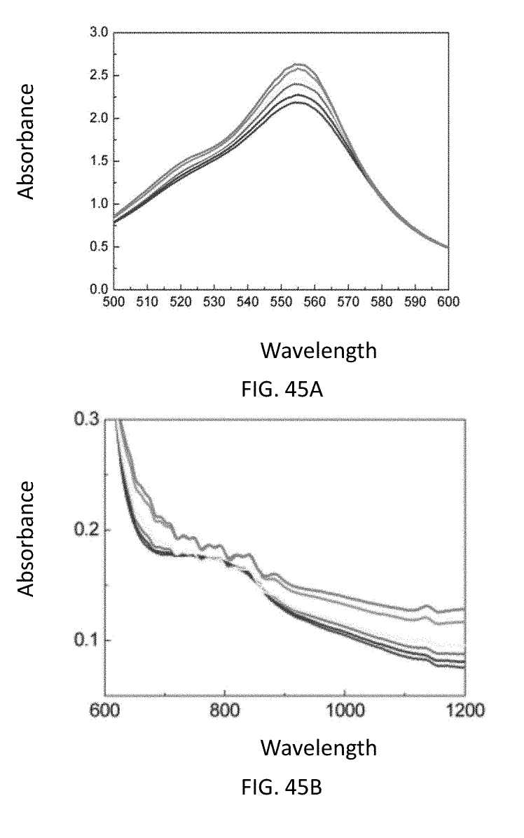

Irradiation of the Co(DBSQ)₆(APSO)₂ complex with excitation at 560 nm leads to ring closure to the closed RC form, as evidenced by a decrease in the pi-pi* band of the RO form at λₘₐₓ 555 nm. A very small change however was observed at λₘₐₓ 800 nm, the MLCT band for the cluster, suggesting that photoisomerization of the RO→RC form does not lead to significant changes in population of the hs-Co(II)-RO. This can be excitation at 560 nm leads to ring closure to the closed RC form, as evidenced by a decrease in the pi-pi* band of the RO form at λₘₐₓ 555 nm. A very small change however was observed at λₘₐₓ 800 nm, the MLCT band for the cluster, suggesting that photoisomerization of the RO→RC form does not lead to significant changes in population of the hs-Co(II)-RO. The spirooxazines generally undergo photo conversion between the RC and RO forms in the ps timescale while the lifetime of the photoinduced magnetic state is 10 s at 300 K. The magnetization of the clusters is larger than in the monomeric complex (10 emu vs 2 emu) due to the presence of more paramagnetic units in the cluster. The ability of these large clusters to exhibit optical gating was established, as indicated by FIGS. 38, 39, and 40A. The photochromic properties of an APSO-containing clustered complex in solid state (e.g., a thin film) also were examined. The photochromic properties of an IPSO-containing clustered complex in solution state (e.g., in DCE) also were examined and the corresponding absorption spectra obtained at temperatures ranging from 293 K to 333 K are provided by FIG. 40B. FIGS. 41 and 42 exhibit comparisons of the magnetic properties in both the solid state (FIG. 41) and the solution state (FIG. 42) of the clustered complexes of a “parent” clustered complex (that is, a complex without a photoisomerizable ligand), an APSO-containing clustered complex, and an IPSO-containing clustered complex. For the APSO-containing clustered complex, a high XT in solution relative to the solid state may indicate that there are dipolar interactions between the different clusters and in some embodiments, a small hysteresis in solution, which may suggest some cooperativity with the cluster in some embodiments. FIGS. 43A-43C illustrate the CTIST behavior of the parent clustered complex (FIG. 43A), an APSO-containing clustered complex (FIG. 43B), and an IPSO-containing clustered complex (FIG. 43C). These figures include the electronic absorption spectra obtained for the clusters at varying temperatures (293 K to 333 K) and indicate that the ground state of the APSO-containing clustered complex likely is RO-hs-Co(II) and the ground state of the IPSO-containing clustered complex likely is RC-hs-Co(II). In some embodiments, the stabilization of the RC form along with population of RC-hs-Co(II) can indicate that there is strong coupling between the IPSO and Co centers. Additional results for CTIST in a representative APSO-containing clustered complex and a representative ISPO-containing clustered complex are illustrated in FIGS. 44A and 44B, respectively. FIGS. 45A and 45B illustrate the temperature dependence of the electronic state of a representative APSO-containing cluster in solution at temperatures ranging from 200 K to 300 K, where it is seen that the p-p* band at 550 nm decreases in intensity as temperature increases (FIG. 45A), but the MLCT band at 800 nm does not (FIG. 45B). With reference to FIG. 45B, the scatter in the data illustrated is due to low signal-to-noise from low intensity transitions in a temperature range in which the solvent is starting to freeze. Nevertheless, this establishes that the MLCT band shifts as the pi-pi* band shifts, providing evidence for photochrome state control of the redox/spin state of the metal center. FIG. 27 illustrates the temperature dependence of the magnetic moment of a thin-film sample of an APSO complex between 305 and 330 K determined in 0.1 K steps.

### Example 4

In this example, a magnetic tunnel junction comprising a complex disclosed herein and method of making the same is described. Specifically, a magnetic tunnel junction comprised of the photomagnetic material as the storage/write layer is fabricated with room-temperature growth of the junction electrode layers. The device can provide the ability to achieve two stable resistive states at zero field, control of the magnetic anisotropy, and high tunneling magnetoresistance (TMR). The tunneling magnetoresistance of the device is defined as the ratio of DR, the maximum difference in resistance observed over the field range, and Rₘᵢₙ, the minimum resistance which corresponds to the electrodes of parallel magnetization. The fabricated magnetic/tunneling/magnetic layer tunnel junction is constructed in which the relative magnetization polarizations of the two layers (parallel vs antiparallel) determines the resistivity through the junction. In this example, the ferromagnetic layer is a CoFeB blend. The tunnel junction layers are fabricated using a shadow mask technique via DC magnetron and ion beam sputtering onto thermally oxidized silicon substrates. An MgO tunnel barrier is used between CoFeB and CoFe FM electrodes, where the CoFe electrode is deposited onto a thin CoFeB layer, and an IrMn layer which serves as an antiferromagnet pinning layer for the fixed layer (AFM). This type of MTJ can yield superior TMR performance at RT (e.g, 50% to 600%), with an extended B-interval of antiparallel electrode magnetization directions. Planar or areal resistance (AR) and TMR values can be measured with the device. The device can provide a demonstrable change in resistivity as a function of write state. Changes in bulk magnetic anisotropy of the free layer also can be observed upon light irradiation. To maximize this effect, an ordered material in which the easy axes are ordered relative to the planar surface can be used. This can be achieved through deposition in the presence of a magnetic field, as at room temperature the system exists partially in the high-spin Co(II) state, which has a large easy axis of magnetization due to spin-orbit coupling. Upon light irradiation, increased population of the hs-Co(II) state then leads to an increase in resistivity “0” due to an increase in magnetic scattering centers.

### Example 5

In this example, the magnetic properties of an organic thin film formed by solution deposition of the CoAPSO complex (i.e., Co(DTBQ)₂(APSO)) onto a graphene/SiO₂ substrate were measured by magneto-optical Kerr effects (MOKE). The probe wavelength for polarized light was 800 nm, the external magnetic field was swept from +3000 Oe to −3000 Oe and back to +3000 Oe. In the absence of irradiation, the elliptical rotation of polarized light was measured as a function of voltage with external magnetic field sweeps, and was found not to change as a function of time (FIG. 49A) with a low MOKE signal (MOKE˜2.0 V). Application of green light (λ_{exc} 550 nm) leads to an increase in the magneto-optical signal by a factor of 2.5 (MOKE˜5.2 V; FIG. 49B), consistent with an increase in magnetic permeability associated with an increase in magnetization, as observed by magnetization measurements by SQUID magnetometry. In addition, a change in magnetization associated with the sign of the external field is observed, consistent with the development of magnetic anisotropy in the thin film. The effects are reversible, as observed by multiple irradiation cycles performed on the thin film. A control experiment carried out with irradiation at 650 nm (HeNe) showed no effect, consistent with a photochrome-initiated event.

### Example 6

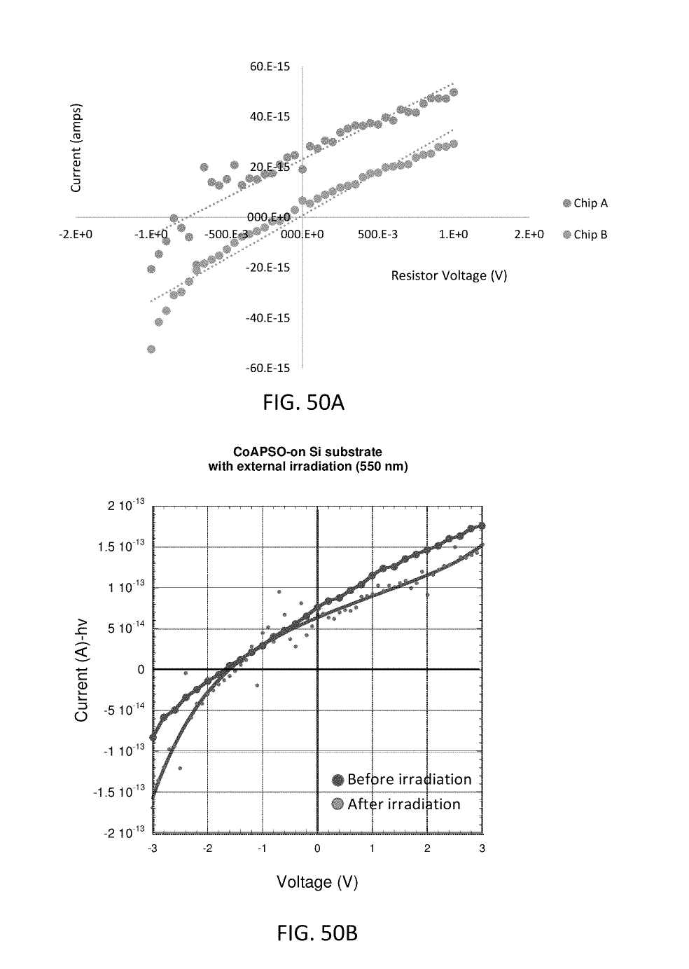

In this example, the electrical resistivities of organic thin films of the CoAPSO complex (i.e., Co(DTBQ)₂(APSO)) were measured on samples deposited by solution deposition on SiO₂/Si chips with patterned interdigitated gold electrodes. The current (I) was measured as a function of applied voltage (V) between −3 V and 3V under the presence of laboratory white light (FIGS. 50A and 50B). CoAPSO in toluene solution was deposited on two substrates, Chip A, which was annealed at 100° C. for 60 minutes under argon using a Chemical Vapour Deposition Tube Furnace; and Chip B, which was not annealed. Electrical properties were measured using a Keithley 4200-SCS Semiconductor Characterization System. The overall resistivity was found to be on the order of 10⁻¹²Ω over multiple samples, with non-ohmic behavior and a non-zero current at 0 applied voltage, which requires another source of a potential drop. Without being limited to a single theory, it currently is believed that the potential difference can be due to possible photovoltaic effects, polarization effects, space-charge effects (the formation of localized states or interfaces are charged and for zero voltage bias one observes a discharging effect with a long life-time), and structural changes induced by applied voltage. As the experiments were carried out under laboratory illumination, and exhibited further changes upon green light irradiation (a decrease in resistivity with the same voltage shift at zero voltage, FIG. 50B), this shows that light irradiation leads to a change in resistivity. The effect is increased with annealing of the thin films (FIG. 50 B), consistent with structural reorganization playing a role in the voltage offset.

In view of the many possible embodiments to which the principles of the present disclosure may be applied, it should be recognized that the illustrated embodiments are only preferred examples of the present disclosure and should not be taken as limiting the scope of the disclosure. Rather, the scope of the disclosure is defined by the following claims.

We claim:

1. A magnetic tunnel junction, comprising:
a photomagnetic layer comprising a magnetically bistable complex or cluster thereof, wherein the magnetically bistable complex comprises an optically bistable photoisomerizable component, and an electronically bistable metal-containing component and wherein the optically bistable photoisomerizable component is coupled to a metal of the electronically bistable metal-containing component;
a tunnel barrier layer positioned adjacent or substantially adjacent to the photomagnetic layer; and
a ferromagnetic layer positioned adjacent or substantially adjacent to the tunnel barrier layer.

2. The magnetic tunnel junction of claim 1, wherein the electronically bistable metal-containing component comprises an organic-metal complex having a formula M_{w}(L^{a})_{z}(L^{r})_{y}, wherein M is a metal selected from a row 1 transition metal, L^{r} is a redox active ligand capable of charge transfer with M, L^{a} is an ancillary ligand, and each of w, y and z independently is an integer selected from 1 to 8.

3. The magnetic tunnel junction of claim 3, wherein the redox active ligand has a formula 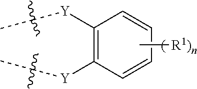
wherein each Y independently is selected from O, S, or NR^{a}, wherein R^{a} is selected from hydrogen, aliphatic, aryl, heteroaliphatic, or heteroaryl; each R¹ independently is selected from a heteroatom-containing functional group, aliphatic, aryl, heteroaliphatic, or heteroaryl; and n is an integer selected from 1 to 4.

4. The magnetic tunnel junction of claim 3, wherein the redox active ligand is a dioxolene ligand selected from

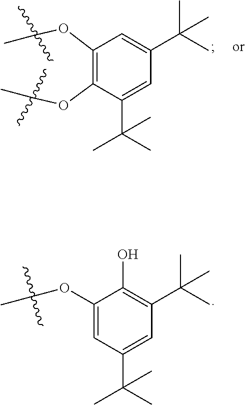 [SMILES: *Oc1cc(C(C)(C)C)cc(C(C)(C)C)c1O* ; *Oc1cc(C(C)(C)C)cc(C(C)(C)C)c1O]

5. The magnetic tunnel junction of claim 1, wherein the optically bistable photoisomerizable component has a structure satisfying a formula 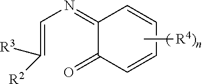
wherein R² and R³ combine to form a 5- to 8-membered aliphatic or heteroaliphatic cyclic ring or aliphatic or heteroaliphatic bicyclic ring; each R⁴ independently is selected from a functional group comprising —NH₂, —OH, —OR⁵, —C(O)H, —C(O)OH, —C(O)R^{b}, —C(O)OR^{b}, —SH, —SR^{b}, —P(R^{b})₃, and cyano, wherein R^{b} is selected from aliphatic, aryl, heteroaliphatic, or heteroaryl; or two R⁴ groups are positioned on adjacent carbons and form a fused aromatic ring, which is optionally bound to one or more additional aromatic or heteroaromatic groups comprising one or more heteroatoms selected from N, O, S, or Se; or two R⁴ groups are positioned on adjacent carbons and form a fused heteroaromatic ring comprising one or more heteroatoms selected from N, O, S, or Se, which is optionally bound to one or more additional aromatic or heteroaromatic groups comprising one or more heteroatoms selected from N, O, S, or Se; and n is an integer selected from 1 to 4.

6. The magnetic tunnel junction of claim 5, wherein the optically bistable photoisomerizable component has a structure satisfying a formula selected from 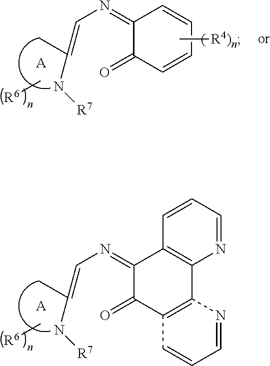
wherein ring A is an indole ring or an azahomoamantyl ring; each R⁶ independently is a heteroatom-containing function group, aliphatic, aryl, heteroaliphatic, or heteroaryl; R⁷ is hydrogen, a heteroatom-containing functional group, aliphatic, or aryl; and each n independently is an integer ranging from 0 to 8.

7. The magnetic tunnel junction of claim 6, wherein ring A is an indole ring, each of R⁶ and R⁷ independently is aliphatic, and n is 2; or wherein ring A is an azahomoadamantyl ring, R⁷ is aliphatic, and n is 0.

8. The magnetic tunnel junction of claim 1, wherein the optically bistable photoisomerizable component is a ring-opened or ring-closed form of spiro[azahomoadamantyl-phenanthrolinoxazine] or a ring-opened or ring-closed form of spiro[indoline-phenanthrolinoxazine].

9. The magnetic tunnel junction of claim 8, wherein the ring-opened form of the spiro[azahomoadamantyl-phenanthrolinoxazine] has a structure 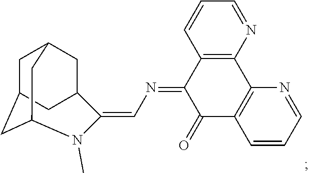 [SMILES: CN1/C(=C/N=C2\C(=O)c3cccnc3-c3ncccc32)C2CC3CC(C2)CC1C3]
and
the ring-opened form of the spiro[indoline-phenanthrolinoxazine] has a structure

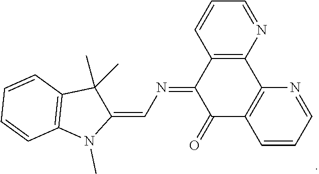 [SMILES: CN1/C(=C/N=C2\C(=O)c3cccnc3-c3ncccc32)C(C)(C)c2ccccc21]

10. The magnetic tunnel junction of claim 1, wherein a metal of the electronically bistable metal-containing component comprises Ti, V, Co, Mo, Cr, Fe, Mn, Ni, Zr, Mo, W, Cu, and combinations or alloys thereof.

11. The magnetic tunnel junction of claim 1, wherein the magnetically bistable complex has a formula
PₓM_{w}(L^{r})_{y}(L^{a})_{z}
wherein M is a metal of the electronically bistable metal-containing component; each of L^{r} and L^{a} are ligands of the electronically bistable metal-containing component; P is the optically bistable component; and each of w, x, y, and z independently is an integer selected from 1 to 8.

12. The magnetic tunnel junction of claim 1, wherein the magnetically bistable complex or cluster thereof is selected from

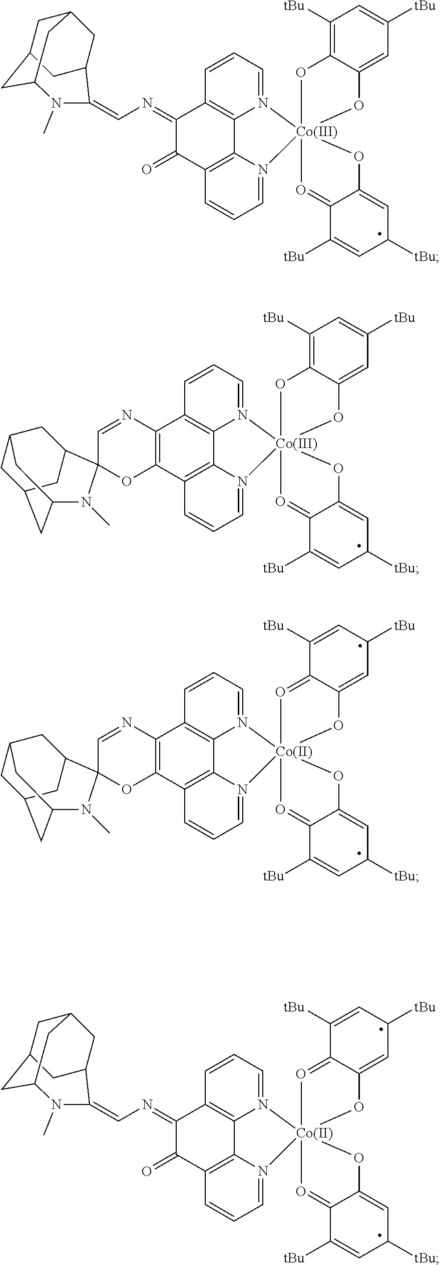

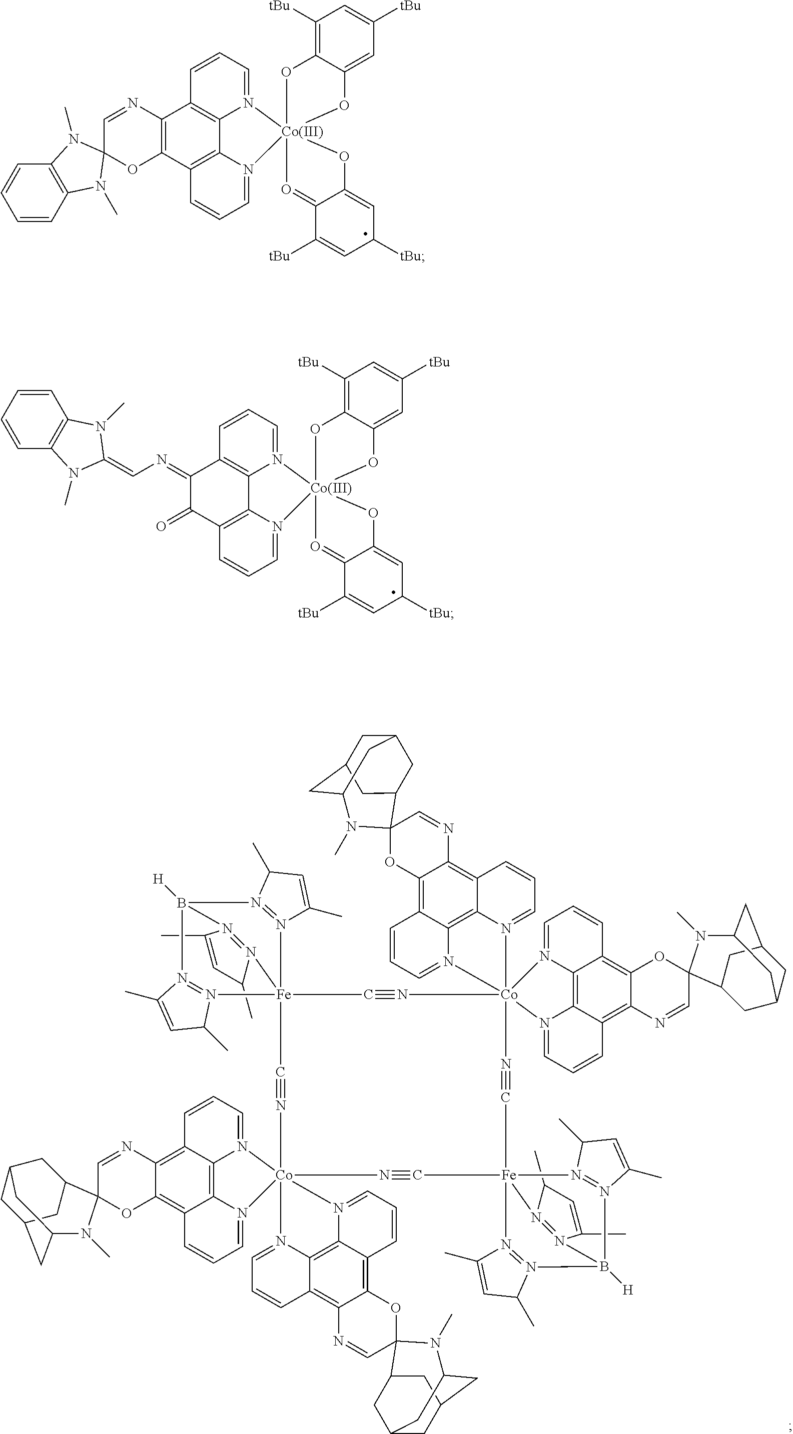

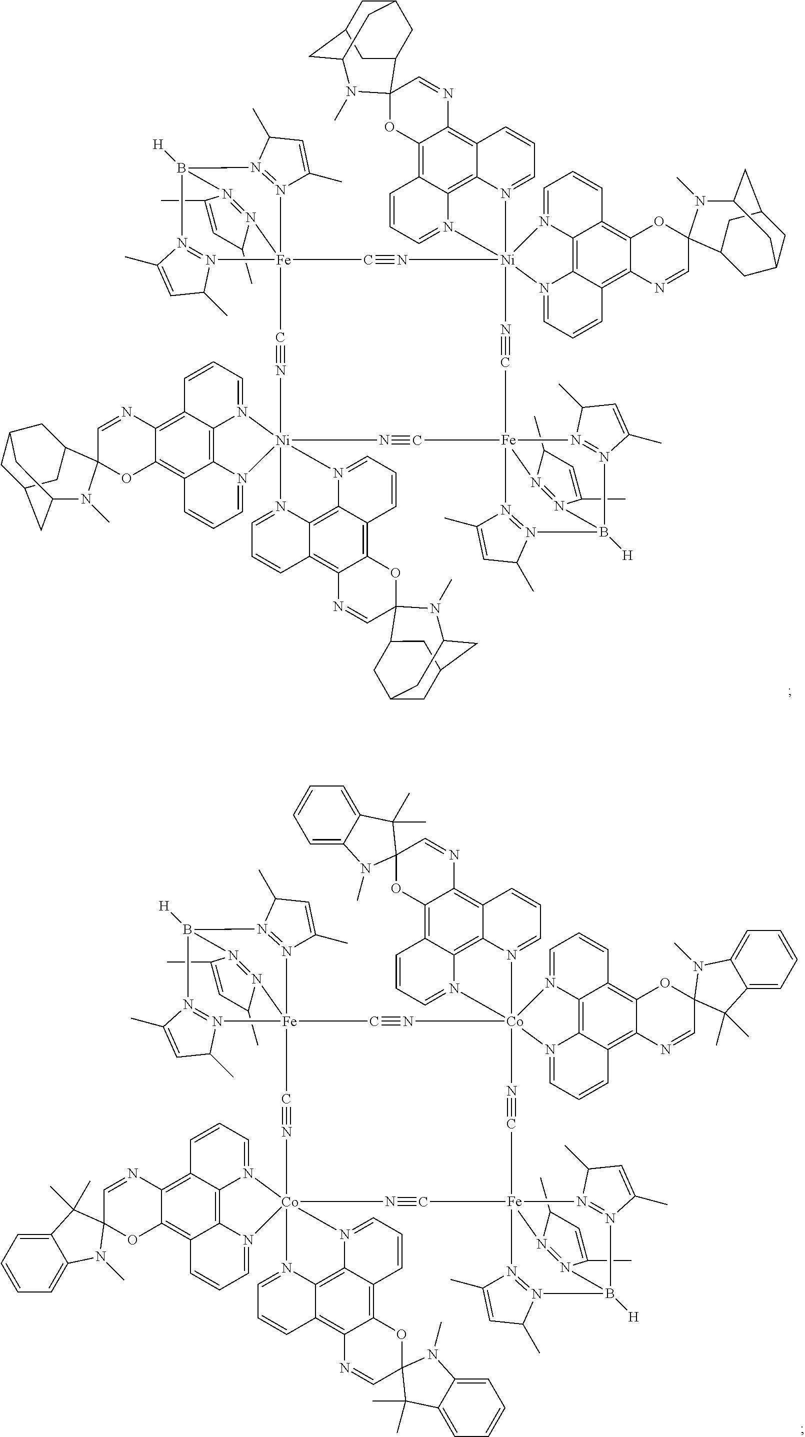

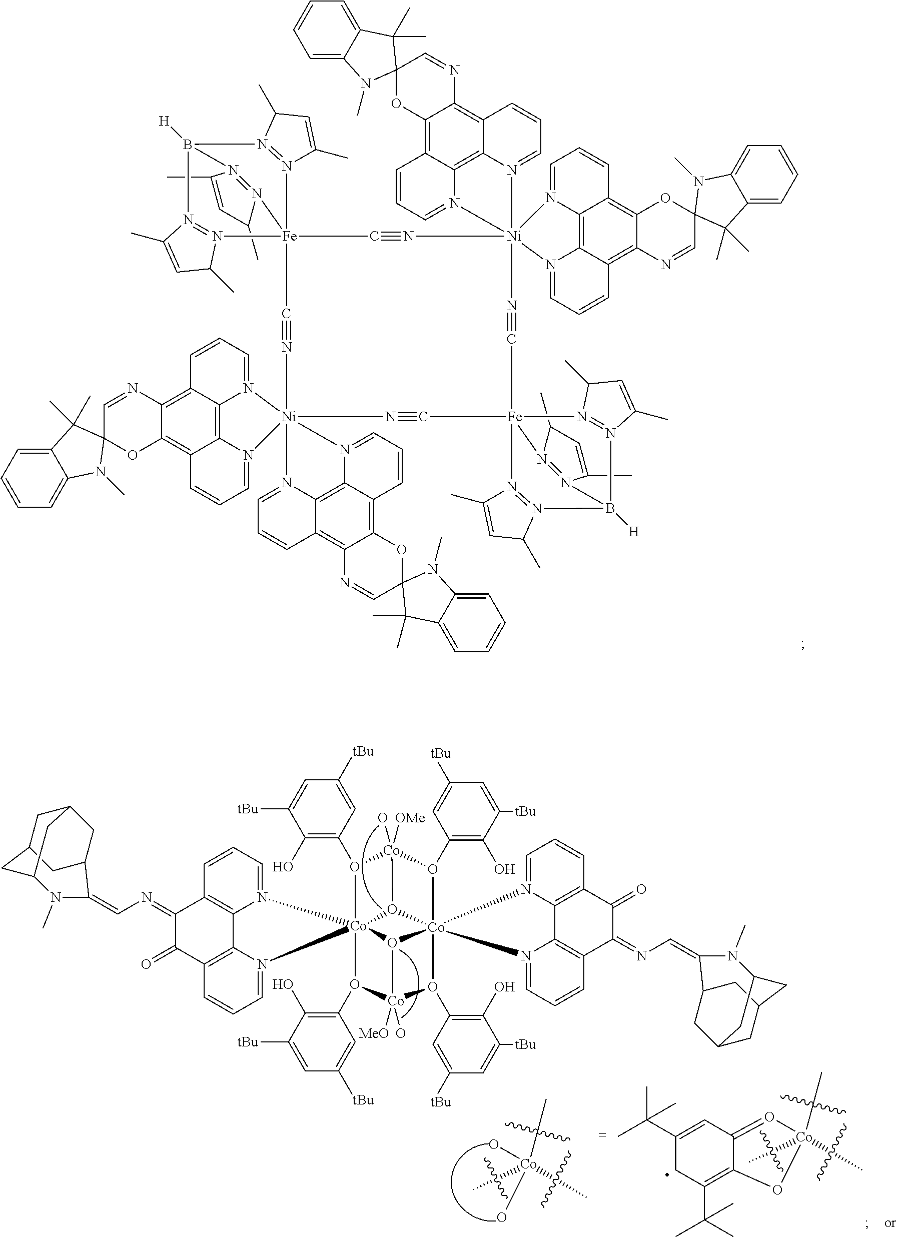

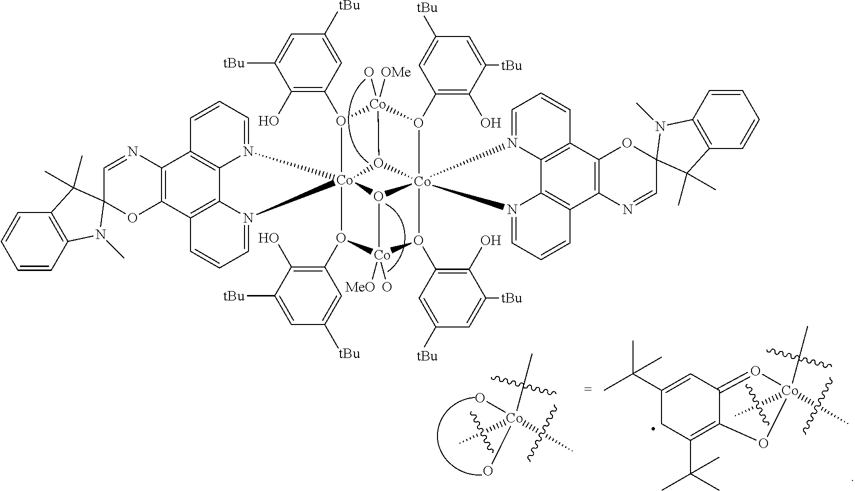

13. The magnetic tunnel junction of claim 1, wherein the tunnel barrier layer comprises a metal oxide selected from magnesium oxide, an aluminum oxide, titanium oxide, or mixtures thereof and the ferromagnetic layer comprises a ferromagnetic material comprising iron, cobalt, boron, nickel, manganese, gallium oxide, germanium oxide, or any mixture or alloy thereof.

14. The magnetic tunnel junction of claim 1, further comprising one or more electrode layers positioned adjacent or substantially adjacent to the photomagnetic layer and/or the ferromagnetic layer; a pinning layer; a reference layer; a multilayer structure layer; or any combination thereof.

15. An array, comprising a plurality of magnetic tunnel junctions according to claim 1.

16. A light-induced magnetic memory device, comprising one or more magnetic storage cells, wherein at least one magnetic storage cell comprises a magnetic tunnel junction according to claim 1.

17. The light-induced magnetic memory of claim 16, further comprising one or more bit lines, one or more word lines, one or more source lines, or a combination thereof, wherein the one or more bit lines, word lines, and/or source lines are coupled to the one or more magnetic storage cells.

18. A bistable complex or cluster thereof, wherein the bistable complex has a structure satisfying a formula
PₓM_{w}(L^{r})_{y}(L^{a})_{z}
wherein:
M is a row 1 transition metal selected from Ti, V, Co, Mo, Cr, Fe, Mn, Ni, Zr, Mo, W, Cu, or an alloy or mixture thereof;
L^{r} is a redox active ligand having a structure satisfying a formula 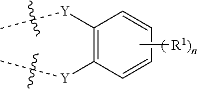
wherein each Y independently is selected from O, S, or NR^{a}, wherein R^{a} is selected from hydrogen, aliphatic, aryl, heteroaliphatic, or heteroaryl; each R¹ independently is selected from hydroxyl, aliphatic, aryl, heteroaliphatic, or heteroaryl; and n is an integer selected from 1 to 4;
L^{a} is an ancillary ligand selected from a cyano ligand, an azide ligand, or other organic ligand capable of undergoing a ligand-to-metal charge transfer process with M;
P is a photoisomerizable ligand having a structure satisfying a formula 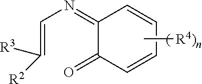
wherein R² and R³ combine to form a 5- to 8-membered aliphatic or heteroaliphatic cyclic ring or aliphatic or heteroaliphatic bicyclic ring; each R⁴ independently is selected from a functional group comprising —NH₂, —OH, —OR⁵, —C(O)H, —C(O)OH, —C(O)R^{b}, —C(O)OR^{b}, —SH, —SR^{b}, —P(R^{b})₃, and cyano, wherein R^{b} is selected from aliphatic, aryl, heteroaliphatic, or heteroaryl; or two R⁴ groups are positioned on adjacent carbons and combined to form a fused aromatic ring, which is optionally bound to one or more additional aromatic or heteroaromatic groups comprising one or more heteroatoms selected from N, O, S, or Se; or two R⁴ groups are positioned on adjacent carbons and combined to form a fused heteroaromatic ring comprising one or more heteroatoms selected from N, O, S, or Se, which is optionally bound to one or more additional aromatic or heteroaromatic groups comprising one or more heteroatoms selected from N, O, S, or Se; and n is an integer selected from 1 to 4; and
each of w, x, y, and z are integers independently selected from 1 to 8; and provided that if the redox active ligand is 3,5-di-tert-butylbenzene-1,2-diol, 2,4-di-tert-butyl-6-hydroxycyclohexa-2,5-dien-1-one, or a catecholate, a semiquinone, or a quinone form thereof, and the photoisomerizable ligand is spiro[azahomoadamantyl-phenanthrolinoxazine] or spiro[indoline-phenanthrolinoxazine], then M is not cobalt.

19. The bistable complex or cluster thereof according to claim 18, wherein the bistable complex exists in the solid state and exhibits a PISCES process at room temperature.

20. The bistable complex or cluster thereof according to claim 18, wherein the redox active ligand is a dioxolene ligand selected from

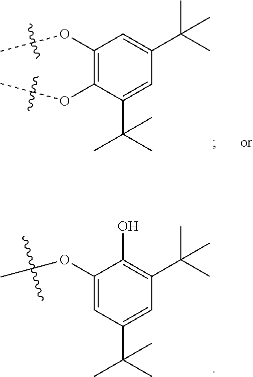

21. The bistable complex or cluster thereof according to claim 18, wherein each P independently is a spirooxazine ligand having a structure satisfying a formula 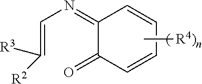
wherein R² and R³ combine to form a 5- to 8-membered aliphatic or heteroaliphatic cyclic ring or aliphatic or heteroaliphatic bicyclic ring; each R⁴ independently is selected from a functional group comprising —NH₂, —OH, —OR⁵, —C(O)H, —C(O)OH, —C(O)R^{b}, —C(O)OR^{b}, —SH, —SR^{b}, —P(R^{b})₃, and cyano, wherein R^{b} is selected from aliphatic, aryl, heteroaliphatic, or heteroaryl; or two R⁴ groups are positioned on adjacent carbons and combined to form a fused aromatic ring, which is optionally bound to one or more additional aromatic or heteroaromatic groups comprising one or more heteroatoms selected from N, O, S, or Se; or two R⁴ groups are positioned on adjacent carbons and combined to form a fused heteroaromatic ring comprising one or more heteroatoms selected from N, O, S, or Se, which is optionally bound to one or more additional aromatic or heteroaromatic groups comprising one or more heteroatoms selected from N, O, S, or Se; and n is an integer selected from 1 to 4.

22. The bistable complex or cluster thereof according to claim 18, wherein the spirooxazine ligand has a structure satisfying a formula selected from 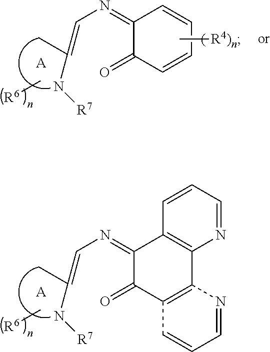
wherein ring A is an indole ring or an azahomoamantyl ring; each R⁶ is a heteroatom-containing function group aliphatic, aryl, heteroaliphatic, or heteroaryl; R⁷ is hydrogen, a heteroatom-containing functional group, aliphatic, or aryl; and each n independently is an integer ranging from 0 to 8.

23. The bistable complex or cluster thereof according to claim 18, wherein ring A is an indole ring, each of R⁶ and R⁷ independently is aliphatic, and n is 2; or wherein ring A is an azahomoadamantyl ring, R⁷ is aliphatic, and n is 0.

24. The bistable complex or cluster thereof according to claim 18, wherein the spirooxazine ligand is a ring-opened form of spiro[azahomoadamantyl-phenanthrolinoxazine] at room temperature.

25. The bistable complex or cluster thereof according to claim 24, wherein the opened form of the spiro[azahomoadamantyl-phenanthrolinoxazine] has a structure 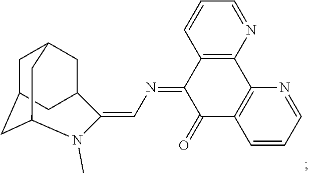 [SMILES: CN1/C(=C/N=C2\C(=O)c3cccnc3-c3ncccc32)C2CC3CC(C2)CC1C3]
and
wherein M is cobalt.

26. The bistable complex or cluster thereof according to claim 18, wherein the bistable complex or cluster is selected from

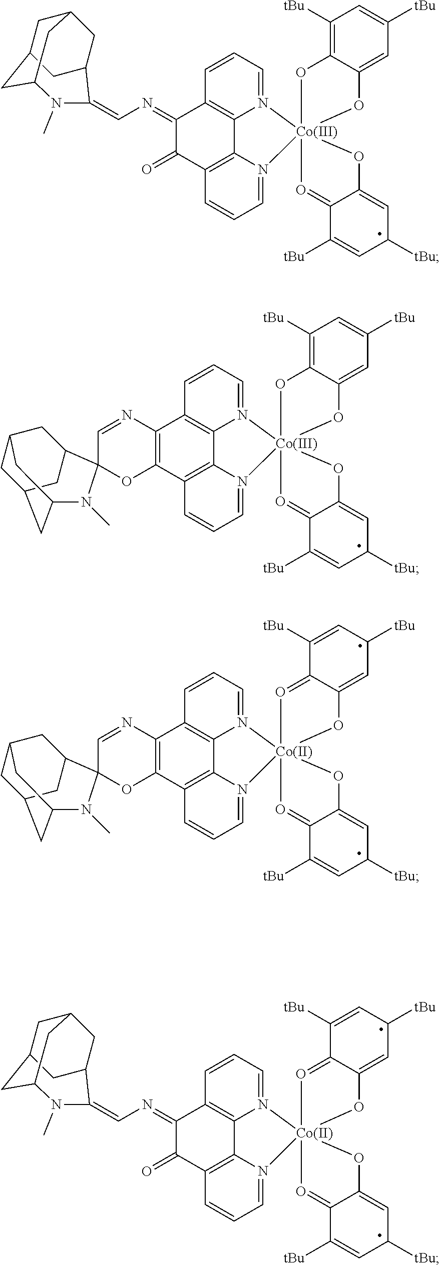

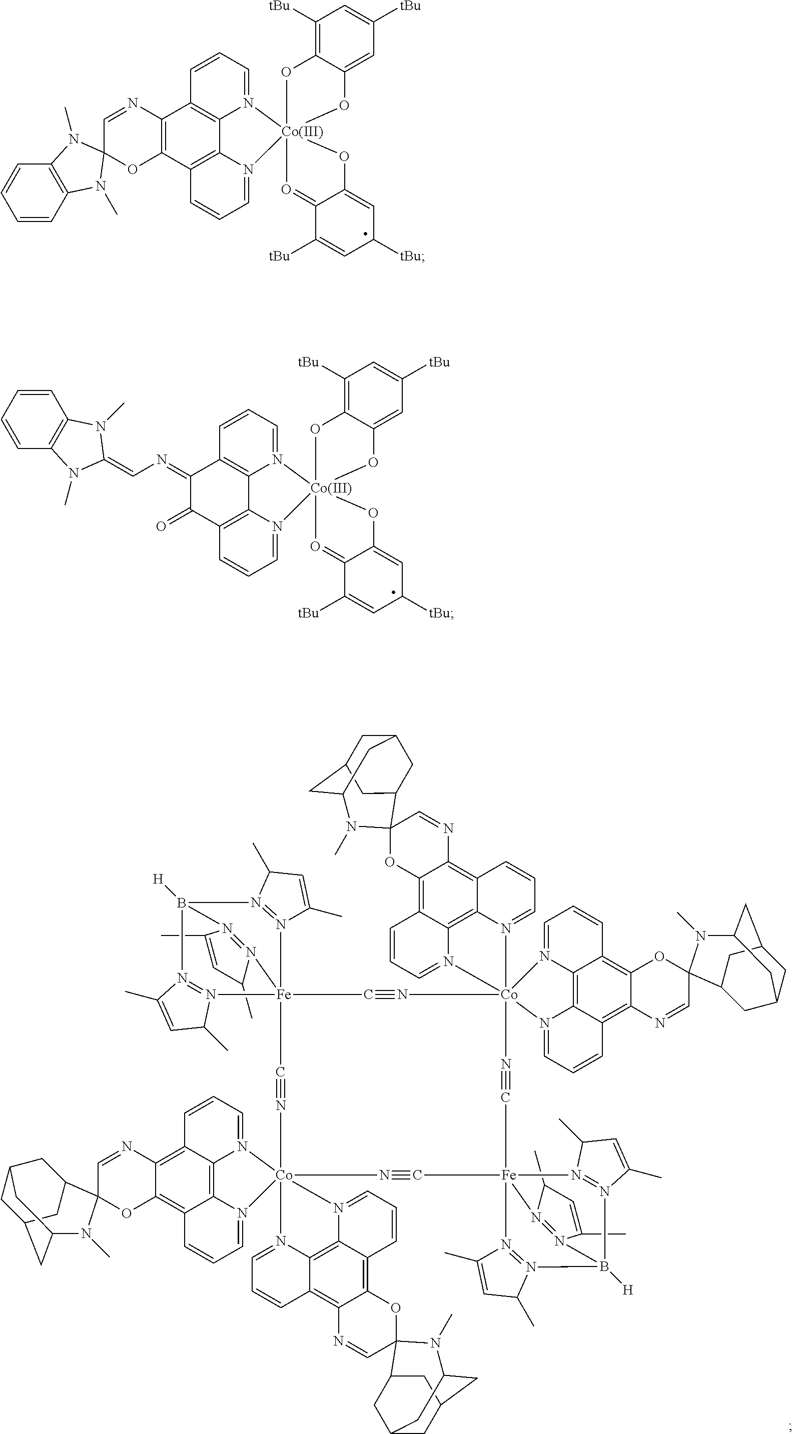

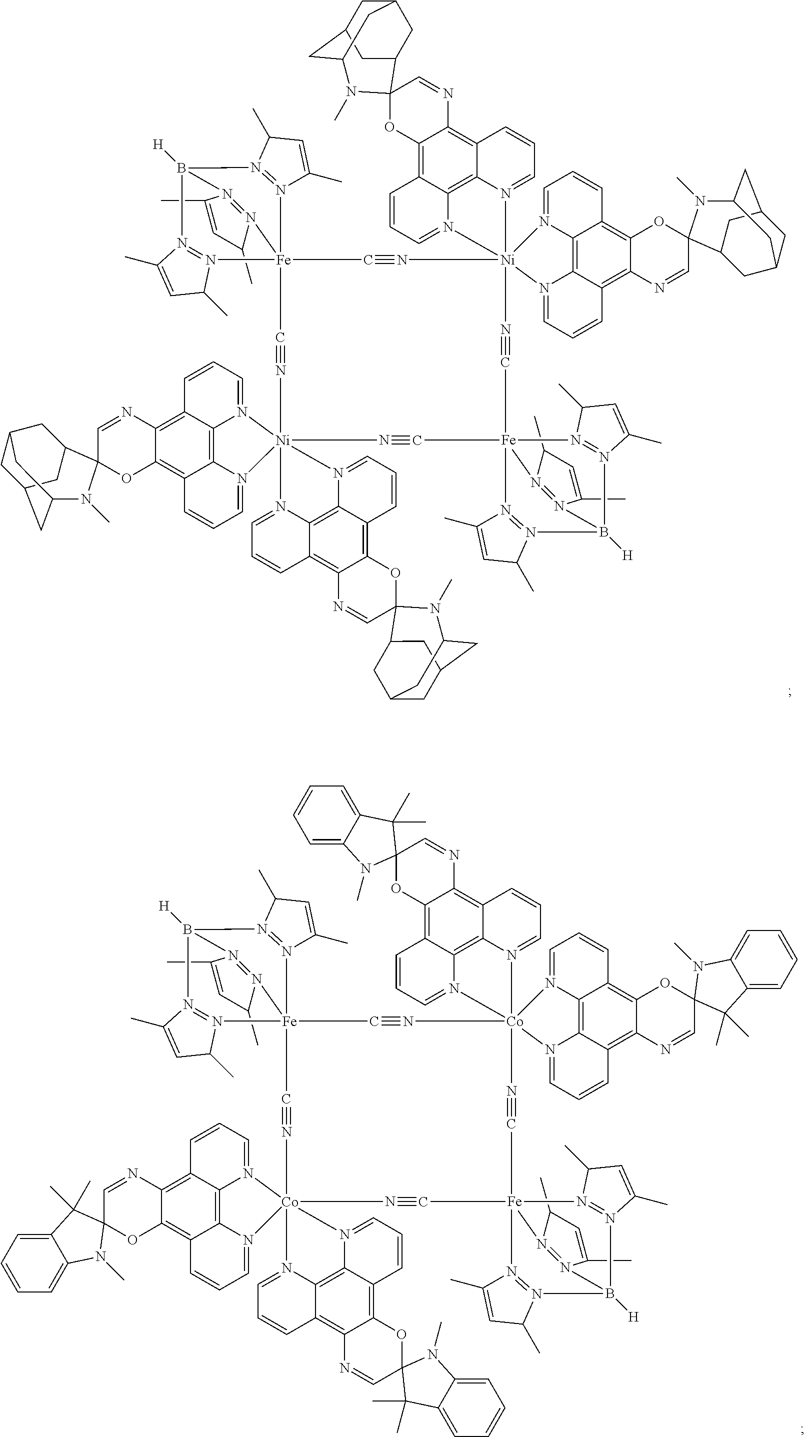

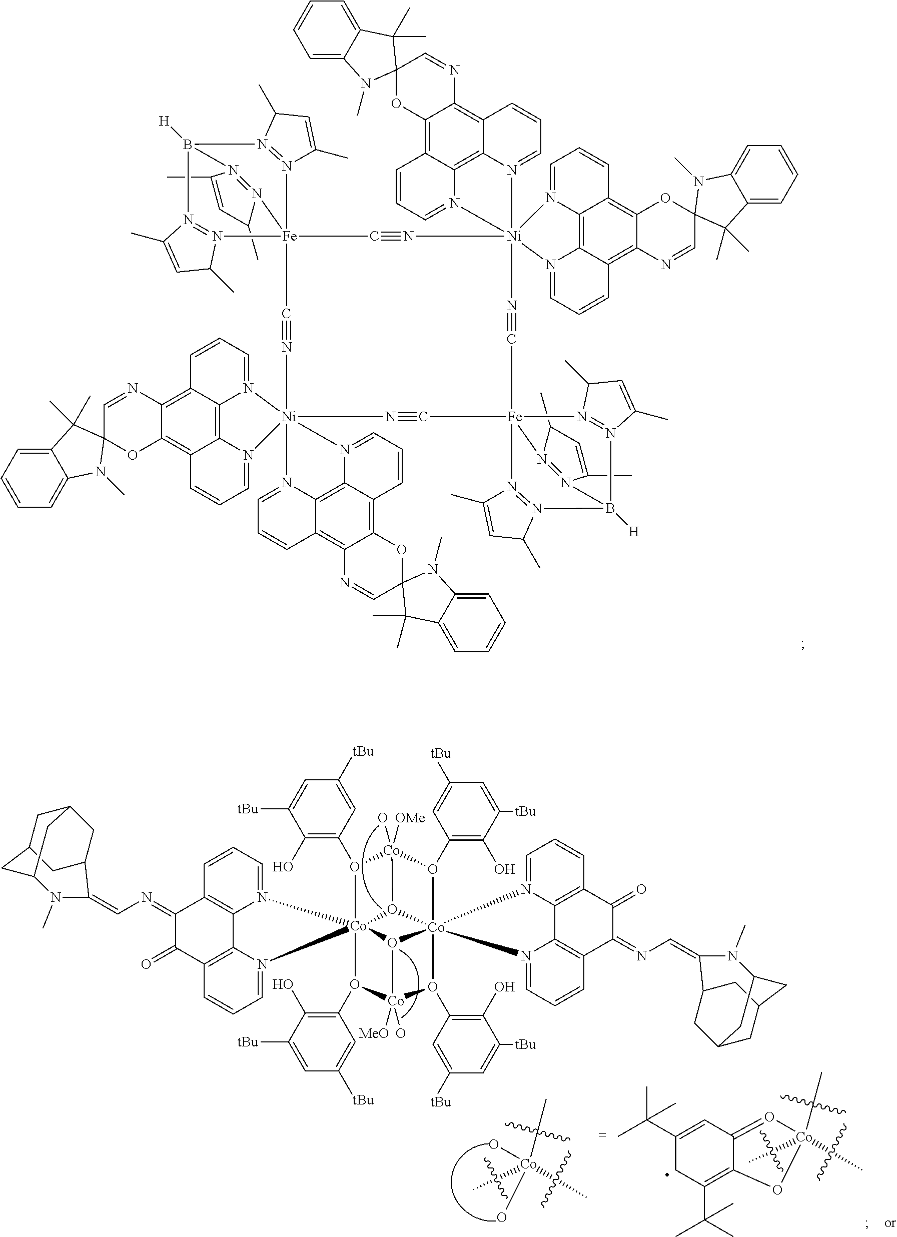

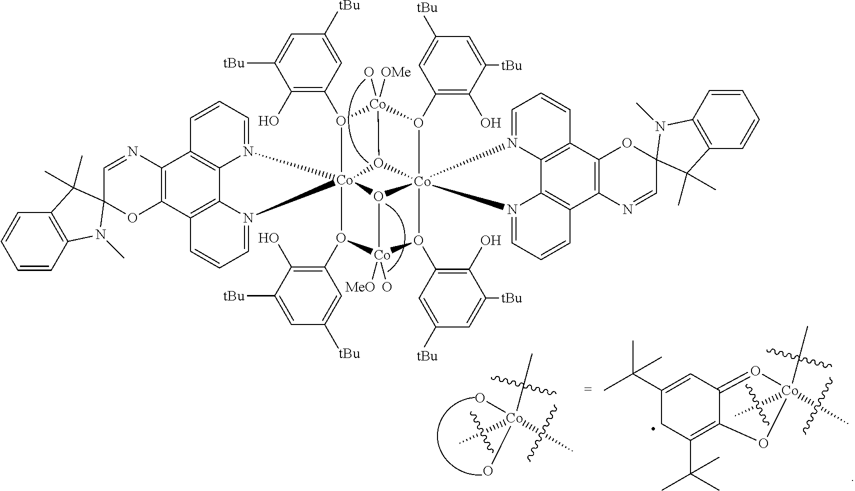

27. A method for making the bistable complex of claim 18, comprising combining a solution comprising a metal complex precursor with a photoisomerizable ligand to obtain a reaction mixture, wherein the metal complex precursor has a formula M(L^{r})₂(pyridine)₂, wherein M is a row 1 transition metal, L^{r} is a redox active ligand; and the photoisomerizable ligand has a structure satisfying a formula 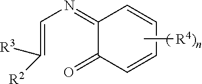
wherein R² and R³ combine to form a 5- to 8-membered aliphatic or heteroaliphatic cyclic ring or aliphatic or heteroaliphatic bicyclic ring; each R⁴ independently is selected from a functional group comprising —NH₂, —OH, —OR⁵, —C(O)H, —C(O)OH, —C(O)R^{b}, —C(O)OR^{b}, —SH, —P(R^{b})₃, and cyano, wherein R^{b} is selected from aliphatic, aryl, heteroaliphatic, or heteroaryl; or two R⁴ groups are positioned on adjacent carbons and combined to form a fused aromatic ring, which is optionally bound to one or more additional aromatic or heteroaromatic groups comprising one or more heteroatoms selected from N, O, S, or Se; or two R⁴ groups are positioned on adjacent carbons and combined to form a fused heteroaromatic ring comprising one or more heteroatoms selected from N, O, S, or Se, which is optionally bound to one or more additional aromatic or heteroaromatic groups comprising one or more heteroatoms selected from N, O, S, or Se; and n is an integer selected from 1 to 4.

28. The method of claim 27, wherein the method further comprises isolating the bistable complex by filtering the bistable complex from the reaction mixture using a solvent and wherein 1 equivalent of the metal complex precursor is combined with 1 to 8 equivalents of the photochromic ligand per metal center.

29. A phase change memory cell, comprising:
a top electrode;
an active layer positioned adjacent to the top electrode, the active layer comprising a bistable complex comprising an optically bistable photoisomerizable component; and an electronically bistable metal-containing component, wherein the optically bistable photoisomerizable component is coupled to a metal of the electronically bistable metal-containing component and wherein the active layer comprises a region effective to under a phase change upon heating;
a heating material positioned proximal to or in contact with the active layer;
an insulator material surrounding at least a portion of the heating material; and
a bottom electrode positioned adjacent to the insulator material.
